(19) United States
(12) Patent Application Publication
(10) Pub. No.: US 2011/0233639 A1
(43) Pub. Date: Sep. 29, 2011

(54) SEMICONDUCTOR DEVICE

(75) Inventors: Hideaki YAMAKOSHI, Kanagawa (JP); Yasushi OKA, Kanagawa (JP); Daisuke OKADA, Kanagawa (JP)

(73) Assignee: RENESAS ELECTRONICS CORPORATION

(21) Appl. No.: 13/046,751

(22) Filed: Mar. 13, 2011

(30) Foreign Application Priority Data
Mar. 23, 2010 (JP) 2010-066111

(51) Int. Cl. H01L 29/788

(52) U.S. Cl. 257/316; 257/E29.3

(57) ABSTRACT

To improve performance of a semiconductor device having a nonvolatile memory. Further to improve reliability of the semiconductor device. Furthermore, to improve performance of a semiconductor device as well as improving reliability of the semiconductor device.

A plurality of memory cells each configured by a memory transistor having a floating gate and a control transistor coupled in series to the memory transistor is arranged in an array in an X direction and in a Y direction on the main surface of a semiconductor substrate. Then, a bit wire that couples drain regions of the memory transistors of the memory cells arranged in the X direction is provided in the lowermost wiring layer of a multilayer wiring structure formed over the semiconductor substrate and the bit wire is arranged to cover the whole floating gate electrode.

### CROSS-REFERENCE TO RELATED APPLICATION

The disclosure of Japanese Patent Application No. 2010-66111 filed on Mar. 23, 2010 including the specification, drawings and abstract is incorporated herein by reference in its entirety.

### BACKGROUND OF THE INVENTION

The present invention relates to a semiconductor device and particularly, to technology effective when applied to a semiconductor device in which nonvolatile memory cells including a floating gate electrode are arranged in an array.

A nonvolatile memory is formed by arranging a plurality of memory cells in an array on the main surface of a semiconductor substrate. Each memory cell has an electrically conductive floating gate electrode and a trapping insulating film capable of accumulating charges, uses a charge accumulated state in the floating gate electrode or the trapping insulating film as stored information, and reads the information as a threshold value of a transistor.

A semiconductor device using a floating gate electrode is disclosed in, for example, Japanese Patent Laid-Open No. 1992-212471 (Patent Document 1), Japanese Patent Laid-Open No. 1984-155968 (Patent Document 2), U.S. Pat. No. 6,842,374 (Patent Document 3), U.S. Pat. No. 6,711,064 (Patent Document 4), Japanese Patent Laid-Open No. 2004-253685 (Patent Document 5), and Japanese Patent Laid-Open No. 2005-317921 (Patent Document 6).

### SUMMARY OF THE INVENTION

A nonvolatile memory is a memory capable of holding stored information in a charge accumulating layer, such as a floating gate electrode. In recent years, there is a trend for a semiconductor device to comprise multiple functions, and therefore, it is desired to develop a nonvolatile memory in which holding characteristics of stored information are improved than before.

The present invention has been made in view of the above circumstances and provides technology capable of improving performance of a semiconductor device.

The present invention has also been made in view of the above circumstances and provides technology capable of improving reliability of a semiconductor device.

The present invention has also been made in view of the above circumstances and provides technology capable of improving performance of a semiconductor device and at the same time, providing technology capable of improving reliability of a semiconductor device.

The other purposes and the new feature of the present invention will become clear from the description of the present specification and the accompanying drawings.

The following explains briefly the outline of a typical invention among the inventions disclosed in the present application.

A semiconductor device according to a typical embodiment comprises a semiconductor substrate, a plurality of nonvolatile memory cells arranged in an array in a first direction and in a second direction intersecting the first direction on the main surface of the semiconductor substrate, and a plurality of wiring layers formed over the main surface of the semiconductor substrate. Each of the nonvolatile memory cells each has a memory transistor having a floating gate electrode and a control transistor coupled in series to the memory transistor and a bit wire that couples drain regions of the memory transistors of the nonvolatile memory cells arranged in the first direction is formed so as to extend in the first direction in the lowermost wiring layer of the wiring layers. Then, the width of the bit wire is greater than the dimension of the floating gate electrode in the second direction.

The following explains briefly the effect acquired by the typical invention among the inventions disclosed in the present application.

According to a typical embodiment, it is possible to improve the performance of a semiconductor device.

It is also possible to improve the reliability of a semiconductor device.

It is also possible to improve the reliability of a semiconductor device as well as improving the performance of the semiconductor device.

### BRIEF DESCRIPTION OF THE DRAWINGS

FIG. 1 is a plan view of relevant parts of a semiconductor device in an embodiment of the present invention;

FIG. 2 is a plan view of relevant parts of a semiconductor device in an embodiment of the present invention;

FIG. 3 is a plan view of relevant parts of a semiconductor device in an embodiment of the present invention;

FIG. 4 is a plan view of relevant parts of a semiconductor device in an embodiment of the present invention;

FIG. 5 is a plan view of relevant parts of a semiconductor device in an embodiment of the present invention;

FIG. 6 is a partially enlarged plan view (plan view of relevant parts) of a semiconductor device in an embodiment of the present invention;

FIG. 7 is a partially enlarged plan view (plan view of relevant parts) of a semiconductor device in an embodiment of the present invention;

FIG. 8 is a section view of relevant parts of a semiconductor device in an embodiment of the present invention;

FIG. 9 is a section view of relevant parts of a semiconductor device in an embodiment of the present invention;

FIG. 10 is a section view of relevant parts of a semiconductor device in an embodiment of the present invention;

FIG. 11 is a section view of relevant parts of a semiconductor device in an embodiment of the present invention;

FIG. 12 is a section view of relevant parts of a semiconductor device in an embodiment of the present invention;

FIG. 13 is a section view of relevant parts of a semiconductor device in an embodiment of the present invention;

FIG. 14 is a circuit diagram (equivalent circuit diagram) of a memory cell array region of a semiconductor device in an embodiment of the present invention;

FIG. 15 is a section view of relevant parts of a semiconductor device in an embodiment of the present invention when forming a wire by patterning an electrically conductive film for wiring;

FIG. 16 is a section view of relevant parts of a semiconductor device in an embodiment of the present invention when forming a wire by patterning an electrically conductive film for wiring;

FIG. 17 is a section view of relevant parts of a semiconductor device in an embodiment of the present invention when forming a wire by patterning an electrically conductive film for wiring;

FIG. 18 is an explanatory diagram showing an operation example (write) of a semiconductor device in an embodiment of the present invention;

FIG. 19 is an explanatory diagram showing an operation example (erase) of a semiconductor device in an embodiment of the present invention;

FIG. 20 is an explanatory diagram showing an operation example (read) of a semiconductor device in an embodiment of the present invention;

FIG. 21 is an explanatory diagram showing an operation example (erase) of a semiconductor device in an embodiment of the present invention;

FIG. 22 is a plan view of relevant parts of a semiconductor device in another embodiment of the present invention;

FIG. 23 is a plan view of relevant parts of a semiconductor device in another embodiment of the present invention;

FIG. 24 is a plan view of relevant parts of a semiconductor device in another embodiment of the present invention;

FIG. 25 is a plan view of relevant parts of a semiconductor device in another embodiment of the present invention;

FIG. 26 is a section view of relevant parts of a semiconductor device in another embodiment of the present invention;

FIG. 27 is a section view of relevant parts of a semiconductor device in another embodiment of the present invention;

FIG. 28 is a plan view of relevant parts of a semiconductor device in another embodiment of the present invention;

FIG. 29 is a plan view of relevant parts of a semiconductor device in another embodiment of the present invention;

FIG. 30 is a section view of relevant parts of a semiconductor device in another embodiment of the present invention;

FIG. 31 is a section view of relevant parts of a semiconductor device in another embodiment of the present invention;

FIG. 32 is a section view of relevant parts of a semiconductor device in another embodiment of the present invention;

FIG. 33 is a plan view of relevant parts of a semiconductor device in another embodiment of the present invention;

FIG. 34 is a plan view of relevant parts of a semiconductor device in another embodiment of the present invention;

FIG. 35 is a plan view of relevant parts of a semiconductor device in another embodiment of the present invention;

FIG. 36 is a section view of relevant parts of a semiconductor device in another embodiment of the present invention;

FIG. 37 is a section view of relevant parts of a semiconductor device in another embodiment of the present invention;

FIG. 38 is a section view of relevant parts of a semiconductor device in another embodiment of the present invention;

FIG. 39 is a section view of relevant parts of a semiconductor device in another embodiment of the present invention;

FIG. 40 is a plan view of relevant parts of a semiconductor device in another embodiment of the present invention;

FIG. 41 is a plan view of relevant parts of a semiconductor device in another embodiment of the present invention;

FIG. 42 is a section view of relevant parts of a semiconductor device in another embodiment of the present invention;

FIG. 43 is a section view of relevant parts of a semiconductor device in another embodiment of the present invention;

FIG. 44 is a plan view of relevant parts of a semiconductor device in another embodiment of the present invention;

FIG. 45 is a plan view of relevant parts of a semiconductor device in another embodiment of the present invention;

FIG. 46 is a section view of relevant parts of a semiconductor device in another embodiment of the present invention;

FIG. 47 is a section view of relevant parts of a semiconductor device in another embodiment of the present invention;

FIG. 48 is a plan view of relevant parts of a semiconductor device in another embodiment of the present invention;

FIG. 49 is a plan view of relevant parts of a semiconductor device in another embodiment of the present invention;

FIG. 50 is a plan view of relevant parts of a semiconductor device in another embodiment of the present invention;

FIG. 51 is a section view of relevant parts of a semiconductor device in another embodiment of the present invention;

FIG. 52 is a section view of relevant parts of a semiconductor device in another embodiment of the present invention;

FIG. 53 is a plan view of relevant parts of a semiconductor device in another embodiment of the present invention;

FIG. 54 is a plan view of relevant parts of a semiconductor device in another embodiment of the present invention;

FIG. 55 is a section view of relevant parts of a semiconductor device in another embodiment of the present invention.

FIG. 56 is a plan view of relevant parts of a semiconductor device in another embodiment of the present invention;

FIG. 57 is a plan view of relevant parts of a semiconductor device in another embodiment of the present invention;

FIG. 58 is a section view of relevant parts of a semiconductor device in another embodiment of the present invention; and

FIG. 59 is a plan view of relevant parts of a nonvolatile memory for storing 1-bit information by two memory cells.

### DETAILED DESCRIPTION OF PREFERRED EMBODIMENTS

The following embodiments will be explained, divided into plural sections or embodiments, if necessary for convenience. Except for the case where it shows clearly in particular, they are not mutually unrelated and one has relationships such as a modification, details, and supplementary explanation of some or entire of another. In the following embodiments, when referring to the number of elements, etc. (including the number, a numeric value, an amount, a range, etc.), they may not be restricted to the specific number but may be greater or smaller than the specific number, except for the case where they are clearly specified in particular and where they are clearly restricted to a specific number theoretically. Furthermore, in the following embodiments, it is needless to say that an element (including an element step etc.) is not necessarily indispensable, except for the case where it is clearly specified in particular and where it is considered to be clearly indispensable from a theoretical point of view, etc. Similarly, in the following embodiments, when shape, position relationship, etc. of an element etc. are referred to, what resembles or is similar to the shape substantially shall be included, except for the case where it is clearly specified in particular and where it is considered to be clearly not right from a theoretical point of view. This statement also applies to the numeric value and range described above.

Embodiments of the present invention are explained in detail based on the drawings. In all the drawings for explaining embodiments, the same symbol is attached to the member having the same function and the repeated explanation thereof is omitted. In the following embodiments, except when necessary in particular, the same or similar part is not explained repeatedly, as a principle.

In a drawing used in the embodiments, in order to make the drawing easy-to-see, hatching may be omitted even if it is a section view. Further, in order to make the drawing easy-to-see, hatching may be attached even if it is a plan view.

### First Embodiment

The present invention is a semiconductor device comprising a nonvolatile memory (nonvolatile storage element, flash memory, nonvolatile semiconductor storage device) and the nonvolatile memory is one in which a floating gate electrode is used mainly at a charge accumulating part. In the following embodiment, the nonvolatile memory is assumed basically to be a p-channel type MISFET (Metal Insulator. Semiconductor Field Transistor) and explanation is given based on a memory cell using a floating gate electrode. In the following embodiment, the polarities (polarities of the applied voltage at the time of write, erasure, read and polarities of carriers) are used for explaining the operation in the case of a memory cell based on the p-channel type MISFET and when based on an n-channel type MISFET, the same operation can be obtained in principles by reverting all the polarities of the applied potential, the conduction type of carriers, etc.

A semiconductor device in the present embodiment will be explained with reference to the drawings.

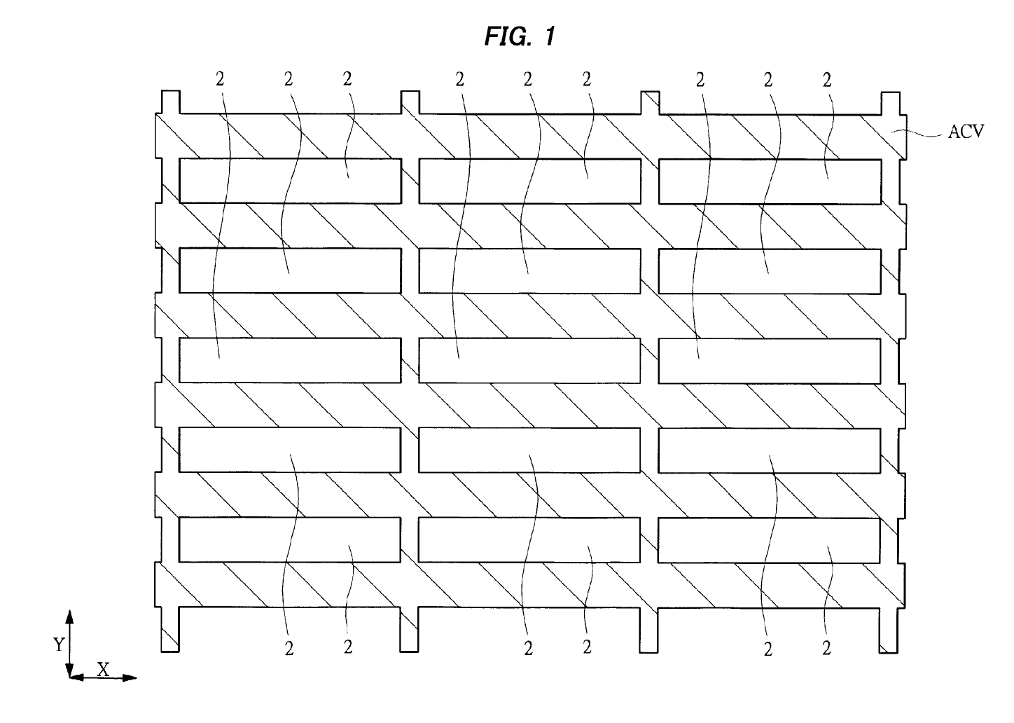

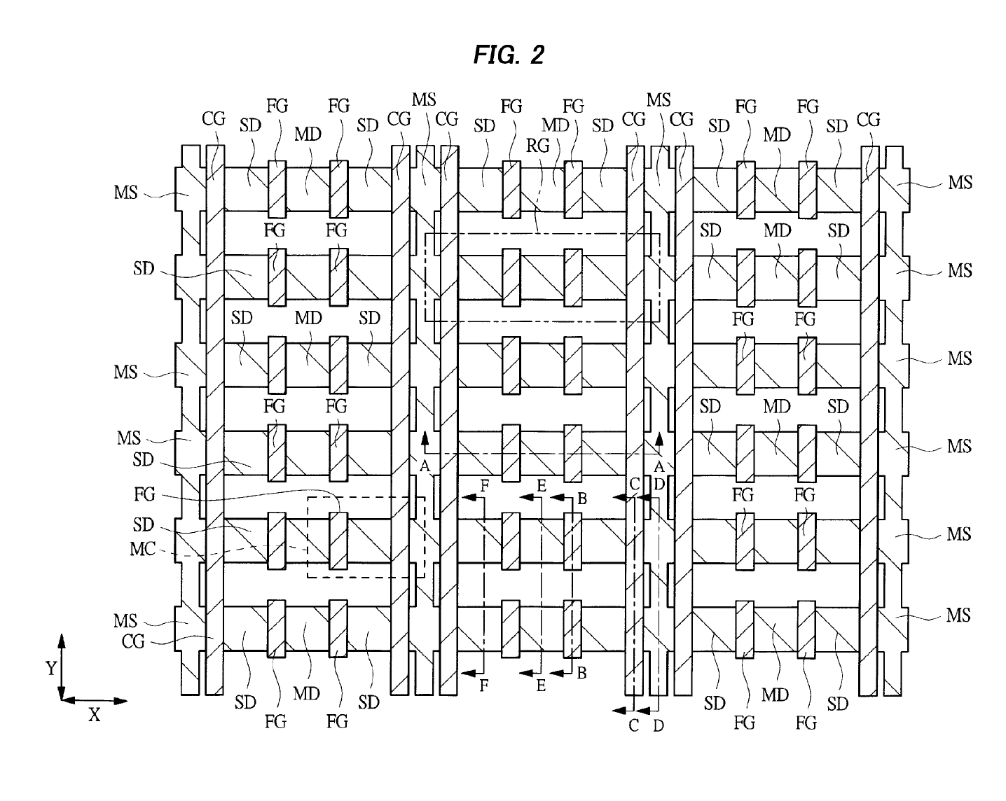

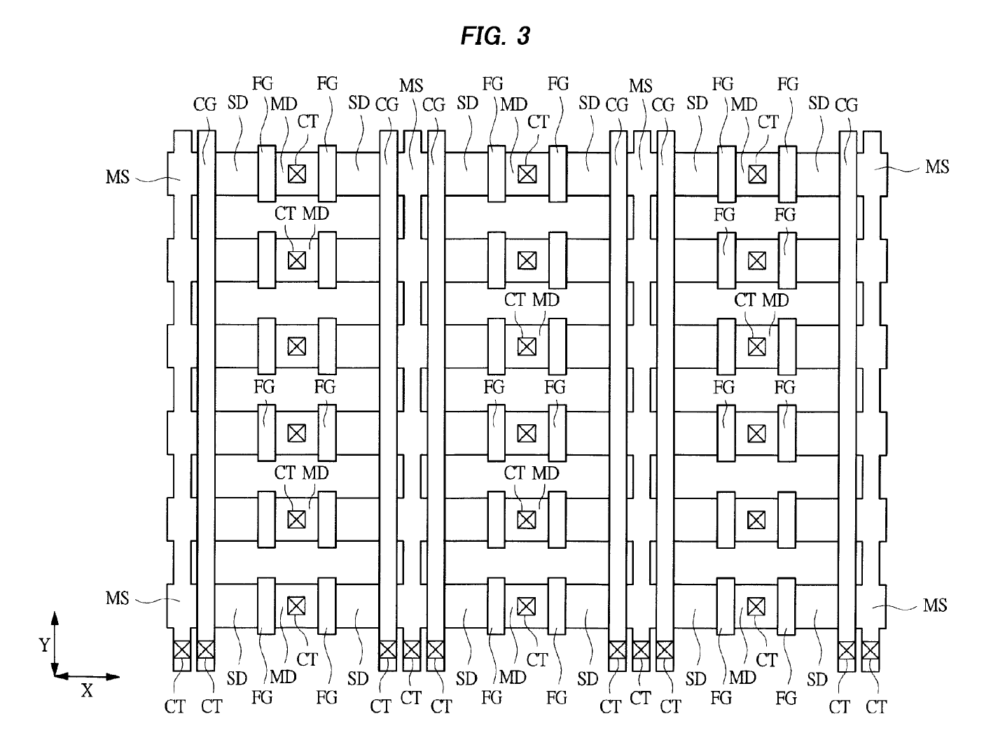

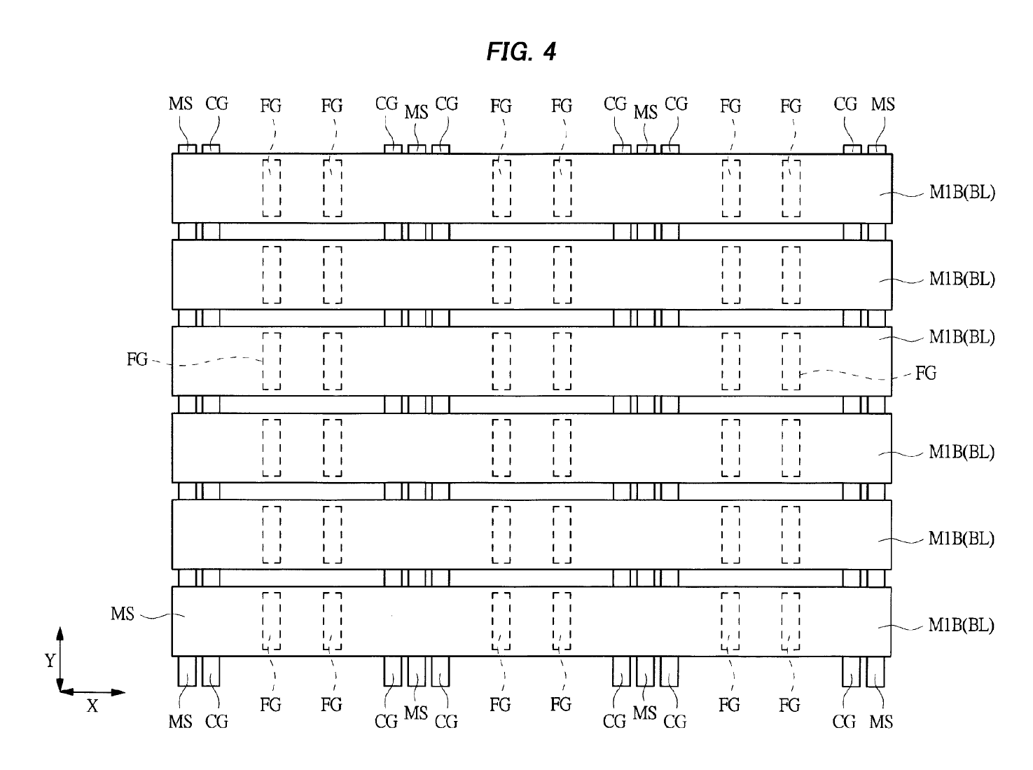

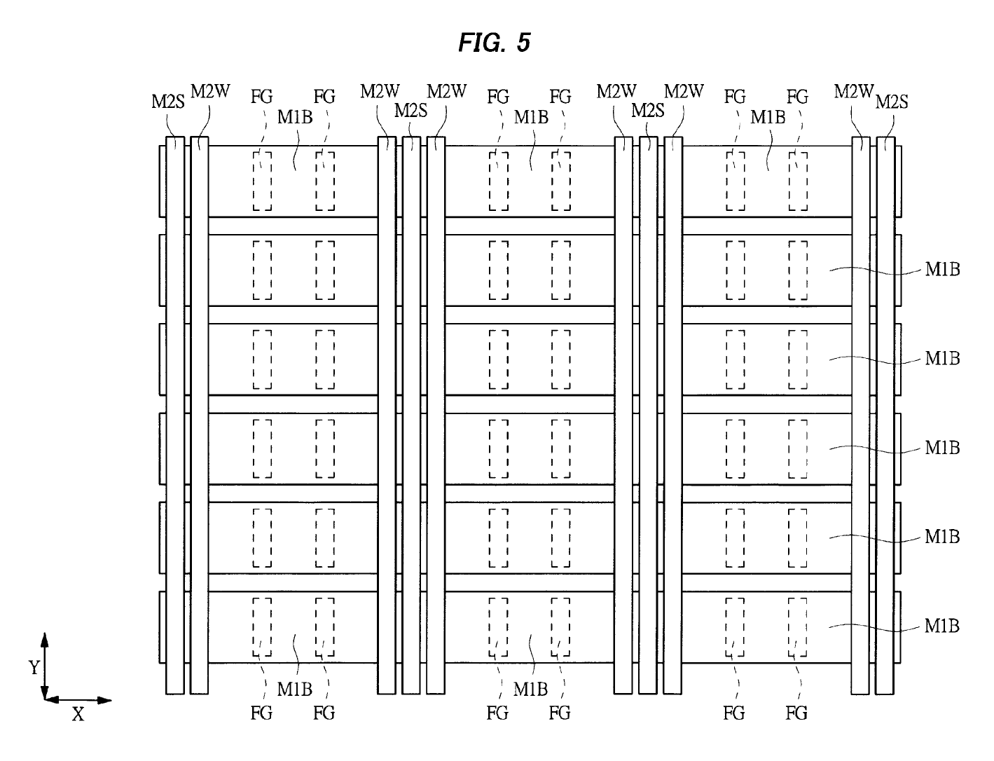

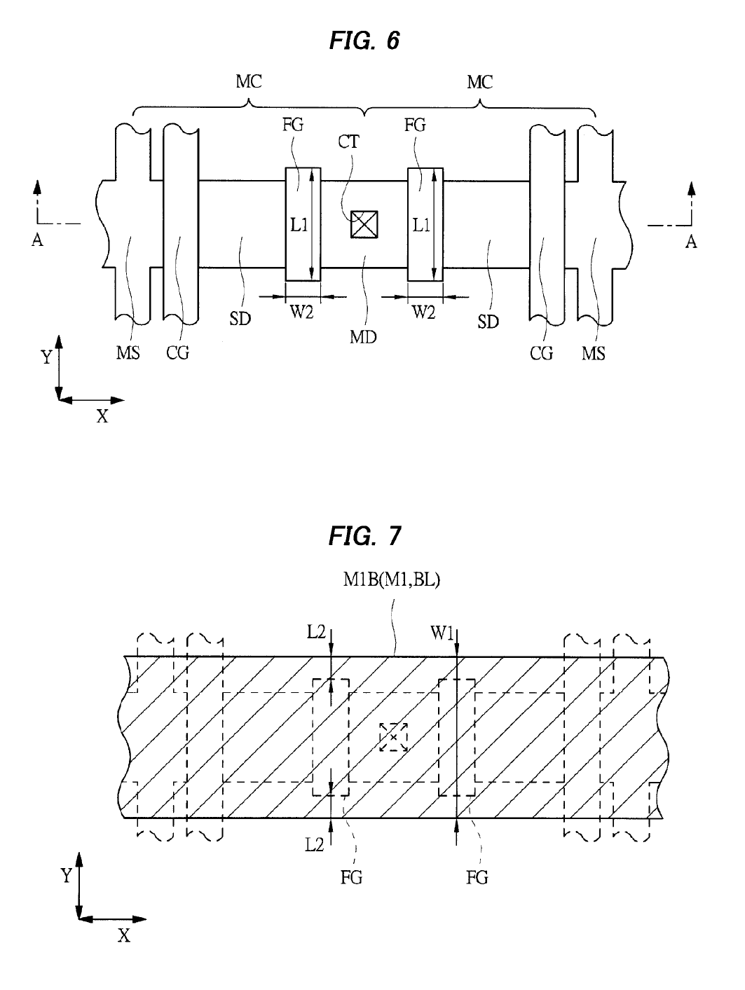

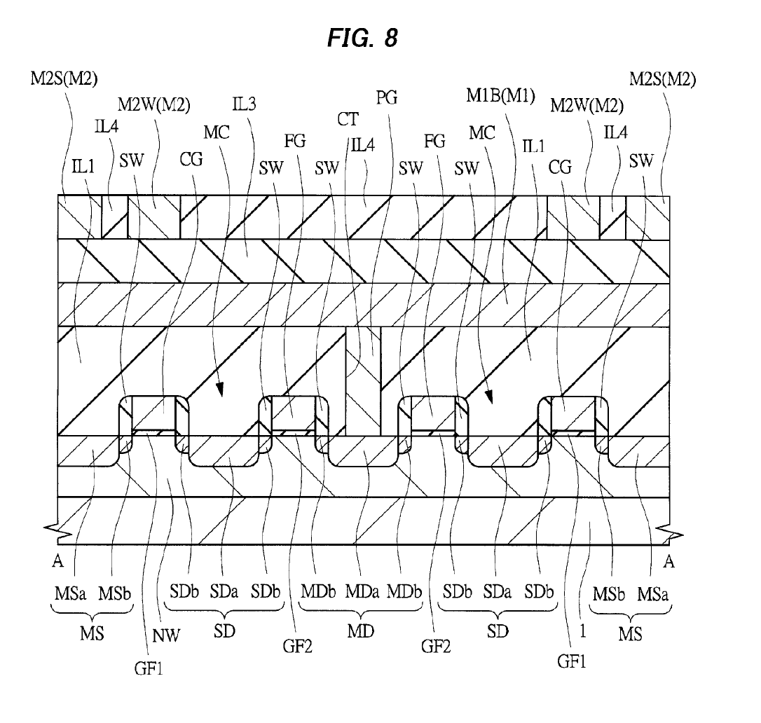

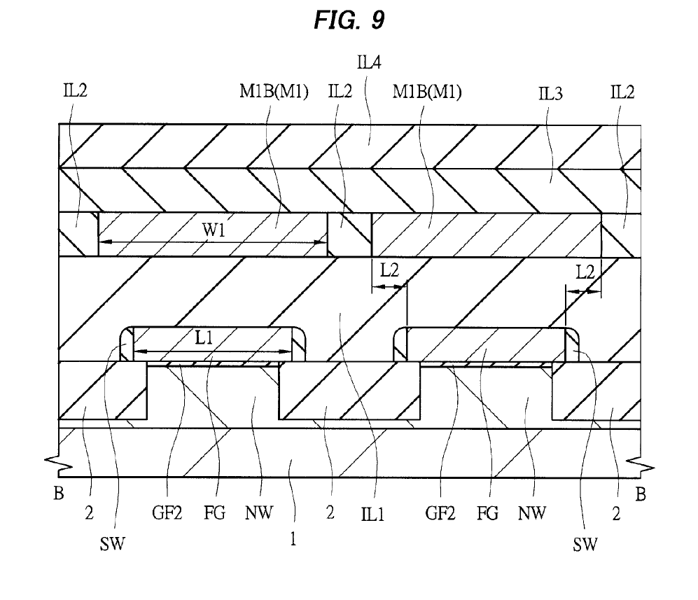

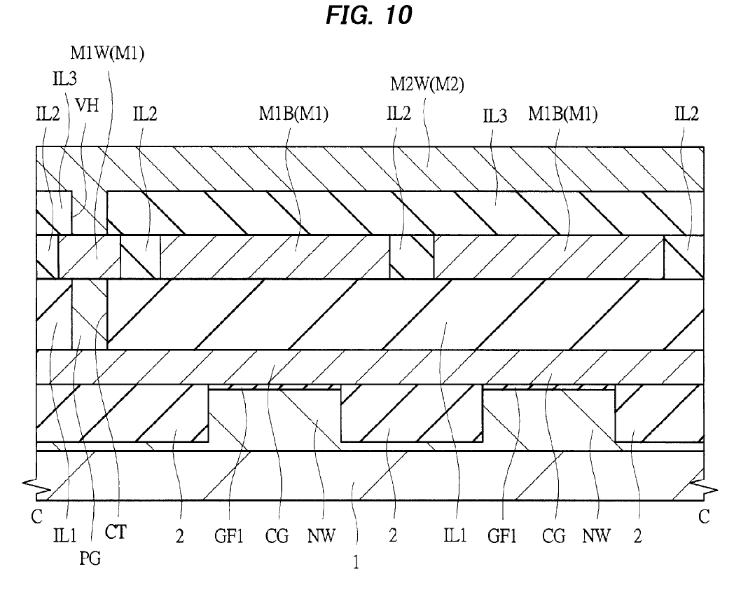

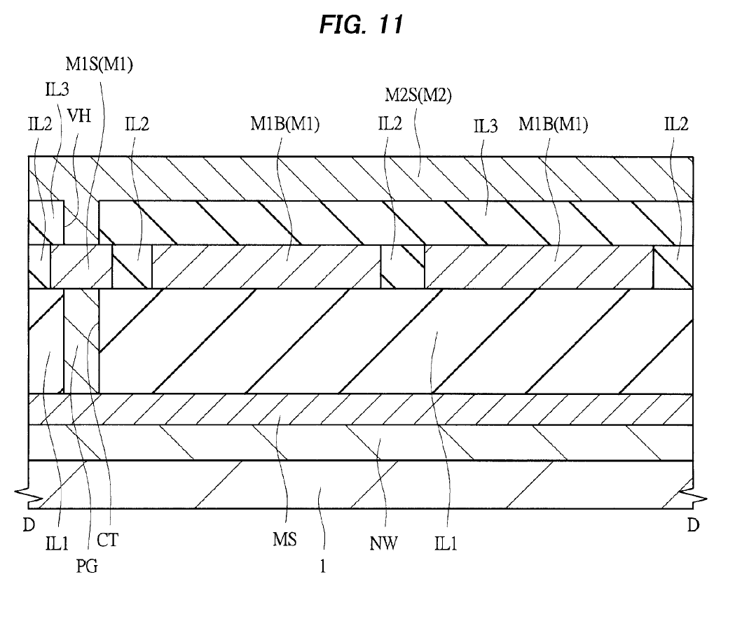

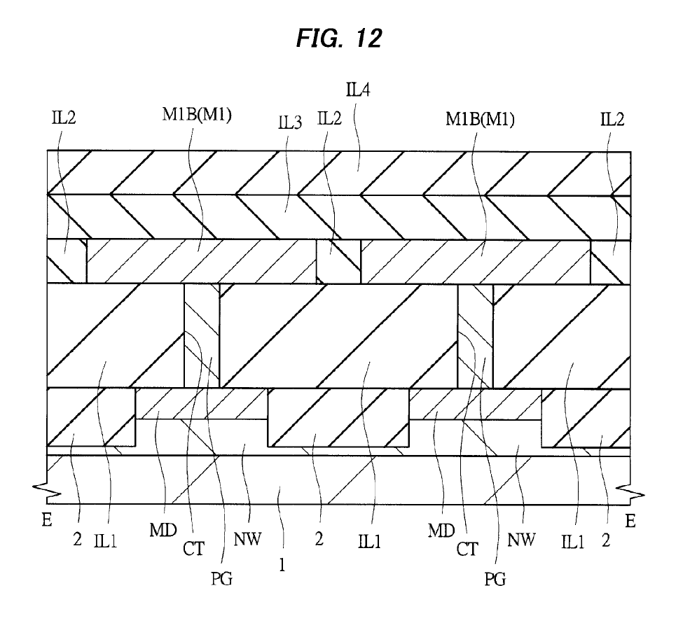

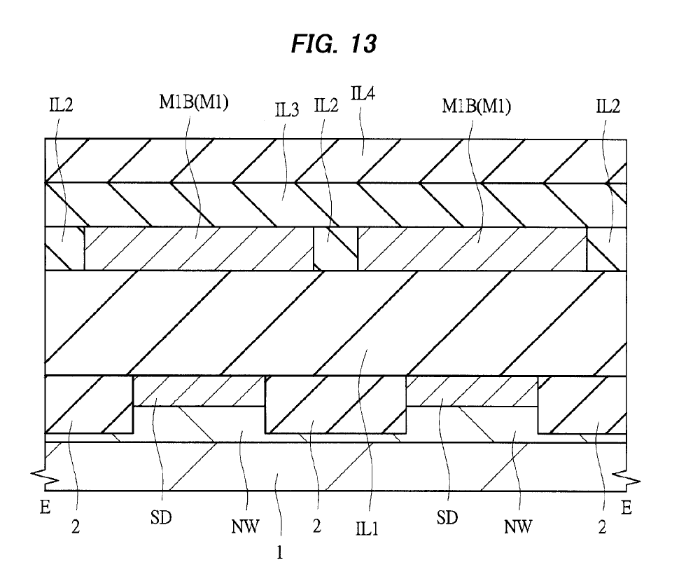

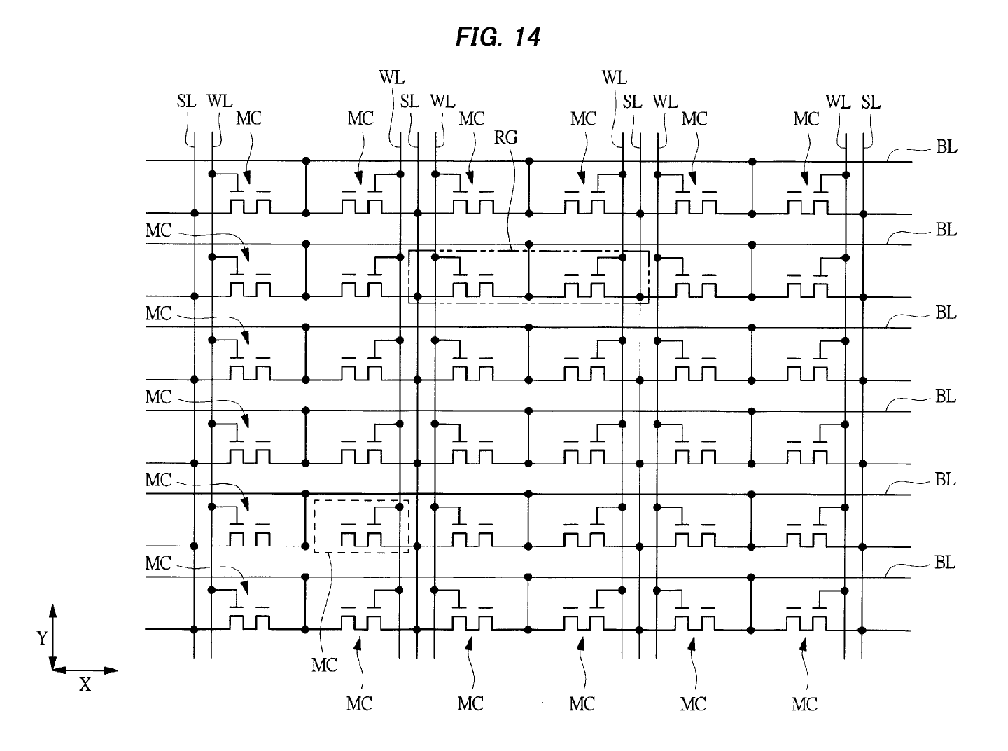

FIG. 1 to FIG. 5 are plan views of relevant parts of the semiconductor device in the present embodiment, FIG. 6 and FIG. 7 are partially enlarged plan views (plan views of relevant parts) of part of the regions (memory cell array regions) shown in FIG. 1 to FIG. 5, FIG. 8 to FIG. 13 are section views of relevant parts of the semiconductor device in the present embodiment, and FIG. 14 is a circuit diagram (equivalent circuit diagram) of the region (memory cell array region) shown in FIG. 1 to FIG. 5. The semiconductor device in the present embodiment has a memory cell array region in which a plurality of memory cells (nonvolatile memory cells) MC is arranged in an array (in an matrix) and FIG. 1 to FIG. 5 show plan views of relevant parts of the memory cell array region. In FIG. 1 to FIG. 5, the same region is shown. However, in FIG. 1, only a planar layout of an active region ACV defined by an element isolation region 2 is shown, in FIG. 2, a plan view, which is FIG. 1 to which a planar layout of a control gate electrode CG and a floating gate electrode FG are added, is shown, and in FIG. 3, a plan view, which is FIG. 2 to which a planar layout of a contact hole CT is added, is shown. In FIG. 4, a plan view, which is FIG. 3 to which a planar layout of a wire M1 (in the case of FIG. 4, a bit wire M1B) is added, is shown, and in FIG. 5, a plan view, which is FIG. 4 to which a planar layout of a wire M2 (in the case of FIG. 5, a source wire M2S and a word wire M2W) is added, is shown. FIG. 1 and FIG. 2 are plan views, however, in FIG. 1, hatching is attached to the active region ACV and in FIG. 2, hatching is attached to the control gate electrode CG, the floating gate electrode FG, and active regions (semiconductor regions MD, MS, SD) in order to make the drawings easy-to-see. In FIG. 4 and FIG. 5, the floating gate electrode FG located under the bit wire M1B is represented by a dotted line. In FIG. 6, an enlarged view of a region RG surrounded by an alternate long and two short dashes line in FIG. 2 is shown. In FIG. 7, a plan view, which is FIG. 6 to which a planar layout of the wire M1 (in the case of FIG. 7, the bit wire M1B) is added, is shown. FIG. 7 is a plan view, however, in order to make the drawing easy-to-see, hatching is attached to the wire M1 (in the case of FIG. 7, the bit wire M1B) and the layout of each member (control gate electrode CG, floating gate electrode FG, and active regions (semiconductor regions MD, MS, SD)) is represented by a dotted line. FIG. 8 substantially corresponds to a section view in a position of an A-A line shown in FIG. 2 (consequently, also to a section view in the position of the A-A line shown in FIG. 6). FIG. 9 substantially corresponds to a section view in a position of a B-B line shown in FIG. 2, FIG. 10 substantially corresponds to a section view in a position of a C-C line shown in FIG. 2, FIG. 11 substantially corresponds to a section view in a position of a D-D line shown in FIG. 2, FIG. 12 substantially corresponds to a section view in a position of an E-E line shown in FIG. 2, and FIG. 13 substantially corresponds to a section view in a position of an F-F line shown in FIG. 2.

As shown in FIG. 1 and FIG. 8 to FIG. 13, in a semiconductor substrate (semiconductor wafer) 1 including p-type single crystal silicon etc. having a specific resistance of, for example, about 1 to 10 Ωcm, the element isolation region 2 to isolate elements is formed and in the active region ACV isolated (defined) by the element isolation region 2, an n-type well NW is formed. In the n-type well NW in the memory cell array region, the memory cell of nonvolatile memory (nonvolatile memory cell) MC including a memory transistor and a control transistor (selection transistor) as shown in FIG. 2, FIG. 6, FIG. 8, etc., is formed. In FIG. 1 to FIG. 5 and FIG. 14, a region in which 36 memory cells MC in total, in six rows and six columns, are formed of the memory cell array region is extracted and shown, however, the number of the memory cells MC formed in the memory cell array region can be changed in a variety of ways as need arises.

In the memory cell array region, a plurality of the memory cells MC is formed in an array (in a matrix) and the memory cell array region is electrically isolated from other regions by the element isolation region 2. That is, the memory cell array region corresponds to a region in which the memory cells MC are formed (arranged, arrayed) in an array on the main surface of the semiconductor substrate 1. Consequently, in the memory cell array region, on the main surface of the semiconductor substrate 1, the memory cells (nonvolatile memory cells) MC are arranged in an array in an X direction (first direction) and in a Y direction (second direction). The Y direction (second direction) shown in FIG. 1 to FIG. 7, FIG. 14, etc., is a direction intersecting the X direction (first direction) and preferably, the Y direction (second direction) is a direction perpendicular to the X direction (first direction). The X direction and the Y direction are directions parallel with the main surface of the semiconductor substrate 1.

The memory cell MC, which is a nonvolatile memory formed in the memory cell array region, is a cell in which two MISFETs are coupled in series, that is, a control transistor (selection transistor) having the control gate electrode (selection gate electrode) CG and a memory transistor having the floating gate electrode (floating gate electrode for memory) FG are coupled in series. Hence, each memory cell MC has a memory transistor having the floating gate electrode FG and a control transistor coupled in series to the memory transistor.

Here, a MISFET (Metal Insulator Semiconductor Field Effect Transistor) comprising the floating gate electrode FG for accumulating charges and a gate insulating film thereunder is referred to as a memory transistor (storage transistor) and a MISFET comprising a gate insulating film and the control gate electrode CG is referred to as a control transistor (selection transistor, memory cell selection transistor). Consequently, the floating gate electrode FG is a gate electrode of a memory transistor, the control gate electrode CG is a gate electrode of a control transistor, and the floating gate electrode FG and the control gate electrode CG are gate electrodes configuring the memory cell MC, which is a nonvolatile memory.

The configuration of the memory cell MC is explained below specifically.

As shown in FIG. 8 to FIG. 13, the memory cell MC, which is a nonvolatile memory, has the p-type semiconductor region MS for source, the p-type semiconductor region MD for drain, and the p-type semiconductor region SD for source and drain formed in the n-type well NW in the semiconductor substrate 1. Then, the memory cell MC, which is a nonvolatile memory, further has the control gate electrode CG formed at the top of the semiconductor substrate 1 (n-type well NW) via an insulating film (gate insulating film) GF1 and the floating gate electrode FG formed at the top of the semiconductor substrate 1 (n-type well NW) via an insulating film (gate insulating film) GF2. The n-type well NW including the p-type semiconductor regions MS, MD, SD is formed in the active region ACV shown in FIG. 1.

The p-type semiconductor regions MS, MD, SD are formed in the n-type well NW of the semiconductor substrate 1, however, when viewed in the X direction, the semiconductor region SD is arranged between the semiconductor region MS and the semiconductor region MD. The control gate electrode CG is formed at the top of the semiconductor substrate 1 (n-type well NW) between the semiconductor region MS and the semiconductor region SD via the insulating film GF1 and extends in the Y direction over the main surface of the semiconductor substrate 1. The floating gate electrode FG is formed at the top of the semiconductor substrate 1 (n-type well NW) between the semiconductor region MD and the semiconductor region SD via the insulating film GF2 and extends in the Y direction over the main surface of the semiconductor substrate 1. Consequently, when viewed in the X direction, the control gate electrode CG, the semiconductor region SD, and the floating gate electrode FG are located between the semiconductor region MS and the semiconductor region MD, the control gate electrode CG is located on the side of the semiconductor region MS, the floating gate electrode FG is located on the side of the semiconductor region MD, and the semiconductor region SD is located between the control gate electrode CG and the floating gate electrode FG.

As described above, in each memory cell MC, the memory transistors and the control transistors are arranged side by side in the X direction and the same semiconductor region SD is shared by the source region of the memory transistor and the drain region of the control transistor.

The insulating film GF1 formed between the control gate electrode CG and the semiconductor substrate 1 (n-type well NW) (that is, the insulating film GF1 under the control gate electrode CG) functions as a gate insulating film of the control transistor. The insulating film GF2 between the floating gate electrode FG and the semiconductor substrate 1 (n-type well NW) (that is, the insulating film GF2 under the floating gate electrode FG) functions as a gate insulating film of the memory transistor. The insulating films GF1, GF2 can be formed by, for example, a silicon oxide film etc.

The semiconductor region MS is a semiconductor region that functions as the source region of the control transistor and the semiconductor region MD is a semiconductor region that functions as the drain region of the memory transistor. The semiconductor region SD is a semiconductor region that functions as both the drain region of the control transistor and the source region of the memory transistor. The semiconductor regions MS, MD, SD include semiconductor regions (p-type impurity diffusion layers) into which p-type impurities (for example, boron etc.) have been introduced, however, each may have an LDD (lightly doped drain) structure.

That is, the semiconductor region MS has a p⁻-type semiconductor region MSb and a p⁺-type semiconductor region MSa having an impurity concentration higher than that of the p⁻-type semiconductor region MSb, the semiconductor region MD has a p⁻-type semiconductor region MDb and a p⁺-type semiconductor region MDa having an impurity concentration higher than that of the p⁻-type semiconductor region MDb, and the semiconductor region SD has a p⁻-type semiconductor region SDb and a p⁺-type semiconductor region SDa having an impurity concentration higher than that of the p⁻-type semiconductor region SDb. The p⁺-type semiconductor region MSa has a greater joint depth and a higher impurity concentration than those of the p⁻-type semiconductor region MSb, the p⁺-type semiconductor region MDa has a greater joint depth and a higher impurity concentration than those of the p⁻-type semiconductor region MDb, and the p⁺-type semiconductor region SDa has a greater joint depth and a higher impurity concentration than those of the p⁻-type semiconductor region SDb. Over the sidewalls of the floating gate electrode FG and the control gate electrode CG, a sidewall insulating film (sidewall, sidewall spacer) SW including an insulator (insulating film), such as silicon oxide, is formed.

The p⁻-type semiconductor region MSb of the semiconductor region MS is formed in a self-alignment manner with respect to the sidewall of the control gate electrode CG and the p⁺-type semiconductor region MSa of the semiconductor region MS is formed in a self-alignment manner with respect to the side surface of the sidewall insulating film SW over the sidewall of the control gate electrode CG. Hence, the p⁻-type semiconductor region MSb having a low concentration is formed under the sidewall insulating film SW over the sidewall of the control gate electrode CG and the p⁺-type semiconductor region MSa having a high concentration is formed outside the p⁻-type semiconductor region MSb having a low concentration. Consequently, the p⁻-type semiconductor region MSb having a low concentration is formed so as to neighbor the channel region of the control transistor (channel region formed under the control gate electrode CG) and the p⁺-type semiconductor region MSa having a high concentration is formed so as to come into contact with the p⁻-type semiconductor region MSb having a low concentration and to be separated from the channel region of the control transistor (channel region formed under the control gate electrode CG) by an amount corresponding to the p⁻-type semiconductor region MSb.

The p⁻-type semiconductor region MDb of the semiconductor region MD is formed in a self-alignment manner with respect to the sidewall of the floating gate electrode FG and the p⁺-type semiconductor region MDa of the semiconductor region MD is formed in a self-alignment manner with respect to the side surface of the sidewall insulating film SW over the sidewall of the floating gate electrode FG. Hence, the p⁻-type semiconductor region MDb having a low concentration is formed under the sidewall insulating film SW over the sidewall of the floating gate electrode FG and the p⁺-type semiconductor region MDa having a high concentration is formed outside the p⁻-type semiconductor region MDb having a low concentration. Consequently, the p⁻-type semiconductor region MDb having a low concentration is formed so as to neighbor the channel region of the memory transistor (channel region formed under the floating gate electrode FG) and the p⁺-type semiconductor region MDa having a high concentration is formed so as to come into contact with the p⁻-type semiconductor region MDb having a low concentration and to be separated from the channel region of the memory transistor (channel region formed under the floating gate electrode FG) by an amount corresponding to the p⁻-type semiconductor region MDb.

The p⁻-type semiconductor region SDb of the semiconductor region SD is formed in a self-alignment manner with respect to the sidewall of the control gate electrode CG and the sidewall of the floating gate electrode FG and the p⁺-type semiconductor region SDa of the semiconductor region SD is formed in a self-alignment manner with respect to the side surface of the sidewall insulating film SW over the sidewall of the control gate electrode CG and the side surface of the sidewall insulating film SW over the sidewall of the floating gate electrode FG. Hence, the p⁻-type semiconductor region SDb having a low concentration is formed under the sidewall insulating film SW over the sidewall of the control gate electrode CG and under the sidewall insulating film SW over the sidewall of the floating gate electrode FG and the p⁺-type semiconductor region SDa having a high concentration is formed outside the p⁻-type semiconductor region SDb having a low concentration. Consequently, the p⁻-type semiconductor region SDb having a low concentration is formed in a region neighboring the channel region of the control transistor (channel region formed under the control gate electrode CG) and a region neighboring the channel region of the memory transistor (channel region formed under the floating gate electrode FG). Then, the p⁺-type semiconductor region SDa having a high concentration is formed so as to come into contact with the p⁻-type semiconductor region SDb having a low concentration and to be separated from the channel region of the control transistor (channel region formed under the control gate electrode CG) by an amount corresponding to the p⁻-type semiconductor region SDb and to be separated from the channel region of the memory transistor (channel region formed under the floating gate electrode FG) by an amount corresponding to the p⁻-type semiconductor region SDb.

Under the insulating film GF1 under the control gate electrode CG, the channel region of the control transistor is formed and under the insulating film GF2 under the floating gate electrode FG, the channel region of the memory transistor is formed. In each memory cell MC, the channel length direction (gate length direction) of the control transistor and the memory transistor is the X direction and the channel width direction (gate width direction) of the control transistor and the memory transistor in each memory cell MC is the Y direction.

The control gate electrode CG is formed by an electrical conductor (electrically conductive film), however, preferably, formed by a silicon film, such as p-type polysilicon (polycrystal silicon into which impurities are introduced, doped polysilicon). The floating gate electrode FG is formed by an electrical conductor (electrically conductive film), however, preferably, formed by a silicon film, such as p-type polysilicon (polycrystal silicon into which impurities are introduced, doped polysilicon). Specifically, the control gate electrode CG and the floating gate electrode FG are formed by a patterned silicon film and into which impurities (preferably, p-type impurities) are introduced to achieve a low resistivity.

Over the semiconductor substrate 1, an insulating film (interlayer insulating film) IL1 is formed as an interlayer insulating film so as to cover the control gate electrode CG, the floating gate electrode FG, and the sidewall insulating film SW. The insulating film IL1 includes a single film of a silicon oxide film, a laminated film of a silicon nitride film and a silicon oxide film formed over the silicon nitride film so as to have a thickness greater than that of the silicon nitride film, or the like. The top surface of the insulating film IL1 is flattened.

In the insulating film IL1, the contact hole (opening, through-hole) CT is formed and in the contact hole CT, an electrically conductive plug PG is embedded as an electrically conductive part (conductive part for connection). The plug PG is formed by a thin barrier conductive film (for example, a titanium film, titanium nitride film, or laminated film thereof) formed at the bottom and over the sidewall of the contact hole CT and a main conductive film (for example, a tungsten film) formed over the barrier conductive film so as to fill in the contact hole CT. For the sake of simplification of the drawings, in FIG. 8, FIG. 10 to FIG. 12, the barrier conductive film and the main conductive film forming the plug PG are shown in an integrated manner.

The contact hole CT and the plug PG embedded therein are formed at the top etc. of the semiconductor region MD (p⁺-type semiconductor region MDa) for drain, the semiconductor region MS (p⁺-type semiconductor region MSa) for source, and the control gate electrode CG (word line). At the bottom of each contact hole CT, part of the main surface of the semiconductor substrate 1, for example, part of the semiconductor region MD (p⁺-type semiconductor region MDa) for drain, part of the semiconductor region MS (p⁺-type semiconductor region MSa) for source, part of the control gate electrode CG (word line), etc., are exposed and the plug PG comes into contact with the exposed part (exposed part at the bottom of the contact hole CT) and is coupled electrically thereto.

Over the insulating film IL1 in which the plug PG is embedded, the wire (wiring layer) M1 forming a first wiring layer, which is a wiring layer in a first layer (lowermost layer), is formed. The wire M1 is, for example, a damascene wire (embedded wire), and embedded in a wire groove provided in an insulating film IL2 formed over the insulating film IL1. In the case where a damascene wire (embedded wire) formed by the damascene method is used as the wire M1, for example, a copper wire (embedded copper wire) may be used. The wire M1 is electrically coupled with the semiconductor region MD (p⁺-type semiconductor region MDa) for drain, the semiconductor region MS (p⁺-type semiconductor region MSa) for source, the control gate electrode CG (word line), etc., via the plug PG.

The semiconductor device in the present embodiment is a semiconductor device having a plurality of wiring layers (multilayer wiring structure) formed over the semiconductor substrate 1 and the wire M1 is a wire formed in the lowermost wiring layer (hereinafter, referred to as a first wiring layer) of the wiring layers (multilayer wiring structure) and the wire M2 is a wire formed in the second wiring layer from the bottom (hereinafter, referred to as a second wiring layer) of the wiring layers (multilayer wiring structure). In FIG. 4, FIG. 7 to FIG. 13, as the wire M1, the bit wire (wire for bit line) M1B is shown, which is electrically coupled to the semiconductor region MD (p⁺-type semiconductor region MDa) for drain via the plug PG.

Over the insulating film IL2 in which the wire M1 is embedded, the wire (wiring layer) M2 forming the second wiring layer, which is a second wiring layer, is formed. The wire M2 is, for example, a damascene wire (embedded wire), and over the insulating film IL2 in which the wire M1 is embedded, insulating films IL3, IL4 are formed in order from the bottom and the wire M2 is embedded in a wire groove provided in the insulating film IL4. When a damascene wire (embedded wire) formed by the damascene method is used as the wire M2, for example, a copper wire (embedded copper wire) may be used. As the wire M2, a dual damascene wire is used and in this case, it is electrically coupled with the wire M1 via a via part (conductive part embedded in a hole part VH formed in the insulating film IL3) formed integrally with the wire M2. When the wire M2 is a single damascene wire, the wire M2 and the via part (conductive part embedded in the hole part VH formed in the insulating film IL3) formed under the wire M2 are formed in different processes.

In FIG. 5, FIG. 10 and FIG. 11, as the wire M2, the word wire (wire for word line) M2W electrically coupled to the control gate electrode CG and the source wire (wire for source line) M2S electrically coupled to the semiconductor region MS (p⁺-type semiconductor region MSa) for source are shown. That is, as shown in FIG. 10, the word wire M2W is electrically coupled to a wire (wiring part) M1W via a via part (conductive part embedded in the hole part VH formed in the insulating film IL3) formed integrally with the word wire M2W and the word wire M2W is electrically coupled with the control gate electrode CG by the wire M1W being electrically coupled with the control gate electrode CG via the plug PG. As shown in FIG. 11, the source wire M2S is electrically coupled to a wire (wiring part) M1S via a via part (conductive part embedded in the hole part VH formed in the insulating film IL3) formed integrally with the word wire M2S and the source wire M2S is electrically coupled with the semiconductor region MS for source by the wire M1S being electrically coupled with the semiconductor region MS for source via the plug PG. The wires M1S, M1W are formed by the wire M1 formed in the first wiring layer and the wire M1S is a wire used to draw up the semiconductor region MS for source to the source wire M2S in the second wiring layer and the wire M1W is a wire used to draw up the control gate electrode CG to the word wire M2W in the second wiring layer.

Over the insulating film IL4 in which the wire M2 is embedded, a wiring layer (wire) in an upper layer and an insulating film are also formed, however, the schematic representation and explanation thereof are omitted here. The wires M1, M2 and wires in layers upper than those are not limited to the damascene wire (embedded wire) and can be formed by patterning an electrically conductive film for wiring, and for example, a tungsten wire or aluminum wire may be used.

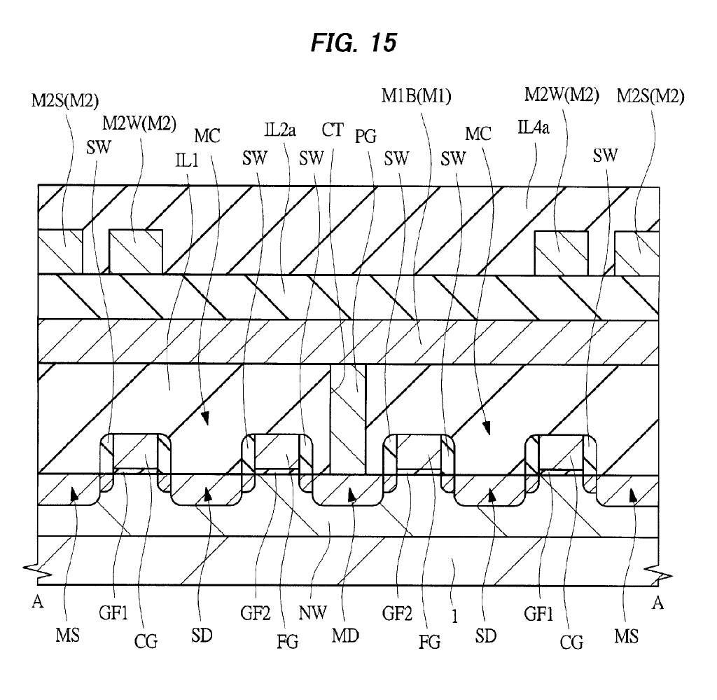

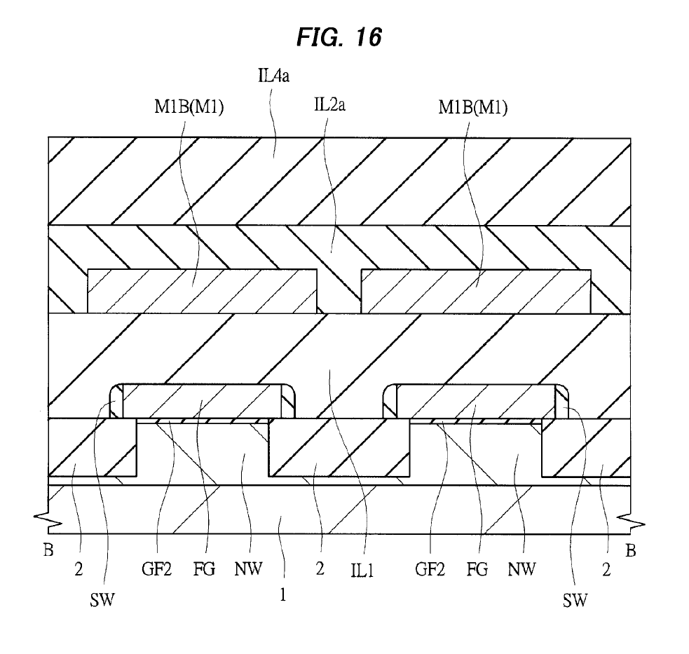

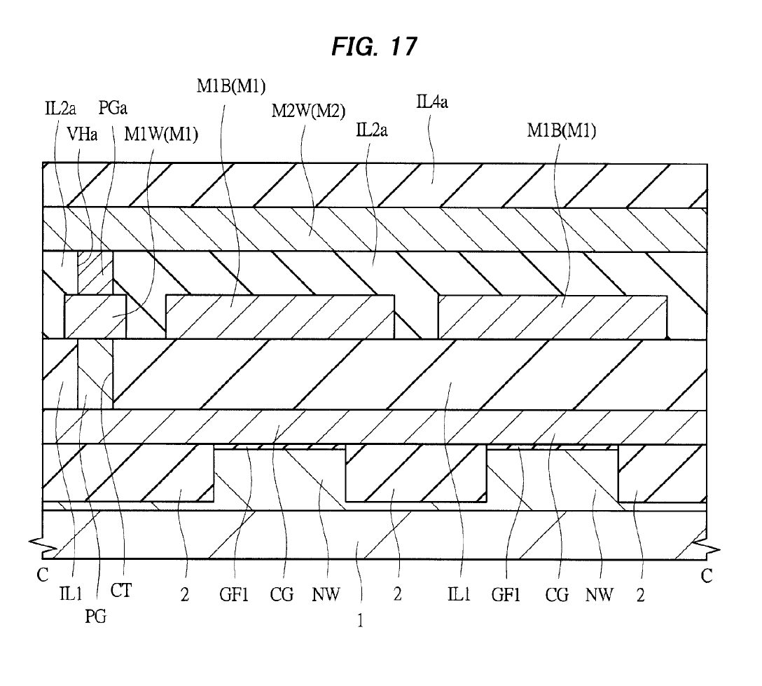

In FIG. 15 to FIG. 17, section views of relevant parts of the semiconductor device in the present embodiment when the wires M1, M2 are formed by patterning an electrically conductive film for wiring are shown and FIG. 15 corresponds to FIG. 8, FIG. 16 to FIG. 9, and FIG. 17 to FIG. 10, respectively.

In the case in FIG. 15 to FIG. 17, over the insulating film IL1 in which the plug PG is embedded, the wire M1 (including the bit wire M1B) is formed by forming an electrically conductive film for wiring and patterning the electrically conductive film and an insulating film IL2a, which is an interlayer insulating film, is formed so as to cover the wire M1. In the insulating film IL2a, a hole part (through-hole, opening) VHa is formed and in the hole part VHa, an electrically conductive plug (conductive part for connection) PGa similar to the plug PG is embedded. Over the insulating film IL2a in which the plug PGa is embedded, the wire M2 (including the source wire M2S and word wire M2W) is formed by forming an electrically conductive film for wiring and patterning the electrically conductive film and an insulating film IL4a, which is an interlayer insulating film, is formed so as to cover the wire M2. Not only in the present embodiment but also in second to tenth embodiments, to be described later, the wires M1, M2 may be formed by the damascene method or formed by patterning an electrically conductive film for wiring.

Next, a relationship between the memory cells MC configuring a memory cell array is explained.

As also shown in FIG. 2 and FIG. 14, a plurality of the memory cells MC, which is a nonvolatile memory, is formed in an array on the main surface (more specifically, in the memory cell array region) of the semiconductor substrate 1. That is, in FIG. 2 and FIG. 14, the region surrounded by the dotted line configures one memory cell MC and the memory cell array region is formed by arranging the memory cells MC in an array (in a matrix) in the X direction and the Y direction. In the region shown in FIG. 7 and FIG. 8 (region corresponding to the region RG in FIG. 2), the two memory cells MC neighboring in the X direction are formed and they share the drain region (semiconductor region MD). Then, the region RG configured by the two memory cells MC that share the drain region (semiconductor region MD) forms a unit region of repetition and the unit regions (regions RG) are arranged repeatedly in the X direction and the Y direction and thereby the memory cell array region is formed.

Hence, in each memory cell MC, the semiconductor region MD for drain, the floating gate electrode FG, the semiconductor region SD, the control gate electrode CG, and the semiconductor region MS for source are arranged side by side in the X direction and as can also be seen from FIG. 2, the semiconductor region MD for drain is shared by the two memory cells MC neighboring in the X direction with the semiconductor region MD sandwiched in between. Further, the semiconductor region MS for source is also shared by the two memory cells MC neighboring in the X direction with the semiconductor region MS sandwiched in between.

As also shown in FIG. 2, among the memory cells MC arranged in an array (in a matrix) in the X direction and the Y direction, the control gate electrodes CG of the memory cells MC arranged side by side in the Y direction are formed integrally linked to one another in the Y direction. That is, one control gate electrode CG extending in the Y direction in FIG. 2 forms the control gate electrodes of the memory cells MC arranged side by side in the Y direction and the control gate electrodes CG extending in the Y direction are arranged side by side in the X direction in the number corresponding to the number of the memory cells MC arranged in the X direction. Consequently, each control gate electrode CG extends in the Y direction in FIG. 2 and functions both as a control gate electrode of the memory cells MC arranged side by side in the Y direction in FIG. 2 and as a word line WL (word line W is shown in FIG. 14) that electrically couples the control gate electrodes of the memory cells MC arranged side by side in the Y direction in FIG. 2.

As also shown in FIG. 2, the floating gate electrodes FG of the memory cells MC arranged in an array in the X direction and the Y direction are not linked but isolated. That is, the independent floating gate electrode FG is provided for each memory cell MC. Hence, the floating gate electrode FG extends in the Y direction and the dimension (length L1) of the floating gate electrode FG in the Y direction is greater than the dimension (width W2) of the floating gate electrode FG in the X direction (L1>W2), however, the floating gate electrodes FG of the memory cells MC arranged side by side in the Y direction are not linked to one another. As can also be seen from FIG. 6 and FIG. 9, the regions in the vicinity of both end parts in the Y direction of each floating gate electrode FG are located over the element isolation region 2 and regions inside the regions (regions in the vicinity of both end parts in the Y direction) are located over the gate insulating film GF2 over the n-type well NW. To each floating gate electrode FG, the wires M1, M2 are not coupled.

As also shown in FIG. 2, the semiconductor regions MS for source of the memory cells MC arranged side by side in the Y direction in FIG. 2 among the memory cells MC arranged in an array in the X direction and Y direction are linked to one another in the Y direction and formed integrally. That is, the semiconductor region MS extending in the Y direction in FIG. 2 forms each source region of the memory cells MC arranged side by side in the Y direction in FIG. 2 and a plurality of the semiconductor regions MS extending in the Y direction is arranged side by side in the X direction. Consequently, each semiconductor region MS extends in the Y direction in FIG. 2 and functions both as a source region of the memory cells MC arranged side by side in the Y direction in FIG. 2 and as a source line SL (source line SL is shown in FIG. 14) that electrically couples the source regions of the memory cells MC arranged side by side in the Y direction in FIG. 2.

As also shown in FIG. 2, among the memory cells MC arranged in an array in the X direction and the Y direction, the semiconductor regions MD for drain of the memory cells MC arranged side by side in the Y direction are located on the same straight line in the Y direction, however, they are not linked to one another and electrically isolated by the element isolation region 2 being interposed in between.

As also shown in FIG. 2, among the memory cells MC arranged in an array in the X direction and the Y direction, the semiconductor regions SD of the memory cells MC arranged side by side in the Y direction are located on the same straight line in the Y direction, however, they are not linked to one another and electrically isolated by the element isolation region 2 being interposed in between.

The bit wire M1B is, as can also be seen from FIG. 4, FIG. 7 to FIG. 13, is a wire formed in the lowermost wiring layer (first wiring layer) of the wiring layers (multilayer wiring structure) formed over the semiconductor substrate 1 and extends in the X direction as shown in FIG. 4. The bit wire M1B is a wire configuring a bit line BL (bit line BL is shown in FIG. 14). That is, the bit wire M1B is a wire (bit line, wire for bit line) that (electrically) couples the semiconductor regions MD for drain of the memory cells MC arranged side by side in the X direction among the memory cells MC arranged in an array in the X direction and the Y direction. That is, the bit wire M1B is a wire that couples the drain regions (semiconductor regions MD) of the memory transistors of the memory cells MC arranged in the X direction. Hence, the bit wire M1B extends over the memory cells MC arranged side by side in the X direction and under the bit wire M1B, the semiconductor region MD for drain, the floating gate electrode FG, the semiconductor region SD, the control gate electrode CG, and the semiconductor region MS for source of each memory cell MC arranged side by side in the X direction are arranged. The bit wire M1B extends over each semiconductor region MD of the memory cells MC arranged side by side in the X direction, and therefore, can be electrically coupled to the semiconductor region MD via the plug PG. Hence, the semiconductor regions MD of the memory cells MC arranged side by side in the X direction are in the state of being electrically coupled to one another via the plug PG and the bit wire M1B.

As described above, the semiconductor regions MS for source of the memory cells MC arranged side by side in the Y direction among the memory cells MC arranged in an array in the X direction and the Y direction are linked to one another in the Y direction and the semiconductor regions MS linked in the Y direction are electrically coupled to the source wire M2S via the plug PG and the wire M1S. As can also be seen from FIG. 5, FIG. 8, and FIG. 11, the source wire M2S is a wire formed in the second wiring layer from the bottom (second wiring layer), that is, in a wiring layer one layer upper (second wiring layer) than the wire M1 (first wiring layer) of the wiring layers (multilayer wiring structure) formed over the semiconductor substrate 1 and extends in the Y direction over the semiconductor region MS as shown in FIG. 5.

As described above, the control gate electrodes CG of the memory cells MC arranged side by side in the Y direction among the memory cells MC arranged in an array in the X direction and the Y direction are linked in the Y direction and the control gate electrodes CG linked in the Y direction are electrically coupled to the word wire M2W via the plug PG and the wire M1W. As can also be seen from FIG. 5, FIG. 8, and FIG. 10, the word wire M2W is a wire formed in a wiring layer second from the bottom (second wiring layer), that is, formed in a wiring layer one layer upper (second wiring layer) than the wire M1 (first wiring layer) of the wiring layers (multilayer wiring structure) formed over the semiconductor substrate 1 and as shown in FIG. 5, extends in the Y direction over the control gate electrode CG. The wires M1S, M1W are wires formed in the same layer (first wiring layer) as that of the bit wire M1B, however, arranged so as to avoid the bit wire M1B so that they do not come into contact with the bit wire M1B.

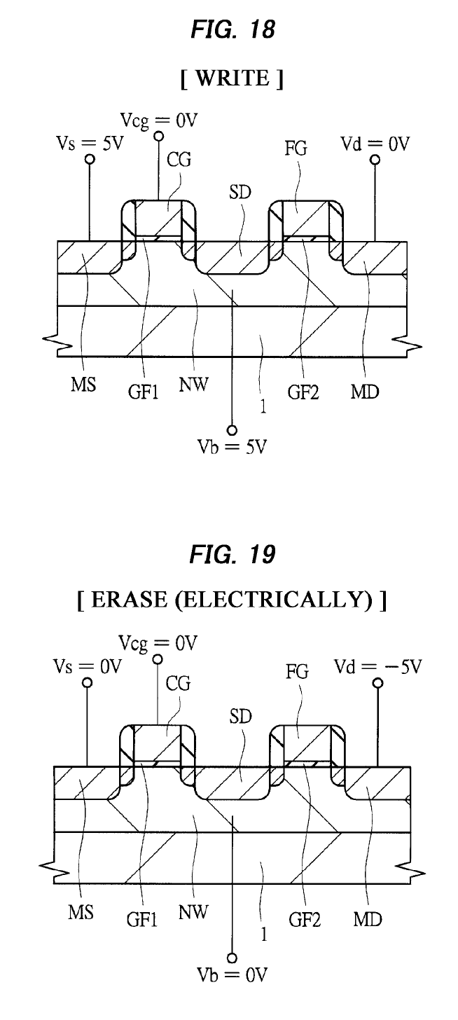

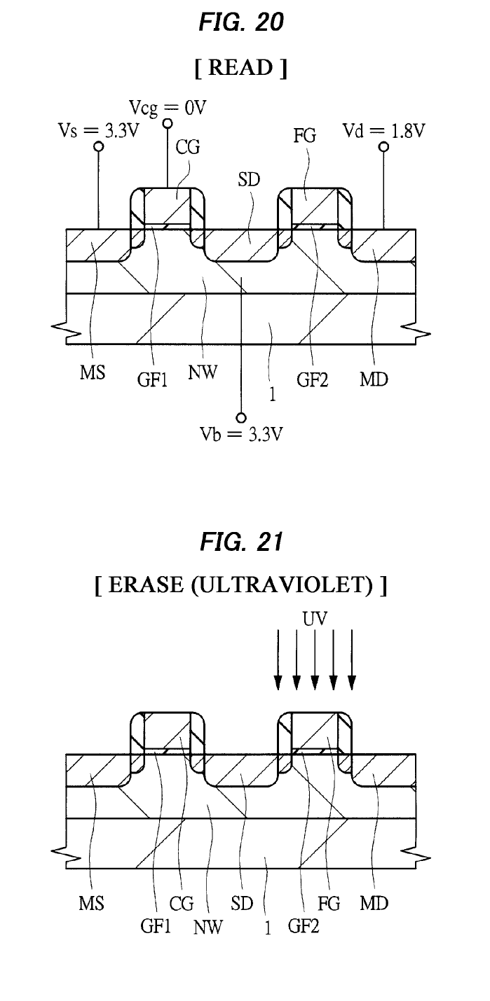

Next, the operation of the semiconductor device in the present embodiment is explained. FIG. 18 to FIG. 21 are explanatory diagrams showing operation examples of the semiconductor device in the present embodiment, wherein FIG. 18 schematically shows “write”, FIG. 19 “erase (electrically)”, FIG. 20 “read”, and FIG. 21 “erase (erase by ultraviolet)”, respectively. Further, FIG. 18 to FIG. 20 describe a voltage Vd to be applied to the drain region (semiconductor region MD) of a selected memory cell, a voltage Vcg to be applied to the control gate electrode CG, a voltage Vs to be applied to the source region (semiconductor region MS), and a base voltage Vb to be applied to the n-type well NW at each time of “write” (FIG. 18), “erase” (FIG. 19), and “read” (FIG. 20), respectively. The voltages shown in FIG. 18 to FIG. 20 are examples of the conditions of applied voltage and the voltages are not limited to those and can be changed in a variety of ways as need arises. In the present embodiment, injection of carriers (holes, here) into the floating gate electrode FG of the memory transistor is defined as “write”.

When performing “write”, holes are injected into the floating gate electrode FG of a selected memory cell by applying, for example, the voltage shown in FIG. 18, to each part of the selected memory cell on which “write” is performed. Here, an electric current flows between source and drain (between the semiconductor regions MS, MD) and at the same time, hot holes are injected into the floating gate electrode FG from the side of the drain region (semiconductor region MD).

When performing “erase”, holes are drawn out from the floating gate electrode FG of the selected memory cell to the drain region (semiconductor region MD) by applying, for example, the voltage shown in FIG. 19, to each part of the selected memory cell on which “erase” is performed.

When performing “read”, for example, the voltage shown in FIG. 20 is applied to each part of the selected memory cell on which “read” is performed. Due to this, the control transistor of the selected memory cell (selection transistor) enters the ON state. At this time, when the state is one where the holes are accumulated in the floating gate electrode FG (that is, a write state), the memory transistor also enters the ON state, and therefore, an electric current (read current) flows between the source region (semiconductor region MS) and the drain region (semiconductor region MD). On the other hand, when the state is one where holes are hardly accumulated in the floating gate electrode FG (that is, an erase state), the memory transistor enters the OFF state, and therefore, an electric current (read current) hardly flows between the source region (semiconductor region MS) and the drain region (semiconductor region MD). Therefore, it is possible to distinguish the write state from the erase state.

It is also possible to perform “erase” by using ultraviolet beams as, for example, shown schematically in FIG. 21. In this case, by irradiating the memory cell array region with ultraviolet beams UV, the holes accumulated in the floating gate electrode FG are excited and caused to tunnel the gate insulating film (insulating film GF2) under the floating gate electrode FG, and thereby, the state where holes are hardly accumulated in the floating gate electrode FG (that is the erase state) can be brought about. At the time of erase by ultraviolet beams, power is not consumed but erase is performed on all the bits at one time.

Next, the main features of the semiconductor device in the present embodiment are explained.

The inventors of the present invention have examined the semiconductor device in which memory cells having a floating gate electrode are arranged in an array and found that such a problem as below arises.

That is, over the main surface of the semiconductor substrate, a plurality of interlayer insulating films is formed and it is found that when water or ions (for example, cations such as Na⁺ ions) diffuse from under these interlayer insulating films and reach the floating gate electrode, the holding characteristics of stored information of a nonvolatile memory are deteriorated. The reason for that is when water or ions that have diffused in the interlayer insulating film exist around the floating gate electrode of the memory cell on which write is performed, the charges accumulated in the floating gate electrode are canceled by them and the charges that should be accumulated in the floating gate electrode seem less (the effective amount of charges accumulated in the floating gate electrode is reduced). When this phenomenon occurs, the threshold value of the memory transistor that uses the floating gate electrode as the gate electrode is changed and there is a possibility that the erase state is read erroneously when the memory cell on which write is performed is read. Hence, it is desired to suppress the diffusion of water or ions (for example, cations such as Na⁺ ions) from the interlayer insulating film in the upper layer to the floating gate electrode as much as possible in order to improve the holding characteristics of stored information of a nonvolatile memory.

Because of the above, in the present embodiment, the above-mentioned problem is solved by devising the bit wire M1B.

The bit wire M1B is a wire that couples the semiconductor regions MD for drain of the memory cells MC arranged side by side in the X direction and extends in the X direction. Each memory cell MC has the floating gate electrode FG, and therefore, the floating gate electrode FG is also located under the bit wire M1B. One of the main features of the present embodiment is that the width W1 (shown in FIG. 7 and FIG. 9) of the bit wire M1B is made greater than the length L1 (shown in FIG. 6 and FIG. 9) of the floating gate electrode FG (that is, W1>L1). Here, the length L1 of the floating gate electrode FG corresponds to the dimension of the floating gate electrode FG in the Y direction and the width W1 of the bit wire M1B corresponds to the dimension of the bit wire M1B in the Y direction. By making the width W1 of the bit wire M1B greater than the length L1 of the floating gate electrode FG (W1>L1), the state becomes one where the floating gate electrode FG is covered with the bit wire M1B when viewed in a planar manner.

Here, “to view in a planar manner” or “in a planar manner” is assumed to indicate the case where something is viewed in a plane parallel with the main surface of the semiconductor substrate 1. The “vertical direction” is assumed to indicate a direction parallel with the direction of thickness of the semiconductor substrate 1. This also applies to the present first embodiment and the second to tenth embodiments below.

When viewed in the vertical direction, between the floating gate electrode FG and the bit wire M1B, the interlayer insulating film IL1 is interposed and the floating gate electrode FG is not in contact with the bit wire M1B. Hence, the floating gate electrode FG is not electrically coupled with the bit wire M1B. On the other hand, when viewed in a plane parallel with the main surface of the semiconductor substrate 1 (that is, when viewed in a planar manner), the floating gate electrode FG is covered with the bit wire M1B and the floating gate electrode FG is in the state where it is not exposed from the bit wire M1B. That is, each floating gate electrode FG is in the state where the whole is covered with the bit wire M1B and the bit wire M1B exists directly on the whole floating gate electrode FG. In other words, when viewed in a planar manner, each floating gate electrode FG is in the state of being included in the bit wire M1B in a planar manner. In further other words, the bit wire M1B is arranged outside each side of each floating gate electrode FG.

In the case, different from the present embodiment, where the wire M1 does not exist directly on the floating gate electrode FG, it is made easier for water or ions (for example, cations such as Na⁺ ions) to diffuse downward and reach the floating gate electrode FG from the insulating film in a layer upper than the insulating film IL1 (insulating films IL2, IL3, IL4 or insulating film in an upper layer) and as described above, this causes deterioration in the holding characteristics of stored information of a nonvolatile memory.

In contrast to this, in the present embodiment, the diffusion of water or ions (for example, cations such as Na⁺ ions) from the insulating film in a layer upper than the insulating film IL1 (insulating films IL2, IL3, IL4 or insulating film in an upper layer) to the floating gate electrode FG is prevented by the bit wire M1B. This is because water or ions (for example, cations such as Na⁺ ions) are easy to diffuse in the insulating film, however, hard to diffuse in a metal wire, such as a wire. By bringing about the state where the bit wire M1B is arranged above the floating gate electrode FG and the floating gate electrode FG is covered with the bit wire M1B when viewed in a planar manner, the bit wire M1B can prevent water or ions (for example, cations such as Na⁺ ions) from diffusing under the bit wire M1B, and therefore, it is possible to reduce the amount of water or the number of ions that reach the floating gate electrode FG. Hence, the charges accumulated in the floating gate electrode FG are appropriately held until the erase operation is performed, and therefore, it is possible to improve the holding characteristics of stored information of a nonvolatile memory. As a result, it is possible to improve the performance of the semiconductor device comprising a nonvolatile memory.

Further, in the present embodiment, the whole of each floating gate electrode FG is covered with the bit wire M1B, and therefore, when viewed in a planar manner, a distance L2 (shown in FIG. 7 and FIG. 9) from the end part of the floating gate electrode FG in the Y direction to the end part of the bit wire M1B in the Y direction is greater than zero (that is, L2>0). By increasing the distance L2, it is possible to further reduce the amount of water or the number of ions (for example, cations such as Na⁺ ions) that skirt the bit wire M1B and reach the floating gate electrode FG. From this viewpoint, when viewed in a planar manner, it is further preferable to set the distance L2 from the end part of the floating gate electrode FG in the Y direction to the end part of the bit wire M1B in the Y direction to 0.4 μm or more (that is, L2≧0.4 μm) and by doing so, it is possible to further improve the holding characteristics of stored information of a nonvolatile memory. Hence, it is recommended to design a width W1 of the bit wire M1B to be as great as possible (at least greater than the length L1 of the floating gate electrode FG, or further preferably, 0.8 μm or more longer than the length L1 of the floating gate electrode FG) while taking into consideration the wire width of the bit wire M1B that can be laid out (limit of the wire width).

It is preferable to design the relative position of the floating gate electrode FG and the bit wire M1B so that the center of the floating gate electrode FG in the Y direction is located in the center of the bit wire M1B in the Y direction when viewed in a planar manner. In this case, the above-mentioned length L2 is the same for both the end parts of the floating gate electrode FG in the Y direction. Due to this, it is possible to efficiently reduce the amount of water or the number of ions (for example, cations such as Na⁺ ions) that skirt the bit wire M1B and reach the floating gate electrode FG while somewhat suppressing an increase in the width W1 of the bit wire M1B. Due to this, it is also possible to make an attempt to increase the density of the memory cell array while improving the holding characteristics of stored memory of a nonvolatile memory.

Because the bit wire M1B also functions as the wire part in the first wiring layer (the wire part that suppresses the diffusion of water or ions to the floating gate electrode FG) that covers the floating gate electrode FG, it is made possible to achieve an efficient wire layout.

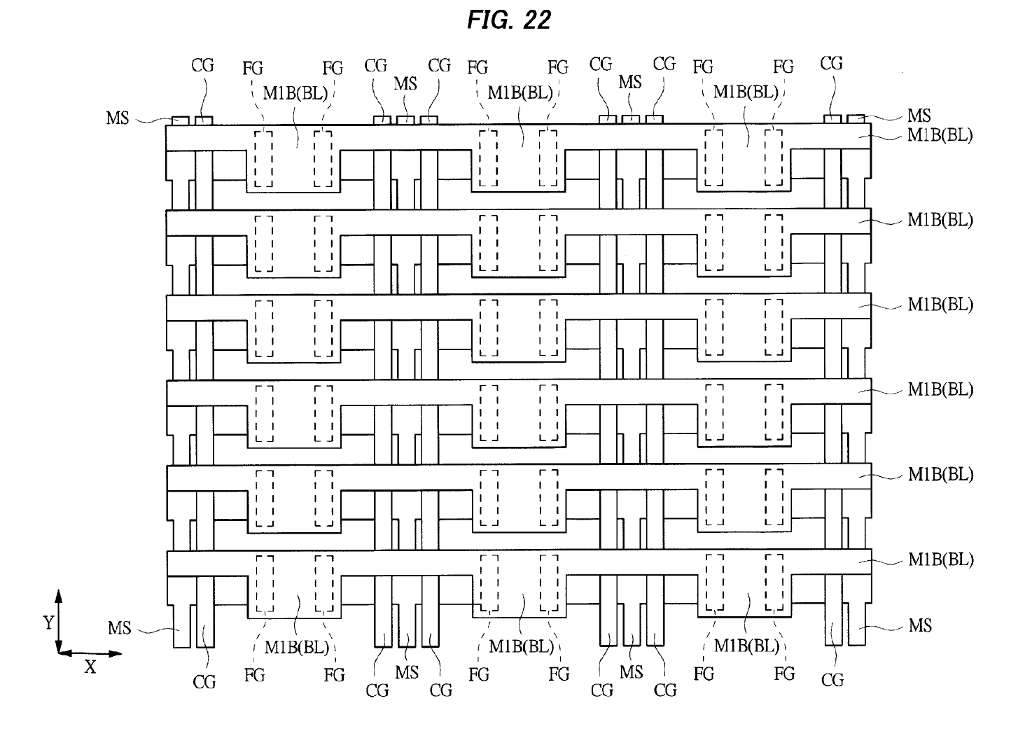

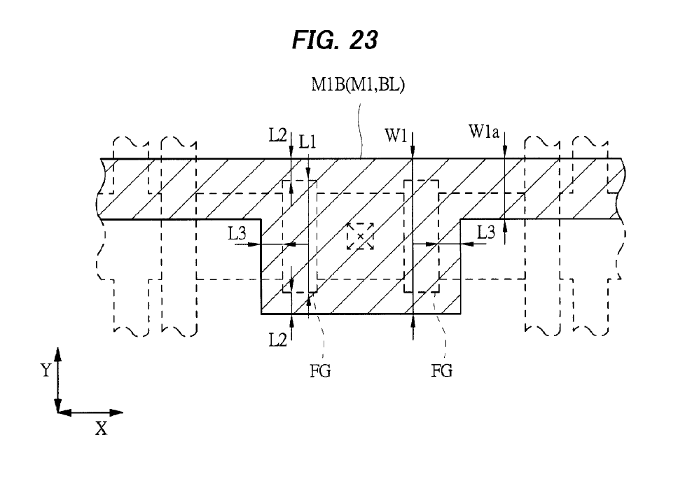

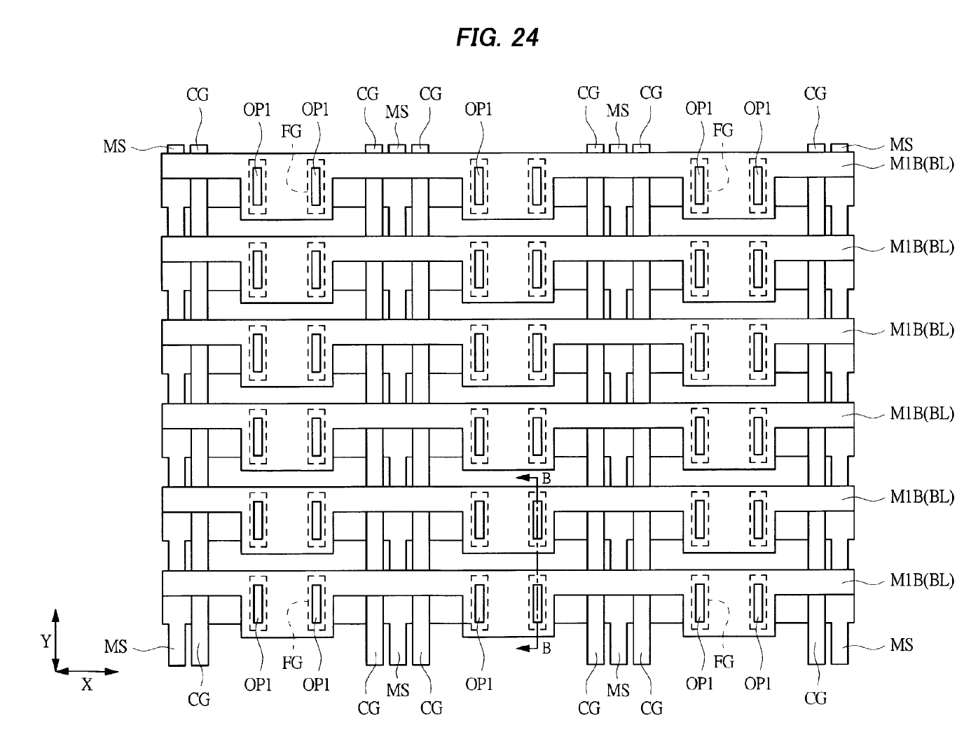

In the case of the present embodiment (FIG. 4 and FIG. 7), the wires M1 (bit wires M1B) are spread in the memory cell array region in a higher density than in the case of the second embodiment (FIG. 22 and FIG. 23), to be described later, and therefore, it is possible to further reduce the difference in level in layers upper than the wire M1.

### Second Embodiment

FIG. 22 and FIG. 23 are plan views of relevant parts of a semiconductor device in the present embodiment, wherein FIG. 22 corresponds to FIG. 4 in the first embodiment and FIG. 23 corresponds to FIG. 7 in the first embodiment.

In the case of the first embodiment, as also shown in FIG. 4 and FIG. 7, the bit wire M1B extends in the X direction with the same width W1 and the with of the bit wire M1B (dimension in the Y direction) is the same in every position in the X direction. In contrast to this, in the present embodiment, the width W1 of the part of the bit wire M1B extending over the floating gate electrode FG is the same as in the case of the first embodiment (FIG. 4 and FIG. 7), however, a width W1a (shown in FIG. 23) of a part distant from the floating gate electrode FG when viewed in a planar manner is set smaller than the width W1 (that is, W1a<W1). Other configurations of the present embodiment are the same as those in the first embodiment.

In the bit wire M1B in the first embodiment (FIG. 4 and FIG. 7), compared to the region nearer to the floating gate electrode FG when viewed in a planar manner, the region distant from the floating gate electrode FG acts less to suppress water or ions (for example, cations such as Na⁺ ions) from diffusing to the floating gate electrode FG. Hence, not only in the case of the bit wire M1B in the first embodiment (FIG. 4 and FIG. 7) but also in the case of the bit wire M1B in the present embodiment shown in FIG. 22 and FIG. 23, it is possible to reduce the amount of water or the number of ions that reach the floating gate electrode FG and to improve the holding characteristics of stored information of a nonvolatile memory. Consequently, it is possible to improve the performance of the semiconductor device comprising a nonvolatile memory.

The fact that the width W1 of the part of the bit wire M1B extending over the floating gate electrode FG is greater than the length L1 (dimension in the Y direction) of the floating gate electrode FG (W1>L1) is the same in the first embodiment and the present embodiment. The present embodiment differs from the first embodiment in the width of the part distant from the floating gate electrode FG when viewed in a planar manner. Hence, both in the first embodiment and in the present embodiment, each floating gate electrode FG is included in the bit wire M1B and the whole of each floating gate electrode FG is in the state of being covered with the bit wire M1B. In other words, the bit wire M1B is arranged outside each side of each floating gate electrode FG.

In the bit wire M1B in the present embodiment shown in FIG. 22 and FIG. 23, the whole of each floating gate electrode FG is covered with the bit wire M1B, and therefore, when viewed in a planar manner, the distance L2 and a distance L3 from the end part of the floating gate electrode FG to the end part of the bit wire M1B are greater, than zero (that is, L2, L3>0). By increasing the distances L2, L3, it is possible to further reduce the amount of water or the number of ions that skirt the bit wire M1B and reach the floating gate electrode FG. From this viewpoint, it is further preferable to set the distances L2, L3 from the end part (outer circumferential part) of the floating gate electrode FG to the end part (outer circumferential part) of the bit wire M1B to 0.4 μm or more (that is, L2, L3≧0.4 μm) and by doing so, it is possible to further improve the holding characteristics of stored information of a nonvolatile memory. Here, the distance L2 (shown in FIG. 23) corresponds to the distance from the end part of the floating gate electrode FG in the Y direction to the end part of the bit wire M1B in the Y direction when viewed in a planar manner and the distance L3 (shown in FIG. 23) corresponds to the distance from the end part of the floating gate electrode FG in the X direction to the end part of the bit wire M1B in the X direction when viewed in a planar manner.

What is common to the bit wire M1B in the first embodiment shown in FIG. 4 and FIG. 7 and to the bit wire M1B in the present embodiment shown in FIG. 22 and FIG. 23 is that the width W1 of the part of the bit wire M1B extending over the floating gate electrode FG is greater than the dimension L1 of the floating gate electrode FG in the Y direction (that is, W1>L1). Due to this fact, each floating gate electrode FG is brought into the sate of being included in the bit wire M1B in a planar manner and the amount of water or the number of ions that reach the floating gate electrode FG from the can be reduced by bit wire M1B, and therefore, it is possible to improve the holding characteristics of stored information of a nonvolatile memory.

### Third Embodiment

When performing the erase operation of a nonvolatile memory, there are cases where erase is performed electrically by applying a predetermined voltage to each part of the selected memory cell on which erase is performed as shown in FIG. 19 and where erase is performed by ultraviolet irradiation as shown in FIG. 21. In the semiconductor devices in the first and second embodiments, it is possible to perform the electrical erase operation appropriately. On the other hand, in the semiconductor devices in the first and second embodiments, it is also possible to perform erase itself by ultraviolet irradiation by utilizing the scattered ultraviolet beams inside the semiconductor device. That is, the ultraviolet beams skirt the bit wire M1B and reach the floating gate electrode FG, and therefore, the erase operation can be performed for the time being. However, in the state where the whole floating gate electrode FG is covered with the bit wire M1B, the ultraviolet beams are shielded by the bit wire M1B, and therefore, the ultraviolet beams cannot reach the floating gate electrode FG successfully and there is a possibility that the efficiency in the erase by ultraviolet irradiation is reduced. In this case, it is required to take measures to increase the ultraviolet irradiation time at the time of erase operation etc.

With the above-mentioned circumstances being taken into account, in the third embodiment and the fourth embodiment, to be described later, openings (OP1, OP2) are provided in the bit wire M1B and it is made possible for ultraviolet beams to reach the floating gate electrode FG through the openings (OP1, OP2). Due to this, it is possible to increase the efficiency in the erase operation by ultraviolet irradiation. The opening to be provided in the bit wire M1B is explained below specifically.

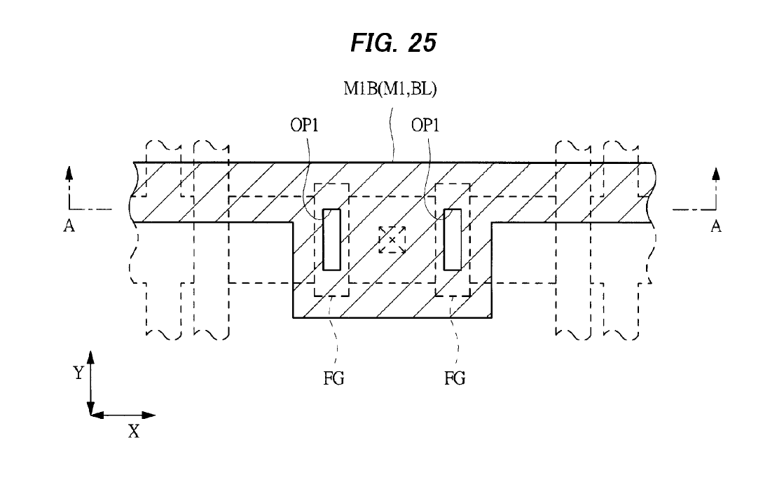

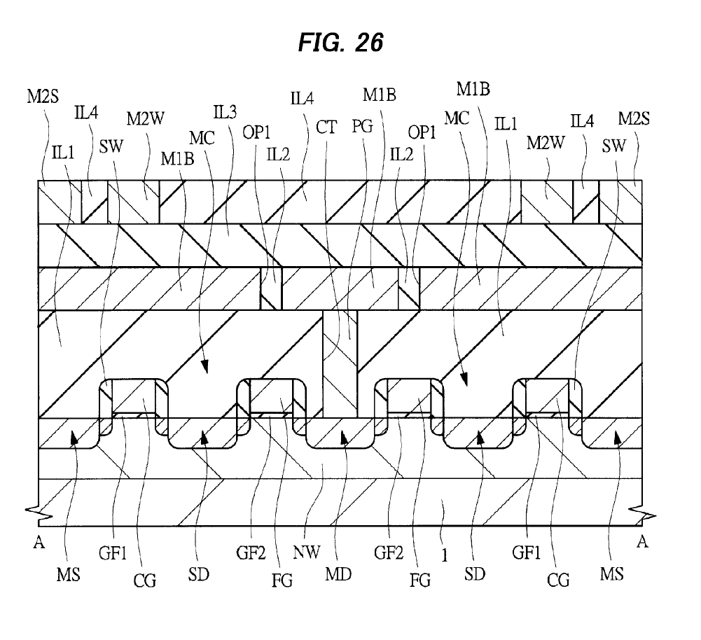

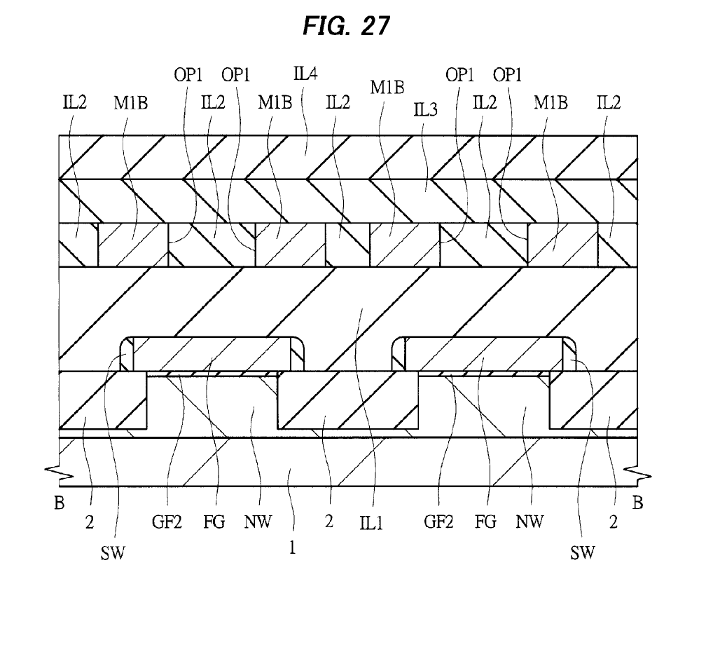

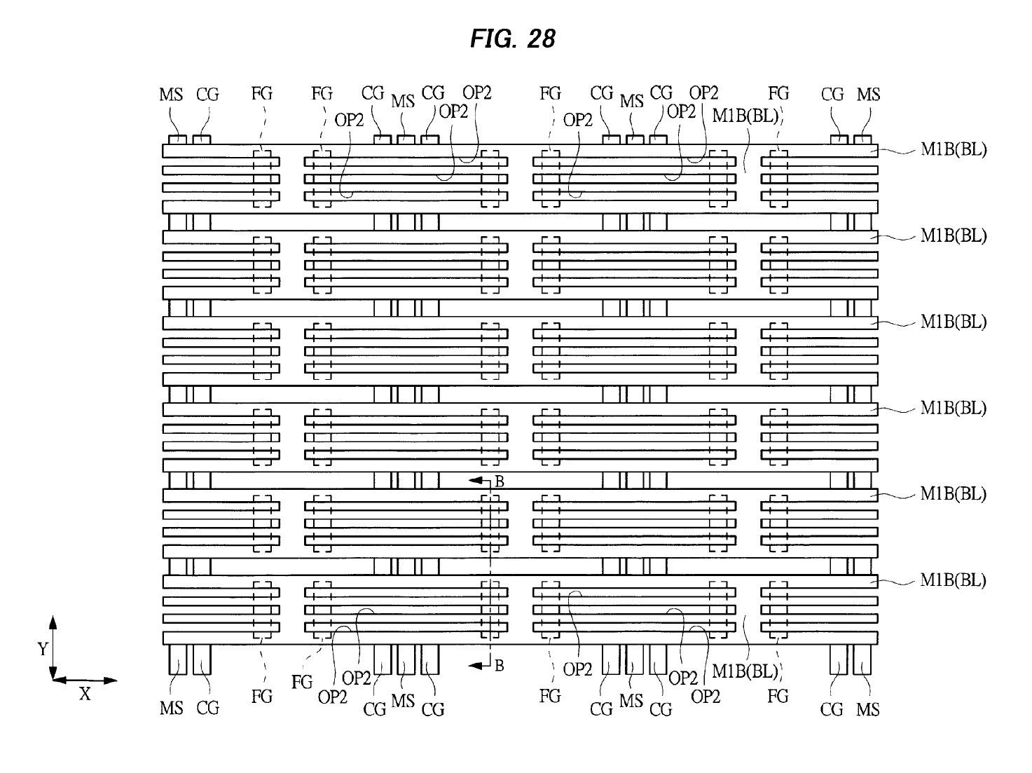

FIG. 24 and FIG. 25 are plan views of relevant parts of the semiconductor device in the present embodiment, wherein FIG. 24 corresponds to FIG. 22 in the second embodiment and FIG. 25 corresponds to FIG. 23 in the second embodiment. FIG. 26 and FIG. 27 are section views of relevant parts of the semiconductor device in the present embodiment, wherein FIG. 26 corresponds to FIG. 8 in the first embodiment and FIG. 27 corresponds to FIG. 9 in the first embodiment. Hence, FIG. 26 substantially corresponds to the section view in the position of the A-A line shown in FIG. 25 and FIG. 27 substantially corresponds to the section view in the position of the B-B line shown in FIG. 24.

The semiconductor device in the present embodiment shown in FIG. 24 to FIG. 27 has the same configuration as that of the semiconductor device in the second embodiment except for that the opening (through-hole) OP1 is provided in the bit wire M1B, and therefore, here, the opening OP1 is explained, which is the different point from the second embodiment (explanation of other parts is omitted).

In the present embodiment, the opening OP1 is provided in the bit wire M1B and this opening OP1 is formed so as to be included in the floating gate electrode FG when viewed in a planar manner. In other words, the opening OP1 is arranged inside each side of each floating gate electrode FG. That is, in each bit wire M1B, the opening OP1 is provided for each floating gate electrode FG existing thereunder and the planar dimensions (planar area) of each opening OP1 are smaller than the planar dimensions (planar area) of the floating gate electrode FG. As can also be seen from FIG. 25, the opening OP1 is included in a planar manner in the floating gate electrode FG. Hence, the state is one where directly under each opening OP1, the floating gate electrode FG exists. The interior of the opening OP1 is filled with the insulating film IL2. Because part of the floating gate electrode FG exists directly under the opening OP1, it is also possible to regard the opening OP1 as an opening that exposes part of the floating gate electrode FG when viewed in a planar manner. That is, in the bit wire M1B in the present embodiment, the opening OP1 that exposes part of the floating gate electrode FG arranged under the bit wire M1B is formed.

In the present embodiment, by providing the opening OP1 (the opening OP1 that exposes part of the floating gate electrode FG) in the bit wire M1B, it is possible to appropriately irradiate the floating gate electrode FG with ultraviolet beams via the opening OP1, and therefore, it is possible to improve the efficiency in the erase operation by ultraviolet irradiation.

In the floating gate electrode FG in which charges are accumulated, the part on which the electric field tends to concentrate is the vicinity of the end part (outer circumferential part) of the floating gate electrode FG. In particular, the electric field tends to concentrate on the corner part of the floating gate electrode FG. Hence, in order to improve the holding characteristics of stored information of a nonvolatile memory, it is particularly effective to make water or ions (for example, cations such as Na⁺ ions) hard to diffuse in the vicinity of the end part (outer circumferential part) of the floating gate electrode FG on which the electric field tends to concentrate. However, different from the present embodiment, if an opening having planar dimensions (planar area) larger than those of the floating gate electrode FG is provided in the bit wire M1B, the whole floating gate electrode FG is exposed from the opening, and therefore, it becomes easier for water or ions (for example, cations such as Na⁺ ions) to diffuse in the vicinity of the end part (outer circumferential part) of the floating gate electrode FG on which the electric field tends to concentrate.

In contrast to this, in the present embodiment, the opening OP1 is provided in the bit wire M1B so that its position and size are included in the floating gate electrode FG in a planar manner. That is, the relationship between the opening OP1 and the floating gate electrode FG is not that the opening OP1 includes the floating gate electrode FG (in this case, the opening OP1 is larger than the floating gate electrode FG) but that the opening OP1 is included in the floating gate electrode FG (in this case, the opening OP1 is smaller than the floating gate electrode FG). Hence, when viewed in a planar manner, the part inside (toward the center side of) the floating gate electrode FG is exposed from the opening OP1, however, the end part (outer circumferential part) of the floating gate electrode FG is not exposed from the opening OP1 and the state is one where the bit wire M1B exists directly on the whole of the end part of the floating gate electrode FG (that is, the end part in the X direction and the end part in the Y direction, that is, the outer circumferential part of the floating gate electrode FG) on which the electric field tends to concentrate. In other words, at least the corner part of each floating gate electrode FG is covered with the bit wire M1B. Further, at least each side of each floating gate electrode FG is covered with the bit wire M1B.

Due to this, even if the opening OP1 is formed, it is possible to efficiently suppress water or ions (for example, cations such as Na⁺ ions) from diffusing in the vicinity of the end part (outer circumferential part) of the floating gate electrode FG on which the electric field tends to concentrate by the bit wire M1B. Consequently, it is possible to improve the holding characteristics of stored information of a nonvolatile memory.

In order to improve the holding characteristics of stored information of a nonvolatile memory as much as possible, the case is more advantageous, where such an opening that exposes part of the floating gate electrode FG is not provided in the bit wire M1B, as in the first and second embodiments described above. On the other hand, in order to make coexist the improvement in the holding characteristics of stored information of a nonvolatile memory and the improvement in the efficiency in the erase operation by ultraviolet irradiation, the case is more advantageous, where such an opening (OP1, OP2) that exposes part of the floating gate electrode FG is provided in the bit wire M1B, as in the present third embodiment and the fourth embodiment, to be described later. Hence, if the present third embodiment and the fourth embodiment, to be described later, are applied to the case where erase is performed by ultraviolet irradiation, the effect is more significant.

In FIG. 24 to FIG. 27, the case is shown, where the opening OP1 is provided in the bit wire M1B in the second embodiment described above, however, it is also possible to provide the same opening OP1 as that in the present embodiment in the bit wire M1B in the first embodiment described above.

Further, the dimension in the X direction (width W2) is smaller than the dimension in the Y direction (length L1) in each floating gate electrode FG, and therefore, if the dimension in the X direction is made smaller than the dimension in the Y direction also in each opening OP1, it is possible to efficiently arrange the opening OP1 so as to be included in the floating gate electrode FG in a planar manner. For example, as also shown in FIG. 25, when the planar shape of the floating gate electrode FG is a rectangular shape having long sides in the Y direction and short sides in the X direction, if the planar shape of the opening OP1 is also formed into a rectangular shape having long sides in the Y direction and short sides in the X direction, it is possible to efficiently arrange the opening OP1 so as to be included in the floating gate electrode FG in a planar manner.

The opening OP1 in the present embodiment and the openings OP2, OP3, OP4 and OP5, to be described later, and a slit ST, to be described later, can be formed when forming the wire M1 having these openings or the slit instead of forming them separately after forming the wire M1.

### Fourth Embodiment

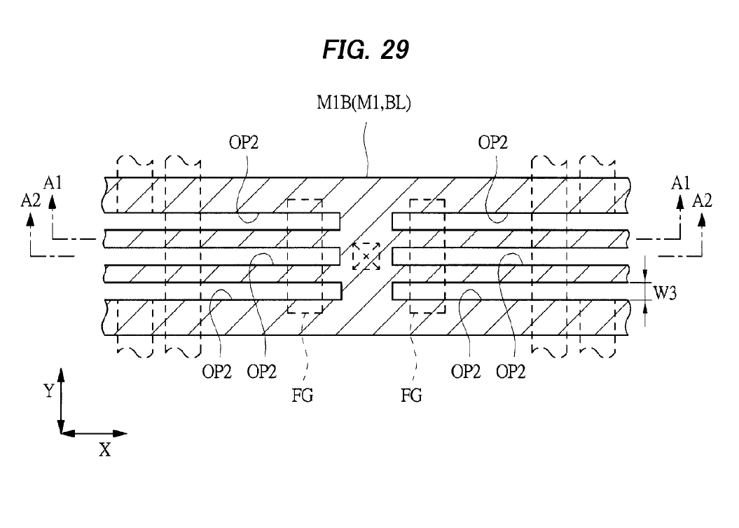

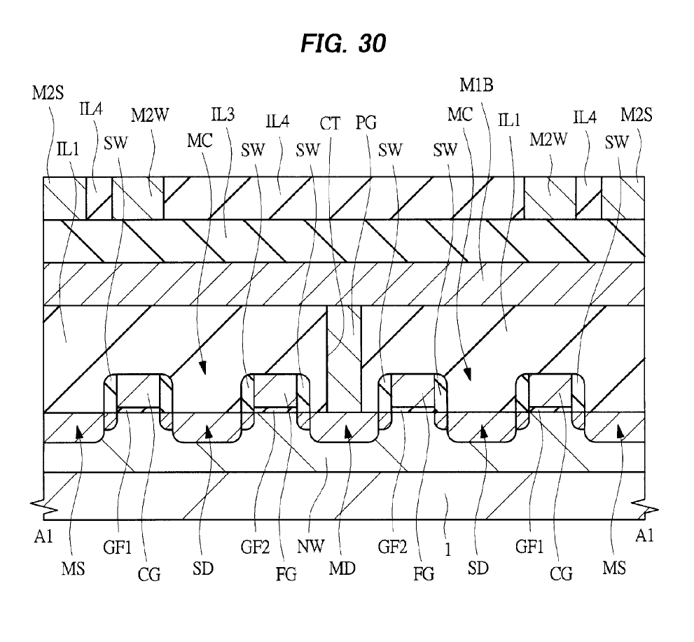

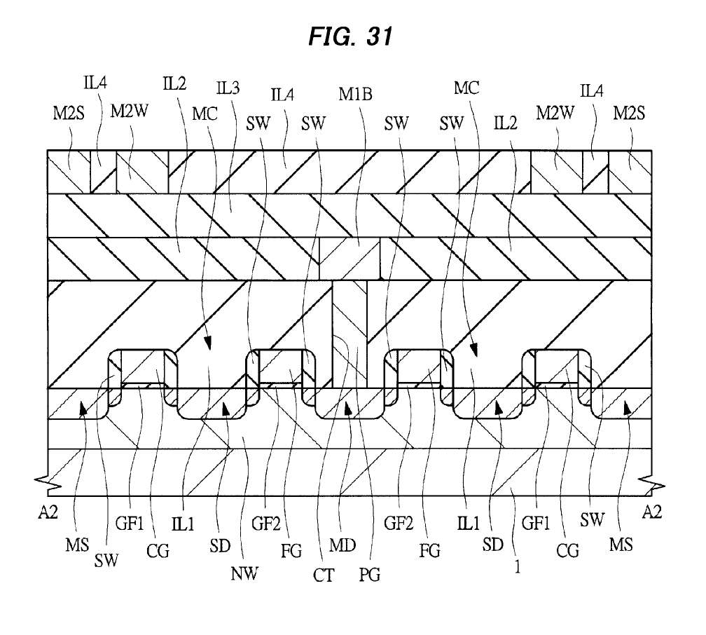

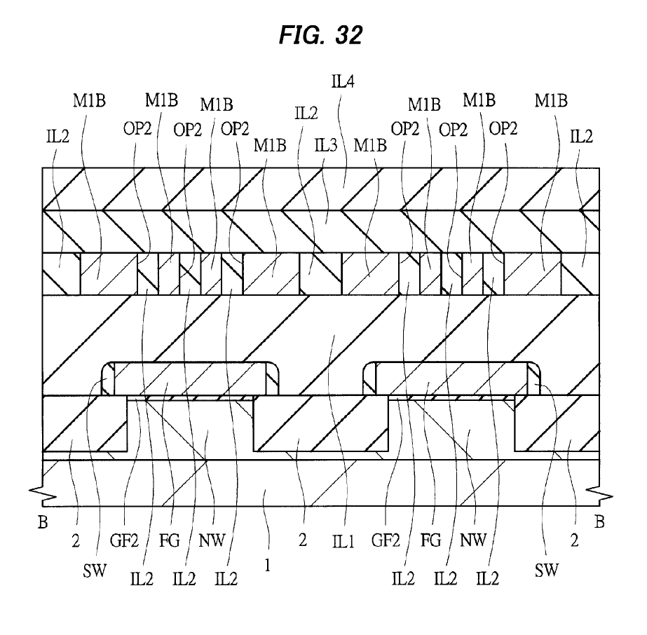

FIG. 28 and FIG. 29 are plan views of relevant parts of the semiconductor device in the present embodiment, wherein FIG. 28 corresponds to FIG. 4 in the first embodiment and FIG. 29 corresponds to FIG. 7 in the first embodiment. FIG. 30 to FIG. 32 are section views of relevant parts of the semiconductor device in the present embodiment, wherein FIG. 30 substantially corresponds to the section view in a position of an A1-A1 line in FIG. 29, FIG. 31 substantially corresponds to a section view in a position of an A2-A2 line in FIG. 29, and FIG. 32 substantially corresponds to the section view in the position of the B-B line in FIG. 28. Consequently, FIG. 30 and FIG. 31 are section views that substantially correspond to FIG. 8 (however, as can also be seen from FIG. 29, the section view in FIG. 30 (section view along the A1-A1 line) somewhat shifts in the Y direction from the section view in FIG. 31 (section view along the A2-A2 line)) and FIG. 32 is a section view that substantially corresponds to FIG. 9.

The semiconductor device in the present embodiment shown in FIG. 28 to FIG. 32 has the same configuration as that of the semiconductor device in the first embodiment except for that the opening (through-hole) OP2 is provided in the bit wire M1B, and therefore, here, the opening OP2 is explained, which is the different point from the first embodiment (explanation of other parts is omitted).

In the present embodiment, the opening OP2 is provided in the bit wire M1B and this opening OP2 is formed as a slit-shaped opening the dimension of which in the X direction is greater than the dimension in the Y direction. Each opening OP2 is formed so as to cross the floating gate electrode FG when viewed in a planar manner and the opening OP2 partially overlaps the floating gate electrode FG. That is, the opening OP2 is formed in the bit wire M1B so that one or more openings OP2 cross the floating gate electrode FG of each memory cell MC. One or more openings OP2 cross each floating gate electrode FG, and therefore, each floating gate electrode FG is in the state where a part directly on which the bit wire M1B does not exist (that is, the part directly on which the insulating film IL2 in the opening OP2 exists) and a part directly on which the bit wire M1B exists (that is, the part directly on which the opening OP2 does not exist) are mixed. The interior of the opening OP2 is filled with the insulating film IL2. Because each floating gate electrode FG partially overlaps the opening OP2 in a planar manner and has the part directly on which the opening OP2 (the insulating film IL2 in the opening OP2) exists, it is also possible to regard the opening OP1 as an opening that exposes part of the floating gate electrode FG when viewed in a planar manner. That is, in the bit wire M1B in the present embodiment, the opening OP2 that exposes part of the floating gate electrode FG arranged under the bit wire M1B is formed.

It is also possible to form the opening OP2 so as to cross not only the floating gate electrode FG but also the semiconductor region SD, the control gate electrode CG, and the semiconductor region MS (source region), however, it is preferable for the opening OP2 not to cross the semiconductor region MD (drain region). By doing so, it is possible to avoid the opening OP2 from overlapping the contact hole CT formed in the top part of the semiconductor region MD (drain region) and the plug PG that is embedded in the contact hole CT. Due to this, it is possible to couple the plug PG formed in the top part of the semiconductor region MD (drain region) to the bit wire M1B both easily and appropriately.

In the present embodiment, by providing the opening OP2 (the opening OP2 that exposes part of the floating gate electrode FG) in the bit wire M1B, it is possible to appropriately irradiate the floating gate electrode FG with ultraviolet beams via the opening OP2, and therefore, it is possible to improve the efficiency in the erase operation by ultraviolet irradiation.

In the floating gate electrode FG in which charges are accumulated, the part on which the electric field tends to concentrate is the vicinity of the end part (outer circumferential part) of the floating gate electrode FG. In order to improve the holding characteristics of stored information of a nonvolatile memory, it is particularly effective to make water or ions (for example, cations such as Na⁺ ions) hard to diffuse in the vicinity of the end part (outer circumferential part) of the floating gate electrode FG on which the electric field tends to concentrate. However, different from the present embodiment, when the opening OP2 is provided so as to expose the whole floating gate electrode FG, it becomes easier for water or ions (for example, cations such as Na⁺ ions) to diffuse in the vicinity of the end part (outer circumferential part) of the floating gate electrode FG on which the electric field tends to concentrate.

In contrast to this, in the present embodiment, the opening OP2 is provided in the bit wire M1B so that one or more openings OP2 cross each floating gate electrode FG in the bit wire M1B. That is, the relationship between the opening OP2 and the floating gate electrode FG is not that the whole of each floating gate electrode FG is exposed from the opening OP2 when viewed in a planar manner but only part of each floating gate electrode FG is exposed from the opening OP2 and the rest is not exposed from the opening OP2. Hence, the state is one where the bit wire M1B exists partially directly on the end part (the end part in the X direction and the end part in the Y direction, that is, the outer circumferential part of the floating gate electrode FG) of the floating gate electrode FG on which the electric field tends to concentrate. Due to this, even if the opening OP2 is formed, it is possible to suppress water or ions (for example, cations such as Na⁺ ions) from diffusing in the vicinity of the end part (outer circumferential part) of the floating gate electrode FG on which the electric field tends to concentrate by the bit wire M1B. Consequently, it is possible to improve the holding characteristics of stored information of a nonvolatile memory.

In the attempt to improve the holding characteristics of stored information, it is effective for the bit wire M1B to exist directly on the end part (outer circumferential part) of the floating gate electrode FG on which the electric field tends to concentrate. In the present embodiment, the opening OP2 is provided so as to cross the floating gate electrode FG, however, as can also be seen from FIG. 29 and FIG. 32, design is made so that both end parts in the Y direction are not exposed from the opening OP2 in each floating gate electrode FG. That is, design is made so that the bit wire M1B exists directly on both end parts in the Y direction (when the planar shape of the floating gate electrode FG is substantially a rectangle, the sides parallel with the X direction of the rectangle) of each floating gate electrode FG. In other words, at least the corner part of each floating gate electrode FG is covered with the bit wire M1B.

Due to this, it is possible to reduce the area of the end part (outer circumferential part) of the floating gate electrode FG exposed from the opening OP2, and therefore, it is possible to efficiently improve the holding characteristics of stored information of a nonvolatile memory. In the third embodiment also, the bit wire M1B exists directly on both end parts in the Y direction of each floating gate electrode FG.

It is preferable to make a width W3 (shown in FIG. 29) of the opening OP2 smaller than the length L1 (shown in FIG. 9) of the floating gate electrode FG (that is W3<L1). Here, the width W3 of the opening OP2 corresponds to the dimension of the opening OP2 in the Y direction. Due to this, it is possible to prevent the whole floating gate electrode FG from being exposed from the opening OP2 and to bring each floating gate electrode FG into the state where part of each floating gate electrode FG is exposed from the opening OP2.

When the planar shape of the floating gate electrode FG is a rectangular shape having long sides in the Y direction and short sides in the X direction, if the planar shape of the opening OP2 is formed into a rectangular shape having long sides in the X direction and short sides in the Y direction, it is possible to efficiently arrange the opening OP2 so as to cross the floating gate electrode FG.

When providing an opening in the bit wire M1B in order to facilitate the irradiation of the floating gate electrode FG with ultraviolet beams, in order to improve the holding characteristics of stored information of a nonvolatile memory as much as possible, the opening OP1 in the third embodiment described above is more advantageous because of the presence of the bit wire M1B directly on the whole of the end part (outer circumferential part) of the floating gate electrode FG on which the electric field tends to concentrate.

On the other hand, when the opening OP2 is provided so that one or more openings OP2 cross each floating gate electrode FG as in the present embodiment, it is possible to increase the dimension of the opening OP2 in the X direction (it is also possible to increase the dimension of the floating gate electrode FG in the Y direction). Hence, when forming the wire M1 including the bit wire M1B by the damascene method, it is possible to suppress or prevent the occurrence of dishing because of the presence of the opening OP2 in the bit wire M1B. Consequently, according to the present embodiment, it is possible to obtain the effect of suppressing or preventing the occurrence of dishing when the wire M1 is a damascene wire (embedded wire) even if the erase by ultraviolet irradiation is not performed.

The number of the openings OP2 that cross each floating gate electrode FG is one or more and if it is assumed to be two or more, it is possible to further improve the effect of suppressing (preventing) the occurrence of dishing when forming the wire M1 including the bit wire M1B by the damascene method.

That in the bit wire M1B, the openings that expose part of the floating gate electrodes FG, respectively, arranged under the bit wire M1B are formed is common to the third embodiment described above and to the present embodiment and the opening corresponds to the opening OP1 in the third embodiment and corresponds to the opening OP2 in the present embodiment. When viewed in a planar manner, each floating gate electrode FG has a part (part directly on which the bit wire M1B does not exist) exposed from the opening (corresponding to opening OP1 in the third embodiment and to the opening OP2 in the present embodiment) and a part (part directly on which the bit wire M1B exists) not exposed. In this state, in the third embodiment, each opening OP1 is formed in the bit wire M1B so as to be smaller than each floating gate electrode FG and so as to be included in a planar manner in each floating gate electrode FG arranged under the bit wire M1B. On the other hand, in the present embodiment, the dimension in the Y direction is smaller than the dimension in the X direction in each opening OP2 and when viewed in a planar manner, one or more openings OP2 cross each floating gate electrode FG.

In the fourth embodiment, the example is shown, in which the bit wire M1B is regarded as one wire and the opening OP2 is formed in the one bit wire M1B. However, this is not limited and it may also be possible to cause one or more bit wires M1B to pass over the floating gate electrode FG. Based on the present fourth embodiment, it may also be possible to cause the four bit wires M1B to pass over the floating gate electrode FG. Then, each bit wire M1B may be coupled in the second wiring layer. In this case also, both end parts in the Y direction are prevented from being exposed from the opening OP2 in each floating gate electrode FG. That is, the bit wire M1B is caused to exist directly on both end parts of each floating gate electrode FG in the Y direction (when the planar shape of the floating gate electrode FG is substantially a rectangle, the sides parallel with the X direction in the rectangle). In other words, at least the corner part of each floating gate electrode FG is caused to be covered with the bit wire M1B.

### Fifth Embodiment

In the first to fourth embodiments described above, the bit wire M1B that functions as the bit wire BL (that is, the bit wire M1B that couples the drain regions of the memory transistors of the memory cells MC arranged in the X direction) is formed in the lowermost wiring layer (wire M1) of the wiring layers (multilayer wiring structure) formed over the semiconductor substrate 1. Then, by devising the bit wire M1B formed in the lowermost wiring layer (wire M1), the attempt is made to improve the holding characteristics of stored information of a nonvolatile memory.

In the present embodiment, a bit wire M2B that functions as the bit line BL (that is, the bit wire M2B that couples the drain regions of the memory transistors of the memory cells MC arranged in the X direction) is formed in the wiring layer second from the bottom (wire M2) of the wiring layers (multilayer wiring structure) formed over the semiconductor substrate 1. Then, by devising the lowermost wiring layer (wire M1) of the wiring layers (multilayer wiring structure) formed over the semiconductor substrate 1, an attempt is made to improve the holding characteristic of stored information of the nonvolatile memory. The present invention is explained below specifically.

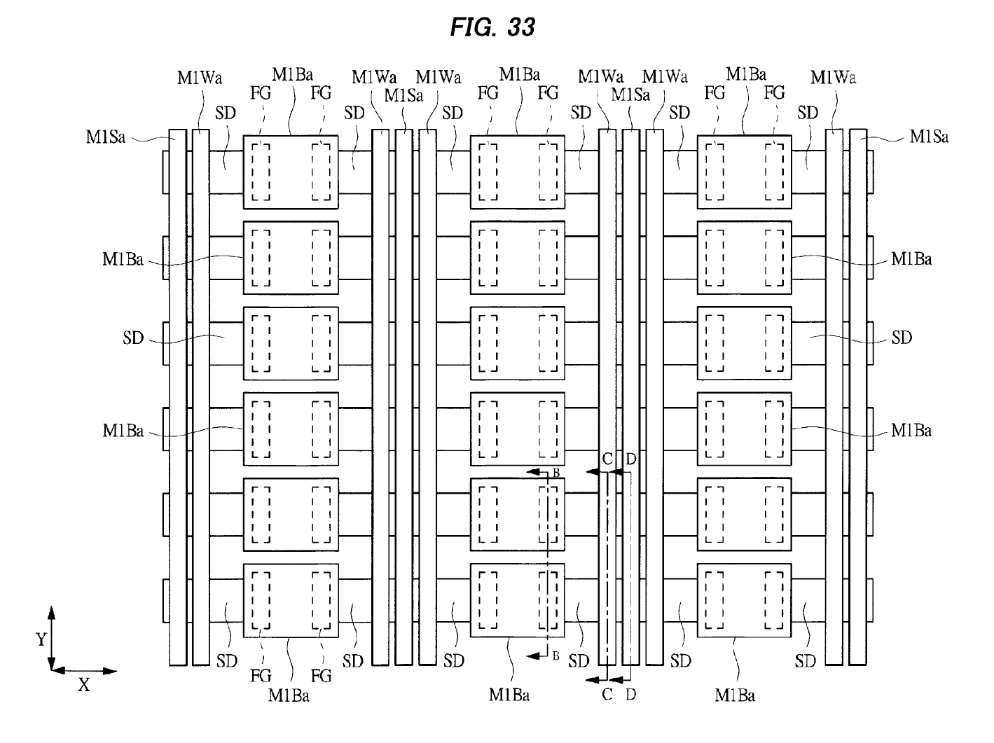

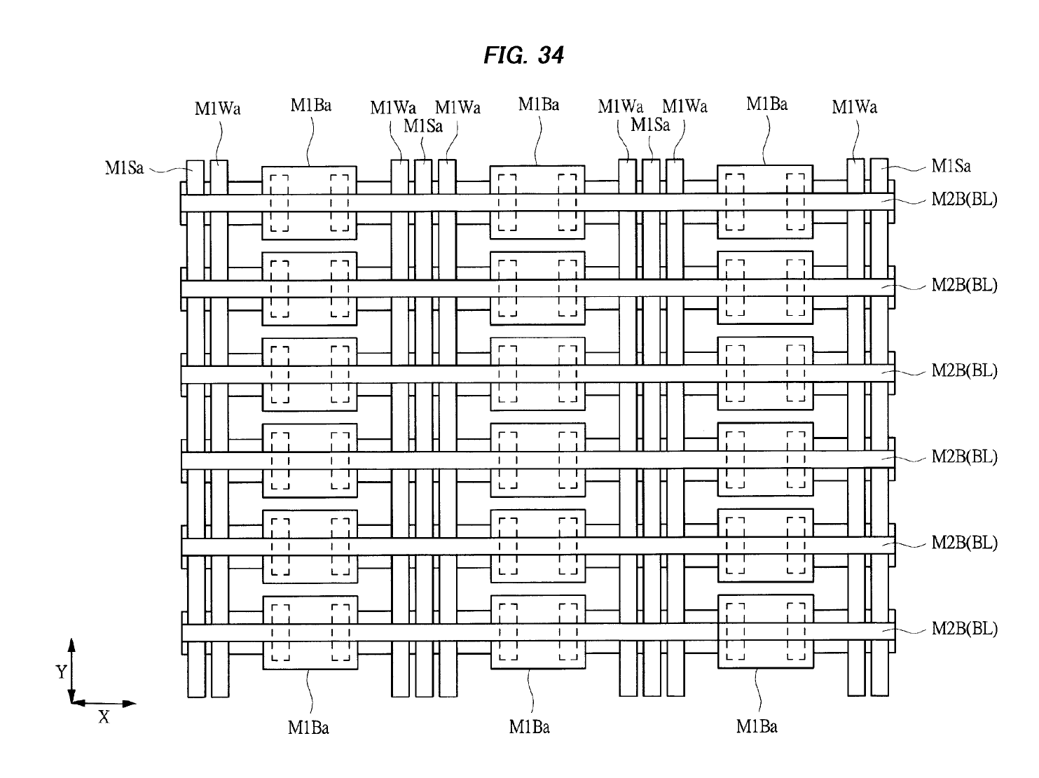

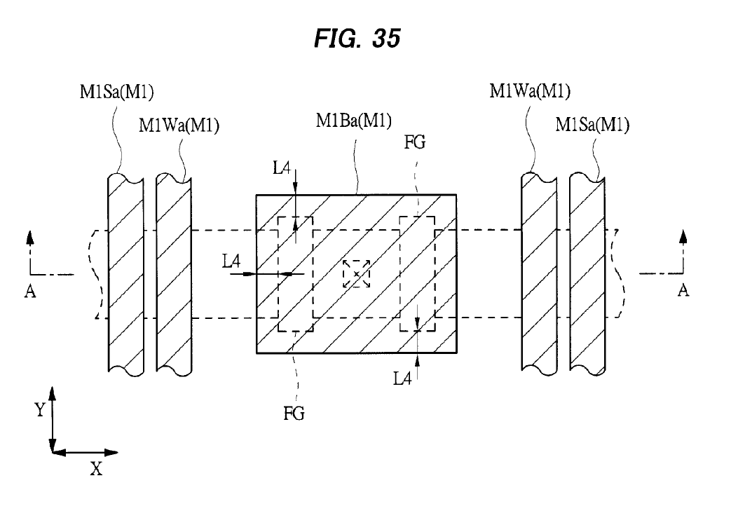

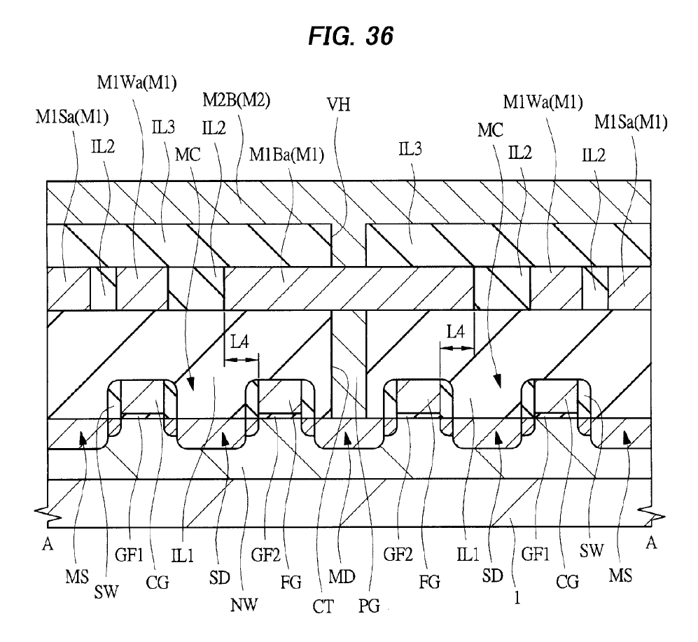

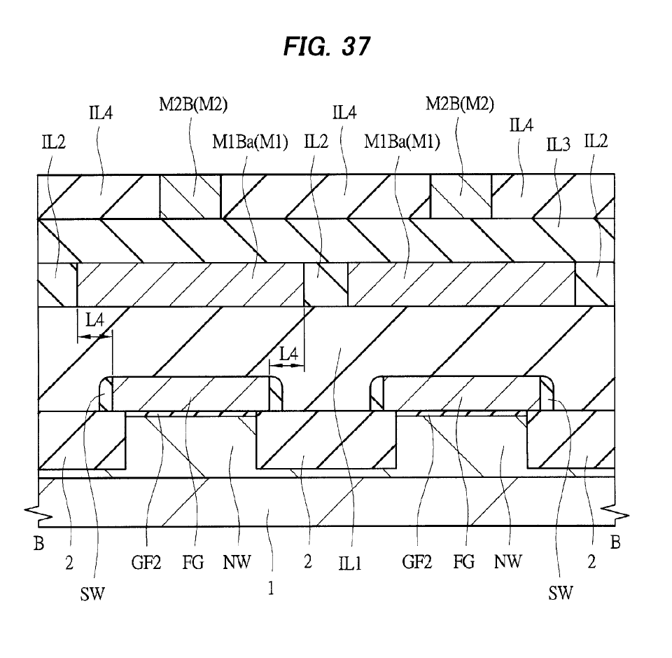

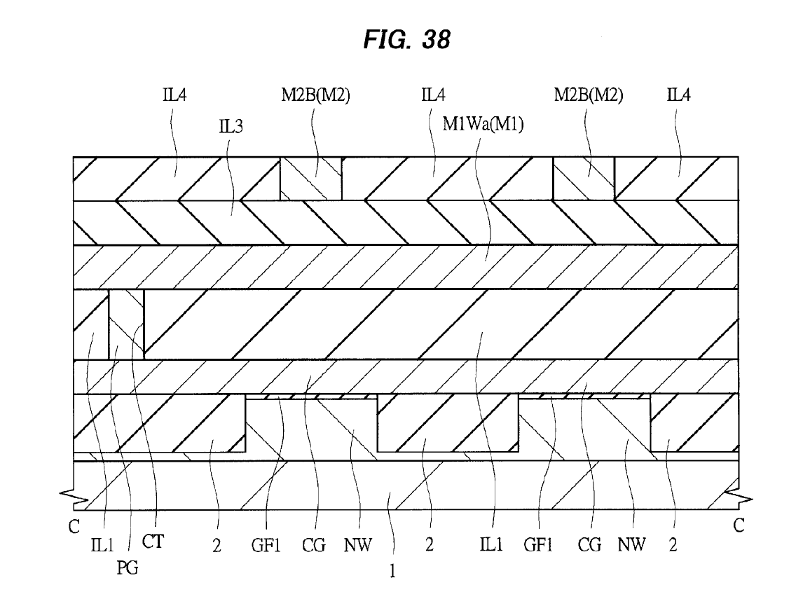

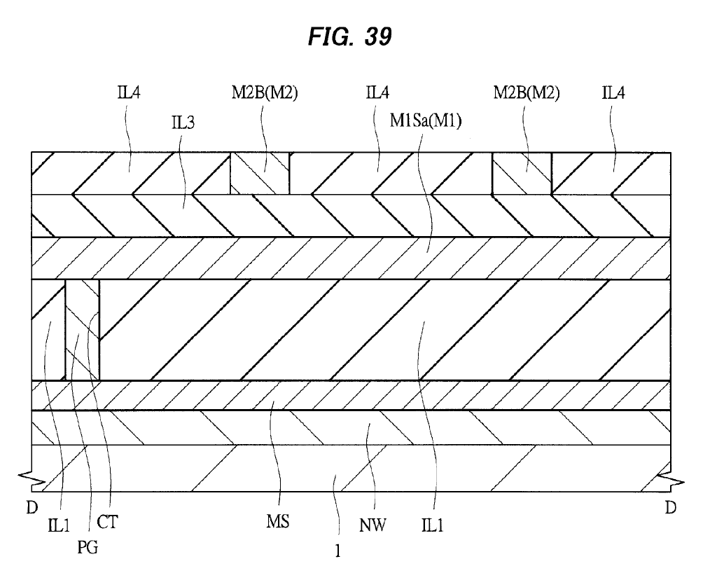

FIG. 33 to FIG. 35 are plan views of relevant parts of a semiconductor device in the present embodiment, wherein FIG. 33 corresponds to FIG. 4 in the first embodiment, FIG. 34 corresponds to FIG. 5 in the first embodiment, and FIG. 35 corresponds to FIG. 7 in the first embodiment. FIG. 36 to FIG. 39 are section vies of relevant parts of the semiconductor device in the present embodiment, wherein FIG. 36 corresponds to FIG. 8 in the first embodiment, FIG. 37 corresponds to FIG. 9 in the first embodiment, FIG. 38 corresponds to FIG. 10 in the first embodiment, and FIG. 39 corresponds to FIG. 11 in the first embodiment. Consequently, FIG. 36 substantially corresponds to the section view in the position of the A-A line shown in FIG. 35, FIG. 37 substantially corresponds to the section view in the position of the B-B line shown in FIG. 33, FIG. 38 substantially corresponds to the section view in the position of the C-C line shown in FIG. 33, and FIG. 39 substantially corresponds to the section view in the position of the D-D line shown in FIG. 33.

The semiconductor device in the present embodiment shown in FIG. 33 to FIG. 39 has the same configuration as that of the semiconductor device in the first embodiment except for the wires M1, M2, and therefore, the wires M1, M2 are explained here, which are different points from the first embodiment (explanation of other parts is omitted).

As can also be seen from the FIG. 36 to FIG. 39, the insulating film IL1 and the structure below the insulating film IL1 of the semiconductor device in the present embodiment are the same as those of the semiconductor device in the first embodiment. Then, in the present embodiment, instead of the wire M1W and the word wire M2W formed in the first embodiment, a word wire (wire for word line) M1Wa is formed in the first wiring layer (wire M1) and instead of the wire M1S and the source wire M2S formed in the first embodiment, a source wire (wire for source line) M1Sa is formed in the first wiring layer (wire M1). The word wire M1Wa formed in the first wiring layer (wire M1) is electrically coupled to the control gate electrode CG via the plug PG and at the same time, extending in the Y direction over the control gate electrode CG. The source wire M1Sa formed in the first wiring layer (wire M1) is electrically coupled to the semiconductor region MS (p⁺-type semiconductor region MSa) for source via the plug PG and at the same time, extending in the Y direction over the semiconductor region MS.

In the present embodiment, the word wire M1Wa and the source wire M1Sa extending in the Y direction are formed in the first wiring layer (wire M1) and the bit wire M2B as the bit line BL extending in the X direction is formed in the second wiring layer (wire M2). The bit wire M2B extends in the X direction, however, specifically, it extends over the memory cells MC arranged side by side in the X direction and under the bit wire M1B, the semiconductor region MD for drain, the floating gate electrode FG, the semiconductor region SD, the control gate electrode CG, and the semiconductor region MS for source of each memory cell MC arranged side by side in the X direction are arranged.

The bit wire M2B is a wire configuring the bit line BL (bit line BL is shown in FIG. 14) and a wire (bit line, wire for bit line) that (electrically) couples the semiconductor regions MD for drain of the memory cells MC arranged side by side in the X direction among the memory cells MC arranged in an array in the X direction and the Y direction. Consequently, it is necessary to electrically couple the semiconductor region MD for drain of the memory cells MC arranged side by side in the X direction to the bit wire M2B thereabove, however, it is not possible to draw it up to the bit wire M2B in the second wiring layer (wire M2) only through the plug PG, and therefore, a wire part (wire) M1Ba is formed between each semiconductor region MD and the bit wire M2B thereabove in the first wiring layer (wire M1). That is, between the bit wire M1B extending in the X direction and the semiconductor region MD for drain of each memory cell MC arranged side by side in the X direction, the plug PG and the wire part M1Ba are arranged.

The wire part M1Ba is formed in the first wiring layer (wire M1) and is a wire part (wire) used to draw up the semiconductor region MD for drain to the bit wire M2B in the second wiring layer. That is, the wire part M1Ba and a wire part M1Bb, to be described later, are a wire part (wire) formed in the first wiring layer (M1) to draw up the drain region (semiconductor region MD) of the memory transistor to the bit wire M2B. Consequently, in the present embodiment, the wire M1 formed in the first wiring layer includes the word wire M1Wa, the source wire M1Sa, and the wire part M1Ba. The wire part M1Ba is provided independently for each semiconductor region MD and one wire part M1Ba is provided for one semiconductor region MD. Each wire part M1Ba is arranged at the top of each semiconductor region MD and the semiconductor region MD and the wire part M1Ba at the top thereof are electrically coupled via the plug PG located between the semiconductor region MD and the wire part M1Ba. The bit wire M2B is electrically coupled with the wire part M1Ba via a via part (conductive part embedded in the hole part VH formed in the insulating film IL3) formed integrally with the bit wire M2B. When the wire M2 is a single damascene wire or a wire formed by patterning an electrically conductive film for wiring, the via part that couples the bit wire M2B and the wire part M1Ba can be formed in a process different from that of the bit wire M2B.

Above each semiconductor region MD of the memory cells MC arranged side by side in the X direction, the wire part M1Ba is arranged and the bit wire M2B is further arranged thereabove extending in the X direction, and therefore, it is possible to electrically couple each semiconductor region MD of the memory cells MC arranged side by side in the X direction to the bit wire M2B via the plug PG and the wire part M1Ba. Consequently, the semiconductor regions MD of the memory cells MC arranged side by side in the X direction are in the state of being electrically coupled to one another via the plug PG, the wire part M1Ba, and the bit wire M2B.

In the present embodiment, by devising the wire part M1Ba, an attempt is made to improve the holding characteristics of stored information of a nonvolatile memory.

That is, in the present embodiment, the wire part M1Ba is caused to cover the whole floating gate electrode FG when viewed in a planar manner by increasing the planar dimensions of the wire part M1Ba. In other words, in each of the memory cells MC arranged in an array in the X direction and the Y direction, the whole floating gate electrode FG is covered with the wire part M1Ba. In further other words, each floating gate electrode FG is included in the wire part M1Ba in a planar manner and the state is one where the wire part M1Ba exists directly on the whole of each floating gate electrodes FG.

In order to do so, it is recommended to design the layout of the wire M1 by increasing the planar dimensions of the wire part M1Ba until the wire part M1Ba covers the floating gate electrode FG neighboring the semiconductor region MD for drain (in the X direction).

When the semiconductor region MD is shared by the two memory cells MC neighboring in the X direction with the semiconductor region MD sandwiched in between, the wire part M1Ba is provided for each semiconductor region MD, and therefore, it is possible to provide one wire part M1Ba for the two memory cells MC neighboring in the X direction with the semiconductor region MD sandwiched in between. In this case, the wire part M1Ba is formed at the top of the semiconductor region MD so as to cover the two floating gate electrodes FG neighboring in the X direction with the semiconductor region MD sandwiched in between.

Further, it is necessary to form the wire part M1Ba in such a manner that it does not come into contact with the word wire M1Wa or the source wire M1Sa, and therefore, it does not extend over the semiconductor, region MS for source or the control gate electrode CG.

In the present embodiment, the wire M2B as the bit line BL extending in the X direction is formed in the second wiring layer (wire M2). Hence, the distance between the bit wire M2B and the floating gate electrode FG located thereunder is considerably great and has a value substantially corresponding to the total thickness of the insulating films IL1 IL2 and IL3. Hence, even if the bit wire M2B covers the floating gate electrode FG in a planar manner, water or ions (for examples, cations such as Na⁺ ions) diffuse from the thick insulating film (combination of the insulating films IL1, IL2 and IL3) to the floating gate electrode FG, and therefore, it is difficult to effectively suppress the diffusion.

Consequently, in the present embodiment, the wire part M1Ba is devised so that the whole floating gate electrode FG is covered with the wire part M1Ba when viewed in a planar manner. In other words, the floating gate electrode FG is arranged so as to be included in the wire part M1Ba when viewed in a planar manner. In further other words, the wire part M1Ba is arranged outside each side of each floating gate electrode FG. Because of the state where the wire part M1Ba extends above the floating gate electrode FG and the whole of each floating gate electrode FG is covered with the wire part M1Ba when viewed in a planar manner, it is possible for the wire part M1Ba to prevent water or ions (for example, cations such as Na⁺ ions) from diffusing under the wire part M1Ba, and therefore, it is possible to reduce the amount of water or the number of ions that reach the floating gate electrode FG. Hence, it is made possible to appropriately hold charges accumulated in the floating gate electrode FG until the erase operation is performed, and therefore, it is possible to improve the holding characteristics of stored information of a nonvolatile memory.

As described above, in the present embodiment, it is possible to prevent water or ions (for example, cations such as Na⁺ ions) from diffusing from the insulating film (the insulating films IL2, IL3, IL4 or insulating films in even upper layers) in layers upper than the insulating film IL1 to the floating gate electrode FG by the wire part M1Ba, and therefore, it is possible to improve the holding characteristics of stored information of a nonvolatile memory. Consequently, it is possible to improve the performance of the semiconductor device comprising a nonvolatile memory.

The floating gate electrode FG is adjacent to the semiconductor region MD in the X direction, and therefore, it is possible to cover the floating gate electrode FG with the wire part M1Ba by extending the planar shape of the wire part M1Ba provided at the top of the semiconductor region MD in the X direction and the Y direction (particularly, in the X direction). Hence, the layout design is easy to make.

In the present embodiment, the wire part M1Ba covers the whole floating gate electrode FG, and therefore, when viewed in a planar manner, a distance L4 (shown in FIG. 35 to FIG. 37) from the end part (outer circumferential part) of the floating gate electrode FG to the end part (outer circumferential part) of the wire part M1Ba is greater than zero (that is, L4>0). By increasing the distance L4, it is possible to reduce the amount of water or the number of ions (for example, cations such as Na⁺ ions) that skirt the wire part M1Ba and reach the floating gate electrode FG. From this viewpoint, it is further preferable to set the distance L4 from the end part (outer circumferential part) of the floating gate electrode FG to the end part (outer circumferential part) of the wire part M1Ba to 0.4 μm or more (that is, L4≧0.4 μm) and by doing so, it is possible to further improve the holding characteristics of stored information of a nonvolatile memory. Hence, it is recommended to design the dimension in the X direction and the dimension in the Y direction of the wire part M1Ba as large as possible while taking into consideration the size of the layout of the wire part M1Ba that can be achieved (the limit dimensions with which the word wire M1Wa and the source wire M1Sa can be avoided).

In the present embodiment, the case is explained, where the wire part M1Ba covers the whole floating gate electrode FG, however, if the wire part M1Ba covers at least part of the floating gate electrode FG, it is possible to reduce the amount of water or the number of ions (for example, cations such as Na⁺ ions) that reach the floating gate electrode FG compared to the case where the floating gate electrode FG is not at all covered with the wire M1. Hence, besides the case where the wire part M1Ba covers the whole floating gate electrode FG, even in the case where the wire part M1Ba covers at least part of the floating gate electrode FG, it is possible to obtain the effect of improving the holding characteristics of stored information of a nonvolatile memory. However, in order to improve the holding characteristics of stored information of a nonvolatile memory as much as possible, it is effective to reduce as much as possible the amount of water or the number of ions that reach the floating gate electrode FG, and therefore, it is further preferable for the wire part M1Ba to cover the whole floating gate electrode FG as shown in FIG. 35.

### Sixth Embodiment

In the semiconductor device in the fifth embodiment, the electrical erase operation can be performed appropriately. On the other hand, in the semiconductor device in the fifth embodiment, it is also possible to perform the erase operation itself by ultraviolet irradiation by utilizing the scattered ultraviolet beams in the semiconductor device, however, in the state where the wire part M1Ba covers the whole floating gate electrode FG, the ultraviolet beams are shielded by the wire part M1Ba, and thereby, the ultraviolet beams cannot reach the floating gate electrode FG successfully and there is a possibility that the efficiency in the erase by ultraviolet irradiation is degraded. In this case, it is required to take measures to increase the ultraviolet irradiation time at the time of the erase operation etc.

Therefore, in the present sixth embodiment, the opening OP3 is provided in the wire part M1Ba and in the seventh embodiment, to be described later, the slit ST is provided in the wire part M1Ba so as to allow ultraviolet beams to reach the floating gate electrode FG through the opening OP3 or the slit ST. By doing so, it is possible to improve the efficiency in the erase operation by ultraviolet irradiation.

The opening OP3 to be provided in the wire part M1Ba is explained below specifically.

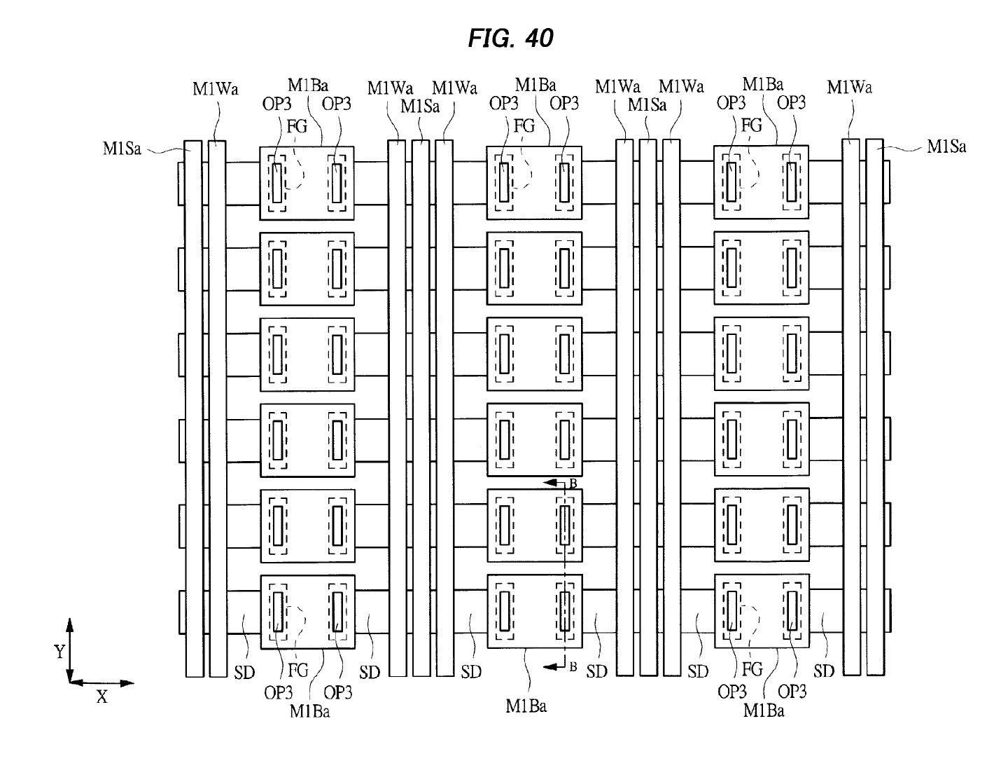

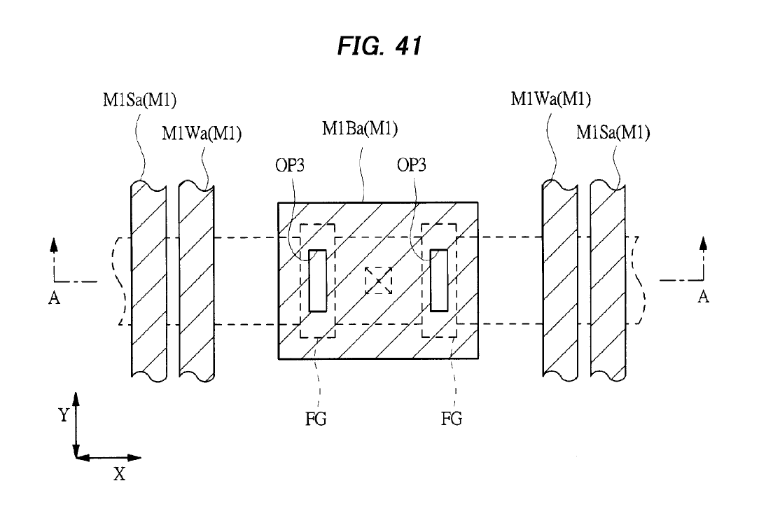

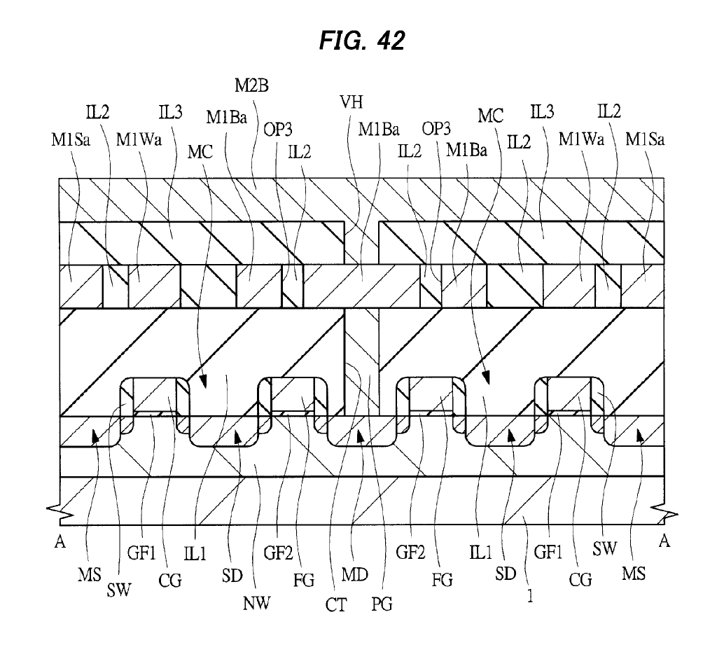

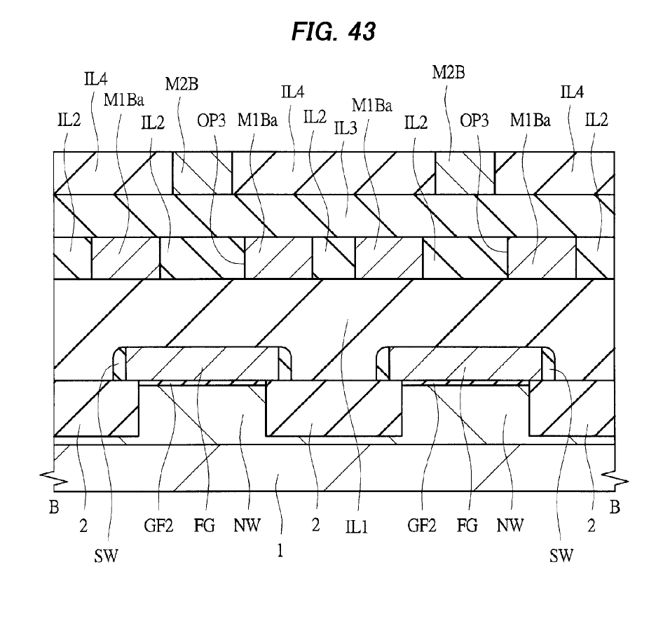

FIG. 40 and FIG. 41 are plan views of relevant parts of the semiconductor device in the present embodiment, wherein FIG. 40 corresponds to FIG. 33 in the fifth embodiment and FIG. 41 corresponds to FIG. 35 in the fifth embodiment. FIG. 42 and FIG. 43 are section views of relevant parts of the semiconductor device in the present embodiment, wherein FIG. 42 corresponds to FIG. 36 in the fifth embodiment and FIG. 43 corresponds to FIG. 37 in the fifth embodiment. Consequently, FIG. 42 substantially corresponds to the section view in the position of the A-A line shown in FIG. 41 and FIG. 43 substantially corresponds to the section view in the position of the B-B line shown in FIG. 40.

The semiconductor device in the present embodiment shown in FIG. 40 to FIG. 43 has the same configuration as that of the semiconductor device in the fifth embodiment except for that the opening (through-hole) OP3 is provided in the wire part M1Ba, and therefore, the opening OP3, which is the different point from the fifth embodiment, is explained here (explanation of other parts is omitted).

The opening OP3 provided in the wire part M1Ba in the present embodiment is basically the same as the opening OP1 provided in the bit wire M1B in the third embodiment. That is, in the present embodiment, the relationship between the opening OP3 provided in the wire part M1Ba and the floating gate electrode FG is the same as the relationship between the opening OP1 provided in the bit wire M1B and the floating gate electrode FG in the third embodiment.

To explain specifically, in the present embodiment, the opening OP3 is provided in the wire part M1Ba and this opening OP3 is formed so as to be included in the floating gate electrode FG when viewed in a planar manner. That is, in each wire part M1Ba, the opening OP3 is provided for each floating gate electrode FG existing thereunder and the planar dimensions (planar area) of each opening OP3 are smaller than the planar dimensions (planar area) of the floating gate electrode FG and as can also be seen from FIG. 41, the opening OP3 is included in a planar manner in the floating gate electrode FG. In other words, the opening OP3 is arranged inside each side of each floating gate electrode FG. Hence, the state is one where directly under each opening OP3, the floating gate electrode FG exists. The interior of the opening OP3 is filled with the insulating film IL2. Because part of the floating gate electrode FG exists directly under the opening OP3, it is also possible to regard the opening OP3 as an opening that exposes part of the floating gate electrode FG when viewed in a planar manner. That is, in the wire part M1Ba in the present embodiment, the opening OP3 that exposes part of the floating gate electrode FG arranged under the wire part M1Ba is formed.

The effect obtained by providing the opening OP3 in the wire part M1Ba in the present embodiment is basically the same as the effect obtained by providing the opening OP1 in the bit wire M1B in the third embodiment. In the present embodiment, by providing the opening OP3 (the opening OP3 that exposes part of the floating gate electrode FG) in the wire part M1Ba, it is possible to appropriately irradiate the floating gate electrode FG with ultraviolet beams via the opening OP3, and therefore, it is possible to improve the efficiency in the erase operation by ultraviolet irradiation.

In order to improve the holding characteristics of stored information of a nonvolatile memory as much as possible, the case is more advantageous, where such an opening that exposes part of the floating gate electrode FG is not provided in the wire part M1Ba, as in the fifth embodiment. On the other hand, in order to make coexist the improvement in the holding characteristics of stored information of a nonvolatile memory and the improvement in the efficiency in the erase operation by ultraviolet irradiation, the case is more advantageous, where such an opening (OP3) that exposes part of the floating gate electrode FG is provided in the wire part M1Ba, as in the present embodiment and in the seventh embodiment, to be described later. Therefore, if the present sixth embodiment and the seventh embodiment, to be described later, are applied to the case where erase is performed by ultraviolet irradiation, the effect is more significant.

In the present embodiment, each opening OP3 is formed so as to be included in each floating gate electrode FG in a planar manner, and therefore, that state is one where the wire part M1Ba exists directly on the whole of the end part (outer circumferential part) of the floating gate electrode FG on which the electric field tends to concentrate. In other words, at least corner part of each floating gate electrode FG is covered with the wire part M1Ba. Further, at least each side of each floating gate electrode FG is covered with the wire part M1Ba.

Hence, it is possible to efficiently improve the holding characteristics of stored information of a nonvolatile memory while providing the opening OP3 that facilitates the irradiation of the floating gate electrode FG with ultraviolet beams in the wire part M1Ba.

### Seventh Embodiment

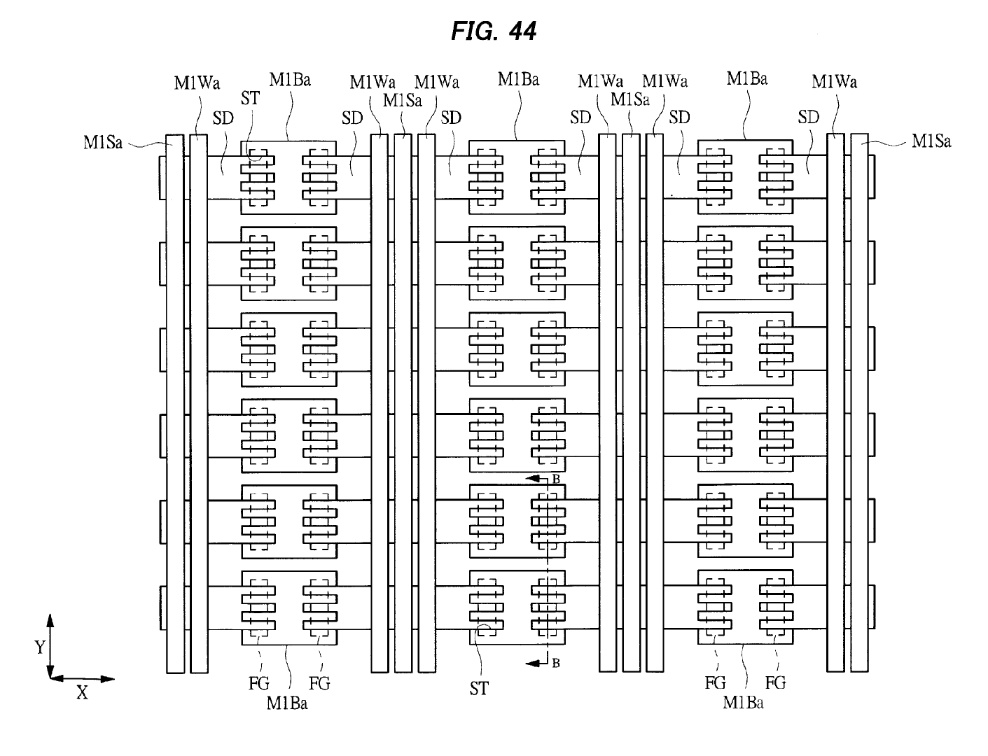

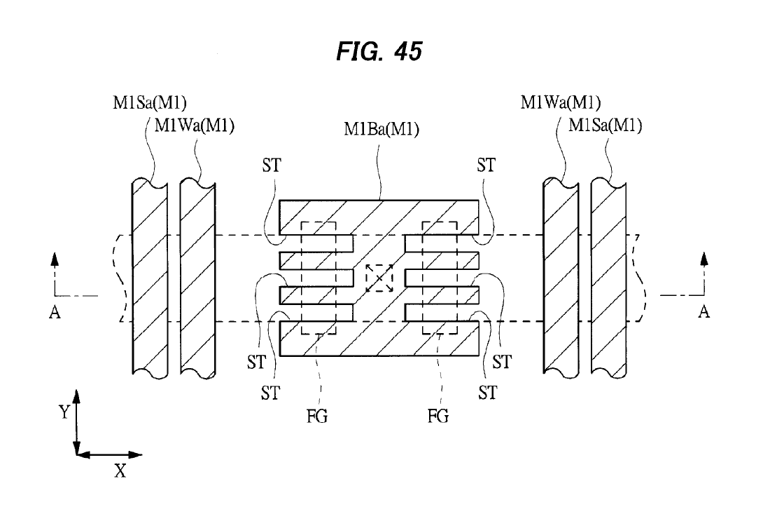

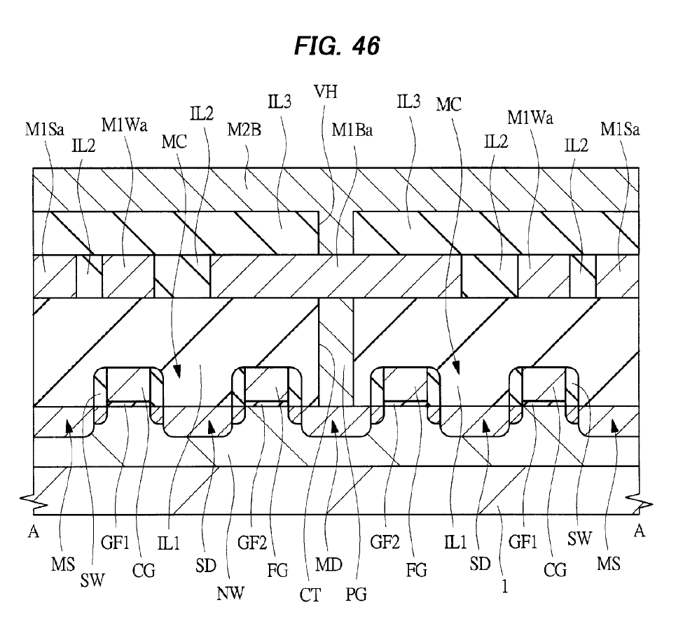

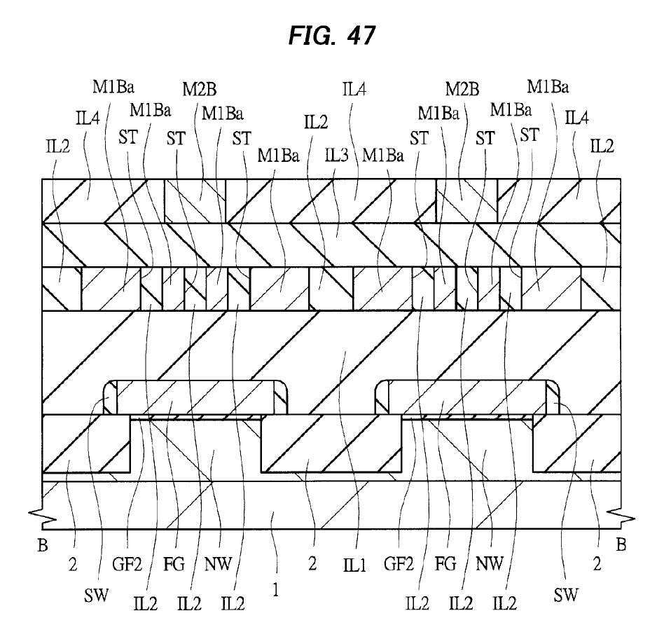

FIG. 44 and FIG. 45 are plan views of relevant parts of the semiconductor device in the present embodiment, wherein FIG. 44 corresponds to FIG. 33 in the fifth embodiment and FIG. 45 corresponds to FIG. 35 in the fifth embodiment. FIG. 46 and FIG. 47 are section views of relevant parts of the semiconductor device in the present embodiment, wherein FIG. 46 corresponds to FIG. 36 in the fifth embodiment and FIG. 47 corresponds to FIG. 37 in the fifth embodiment. Consequently, FIG. 46 substantially corresponds to the section view in the position of the A-A line shown in FIG. 45 and FIG. 47 substantially corresponds to the section view in the position of the B-B line shown in FIG. 44.

The semiconductor device in the present embodiment shown in FIG. 44 to FIG. 47 has the same configuration as that of the semiconductor device in the fifth embodiment except for that the slit ST is provided in the wire part M1Ba, and therefore, the slit ST, which is the different point from the fifth embodiment, is explained here (explanation of other parts is omitted).

The slit ST provided in the wire part M1Ba in the present embodiment corresponds to the opening OP2 provided in the bit wire M1B in the fourth embodiment, however, accompanying that the dimension of the wire part M1Ba in the X direction is smaller than the dimension of the bit wire M1B in the X direction in the fourth embodiment, the slit ST is formed in the wire part M1Ba instead of the opening OP2.

The openings OP1, OP2, OP3 and the openings OP4, OP5, to be described later, penetrate through the wire (wire part) in the vertical direction in which these openings are formed, however, when viewed in a planar manner, they are closed regions (closed spaces) surrounded by the wire (wire part). On the other hand, the slit ST penetrates through the wire part M1Ba in the vertical direction in which the slit ST is formed, however, one end part of the slit ST in the X direction is not closed by the wire part M1Ba (that is, an open state).

The relationship between the slit ST provided in the wire part M1Ba and the floating gate electrode FG in the present embodiment is the same as the relationship between the opening OP2 provided in the bit wire M1B and the floating gate electrode FG in the fourth embodiment.

To explain specifically, in the slit (cut-in part, notch part) ST provided in the wire part M1Ba, the dimension in the X direction is greater than the dimension in the Y direction and the slit extends, when viewed in a planar manner, in the X direction from the sides of both ends of the wire part M1Ba in the X direction toward the center side of the wire part M1Ba. When viewed in a planar manner, each slit ST is formed so as to cross the floating gate electrode FG and the slit ST and the floating gate electrode FG overlap partially. That is, when viewed in a planar manner, the slit ST is provided in each wire part M1Ba so that one or more slits ST cross the floating gate electrode FG of each memory cell MC. One or more slits ST cross each floating gate electrode FG, and therefore, each floating gate electrode FG is in the state where a part directly on which the wire part M1Ba does not exist (that is, the part directly on which the insulating film IL2 in the slit ST exists) and a part directly on which the wire part M1Ba exists (that is, the part where the slit ST does not exists) are mixed. The interior of the slit ST is filled with the insulating film IL2. Part of each floating gate electrode FG overlaps the slit ST in a planar manner and has a part directly on which the slit ST (insulating film IL2 in the slit ST) exists, and therefore, it is also possible to regard the slit ST as a slit that exposes part of the floating gate electrode FG when viewed in a planar manner. That is, in the wire part M1Ba in the present embodiment, the slit ST that exposes part of the floating gate electrode FG arranged under the wire part M1Ba is formed.

It is possible to form the slit ST so as to cross the floating gate electrode FG when viewed in a planar manner, however, it is preferable for the slit ST not to cross the semiconductor region MD (drain region). By doing so, it is possible to prevent the slit ST from overlapping in a planar manner the contact hole CT formed in the top part of the semiconductor region MD (drain region) and the plug PG embedded in the contact hole CT. Hence, it is possible to couple the plug PG formed in the top part of the semiconductor region MD (drain region) to the wire part M1Ba both easily and appropriately.

The effect obtained by providing the slit ST in the wire part M1Ba in the present embodiment is basically the same as the effect obtained by providing the opening OP2 in the bit wire M1B in the fourth embodiment. In the present embodiment, by providing the slit ST (the slit ST that exposes part of the floating gate electrode FG) in the wire part M1Ba, it is possible to appropriately irradiate the floating gate electrode FG with ultraviolet beams via the slit ST, and therefore, it is possible to improve the efficiency in the erase operation by ultraviolet irradiation.

In the attempt to improve the holding characteristics of stored information, it is effective for the wire part M1Ba to exist directly on the end part (outer circumferential part) of the floating gate electrode FG on which the electric field tends to concentrate, and therefore, in the present embodiment, the slit ST is provided so as to cross the floating gate electrode FG. As can also be seen from FIG. 45 and FIG. 47, it is preferable for both end parts of each floating gate electrode FG in the X direction not to be exposed from the slit ST. That is, it is preferable for the wire part M1Ba to exist directly on both end parts (when the planar shape of the floating gate electrode FG is substantially a rectangle, sides parallel with the X direction in the rectangle) of each floating gate electrode FG in the Y direction. In other words, it is preferable for at least the corner part of each floating gate electrode FG to be covered with the wire part M1Ba.

By doing so, it is possible to reduce the area of the end part (outer circumferential part) of the floating gate electrode FG to be exposed from the slit ST, and therefore, it is possible to efficiently improve the holding characteristics of stored information of a nonvolatile memory. In the sixth embodiment also, directly on both end parts of each floating gate electrode FG in the Y direction, the wire part M1Ba exists.

When the slit ST that crosses the floating gate electrode FG is provided in the wire part M1Ba as in the present embodiment, it is possible to increase the dimension of the slit ST in the X direction or the number of the slits ST. Hence, when forming the wire M1 including the wire part M1Ba by the damascene method, it is possible to suppress or prevent the occurrence of dishing due to the presence of the slit ST in the wire part M1Ba. Consequently, in the present embodiment, it is possible to obtain the effect of suppressing or preventing the occurrence of dishing when the wire M1 is the damascene wire (embedded wire) even if the erase by ultraviolet irradiation is not performed.

The number of the slits ST crossing each floating gate electrode FG is one or more, and if the number is assumed to be two or more, it is possible to further improve the effect of suppressing (preventing) the occurrence of dishing when forming the wire M1 including the wire part M1Ba by the damascene method.

From the viewpoint of improving the holding characteristics of stored information of a nonvolatile memory as much as possible, it is effective to increase the area of the part covered with the wire part M1Ba in the end part (outer circumferential part) of the floating gate electrode FG. From this viewpoint, in the present embodiment and the sixth embodiment, it is preferable to form the shape of the wire part M1Ba into one, which is a profile (corresponding to the wire part M1Ba in the fifth embodiment) capable of covering the whole floating gate electrode FG in which the opening OP3 or the slit ST that exposes part of the floating gate electrode FG is provided. That is, it is preferable to design the profile of the wire part M1Ba so that the whole profile of the wire part M1Ba including the opening OP3 or the slit ST includes the floating gate electrode FG in the wire part M1Ba in which the opening OP3 or the slit ST is provided.

### Eighth Embodiment

In the fifth to seventh embodiments described above, the attempt is made to improve the holding characteristics of stored information of a nonvolatile memory by drawing up the semiconductor region MD for drain to the bit wire M2B in the second wiring layer (M2) via the wire part M1Ba in the first wiring layer (M1) and covering at least part of each floating gate electrode FG with the wire part M1Ba.

In the present embodiment, that the word wire M1Wa and the source wire M1Sa extending in the Y direction are formed in the first wiring layer (wire M1) and the bit wire M2B as the bit line BL extending in the X direction is formed in the second wiring layer (wire M2) is the same as that in the fifth to seventh embodiments, however, the attempt is made to improve the holding characteristics of stored information of a nonvolatile memory by using a wire M1A formed in the first wiring layer (M1) and not electrically coupled with the bit wire M2B. The present embodiment is explained below specifically.

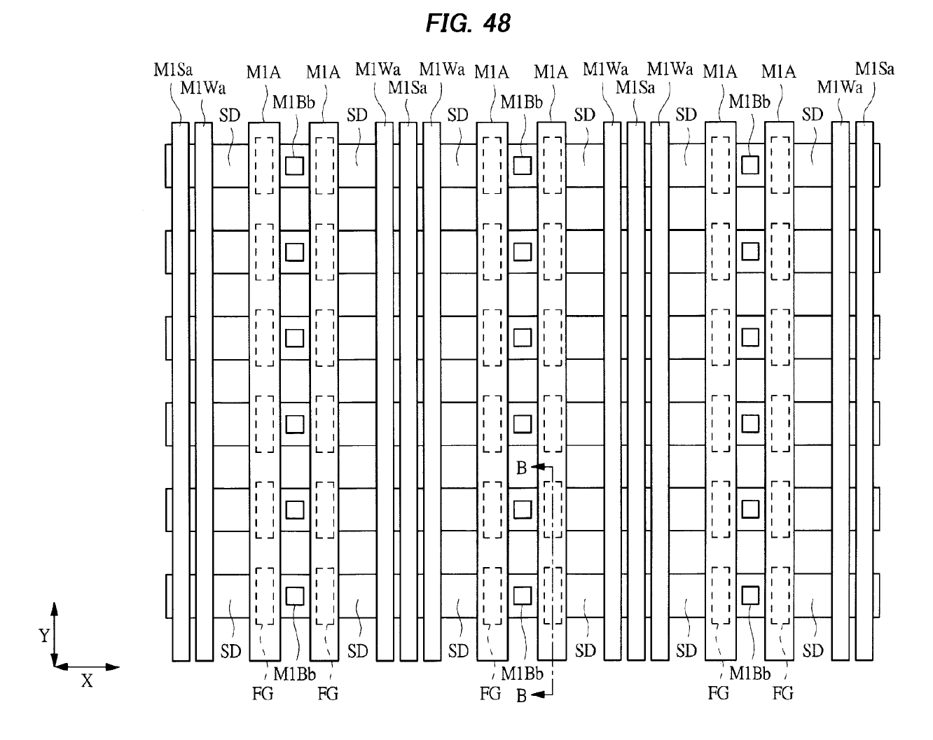

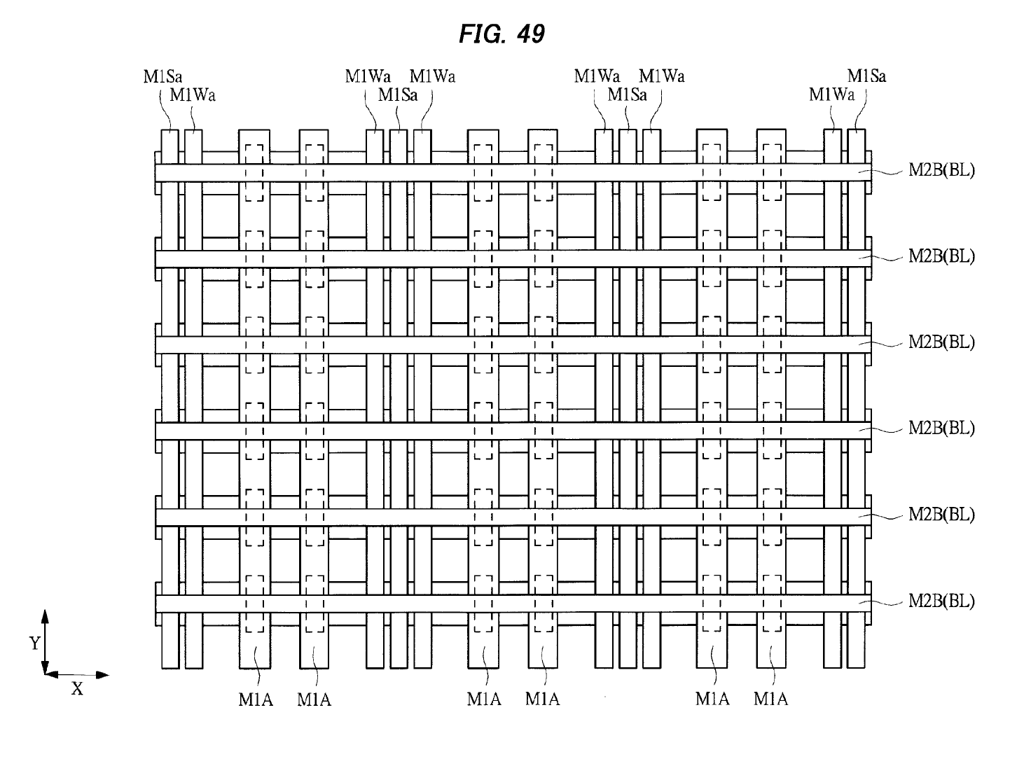

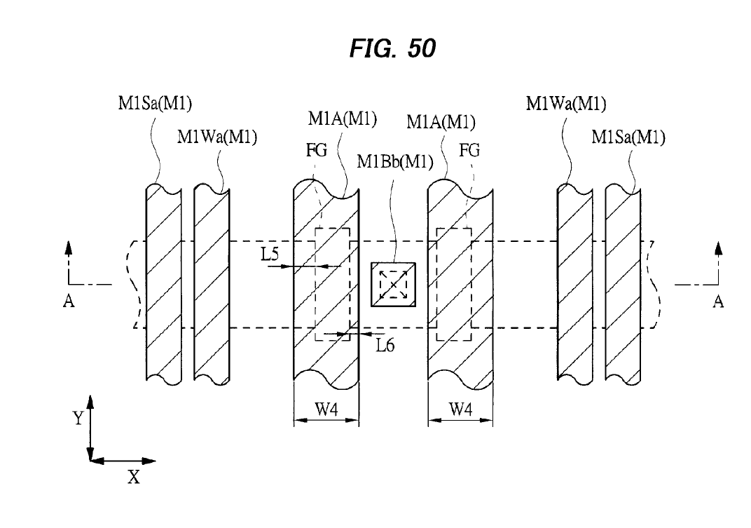

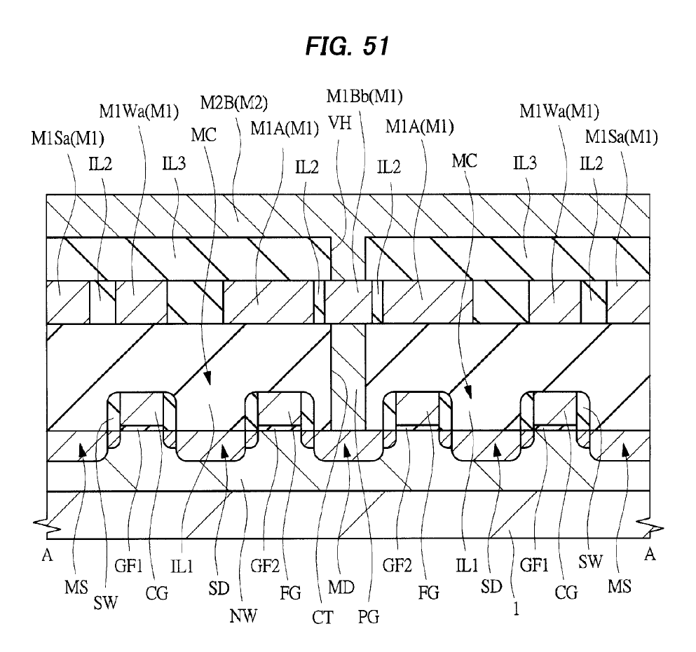

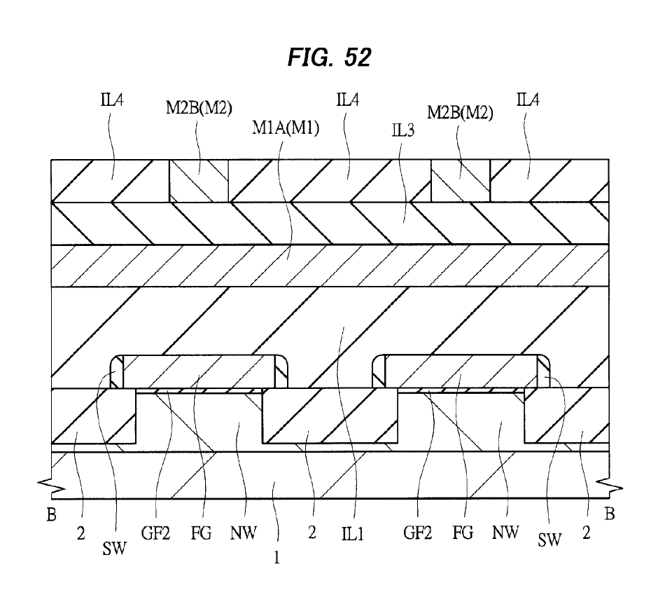

FIG. 48 to FIG. 50 are plan views of relevant parts of the semiconductor device in the present embodiment, wherein FIG. 48 corresponds to FIG. 4 in the first embodiment, FIG. 49 corresponds to FIG. 5 in the first embodiment, and FIG. 50 corresponds to FIG. 7 in the first embodiment. FIG. 51 and FIG. 52 are section views of relevant parts of the semiconductor device in the present embodiment, wherein FIG. 51 corresponds to FIG. 8 in the first embodiment and FIG. 52 corresponds to FIG. 9 in the first embodiment. Consequently, FIG. 51 substantially corresponds to the section view in the position of the A-A line shown in FIG. 50 and FIG. 52 substantially corresponds to the section view in the position of the B-B line shown in FIG. 48.

The semiconductor device in the present embodiment shown in FIG. 48 to FIG. 51 has the same configuration as that of the semiconductor device in the fifth embodiment except for that the wire part M1Bb and the wire M1A are provided instead of the wire part M1Ba, and therefore, the wire part M1Bb and the wire M1A, which are the different points from the fifth embodiment, are explained here (explanation of other parts is omitted).

As can also be seen from FIG. 51 and FIG. 52, the insulating film IL1 and the structure below the insulating film IL1 of the semiconductor device in the present embodiment are the same as those of the semiconductor device in the first embodiment. Then, in the present embodiment, as can also be seen from FIG. 48 to FIG. 52, the word wire M1Wa and the source wire M1Sa extending in the Y direction are formed in the first wiring layer (wire M1) and the bit wire M2B as the bit line BL extending in the X direction is formed in the second wiring layer (wire M2).

In the present embodiment, in the first wiring layer (wire M1), the wire part M1Bb is provided instead of the wire part M1Ba. The wire part M1Bb corresponds to the wire part M1Ba the planar dimensions (planar area) of which are reduced and while the wire part M1Ba covers the floating gate electrode FG when viewed in a planar manner, in the present embodiment, the wire part M1Bb does not overlap the floating gate electrode FG in a planar manner and does not cover the floating gate electrode FG. Hence, the state is one where the wire part M1Bb does not exist directly on each floating gate electrode FG. However, the wire part M1Bb can be coupled to the semiconductor region MD for drain via the plug PG and has the planar dimensions (planar area) that can be coupled to the bit wire M2B via the via part of the bit wire M2B. Other configurations of the wire part M1Bb are the same as those of the wire part M1Ba, and therefore, their explanation is omitted here.

In the present embodiment, the wire M1A is provided in the first wiring layer (wire M1) so as to cover the floating gate electrode FG when viewed in a planar manner. That is, the wire M1A extends in the Y direction so as to cover each floating gate electrode FG of the memory cells MC arranged side by side in the Y direction among the memory cells MC arranged in an array in the X direction and the Y direction. One wire M1A is arranged for the memory cells MC arranged side by side in the Y direction and directly under each wire M1A, a plurality of the floating gate electrodes FG of the memory cells MC arranged side by side in the Y direction is arranged. A plurality of the wires M1A as described above is arranged side by side in the X direction in accordance with the arrangement of the memory cells MC in the X direction. When viewed in the X direction, the wire M1A is located between the word wire M1Wa and the wire part M1Bb. The wire M1A extends in the Y direction, and therefore, it is possible to arrange the wire M1A so as not to come into contact with the word wire M1Wa or the source wire M1Sa extending in the Y direction in the same first wiring layer (wire M1). Further, the wire M1 is formed so as not to come into contact with the word wire M1Wa or the source wire M1Sa, and therefore, it does not extends over the semiconductor region MS for source or the control gate electrode CG.

While the wire part M1Ba and the wire part M1Bb are wire parts (wires) electrically coupled to the bit wire M2B (that is, the bit line BL), the wire M1A is a wire not electrically coupled to the bit wire M2B (that is, the bit line BL). That is, while the wire part M1Ba and the wire part M1Bb are both wire parts (wires) electrically coupled to the semiconductor region MD for drain of any of the memory cells MC, the wire M1A is a wire not electrically coupled to any of the semiconductor regions MD for drain of the memory cells MC.

While the floating gate electrode FG is covered with the wire part M1Ba electrically coupled to the bit wire M2B (that is, the bit line BL) in the fifth embodiment, in the present embodiment, the floating gate electrode FG is covered with the wire M1A not electrically coupled to the bit wire M2B (that is, the bit line BL). Due to the state where the floating gate electrode FG is covered with the wire M1A when viewed in a planar manner, it is possible for the wire M1A to prevent water or ions (for example, cations such as Na⁺ ions) from diffusing under the wire M1A, and therefore, it is possible to reduce the amount of water or the number of ions that reach the floating gate electrode FG. Hence, the charges accumulated in the floating gate electrode FG can be held appropriately until the erase operation is performed, and therefore, it is possible to improve the holding characteristics of stored information of a nonvolatile memory.

As described above, in the present embodiment, the diffusion of water or ions (for example, cations such as Na⁺ ions) from the insulating film (insulating films IL2, IL3, IL4 and the insulating film in the upper layer) in the layer upper than the insulating film IL1 to the floating gate electrode FG can be prevented by the wire M1A, and therefore, it is possible to improve the holding characteristics of stored information of a nonvolatile memory. As a result, it is possible to improve the performance of the semiconductor device comprising a nonvolatile memory.

The wire M1A is a wire not coupled electrically to any of the bit wires M2B (that is, the bit lines BL), however, it is preferable to couple the wire to a fixed potential. Further, a plurality of the wires M1A is arranged side by side in the X direction in correspondence with the arrangement of the memory cells MC in the X direction, however, it is further preferable for the fixed potentials to be supplied to the wires M1A to be the same potential (most preferably, the ground potential). By coupling the wire M1A to a fixed potential, it is possible to prevent the wire M1A from becoming a floating potential, resulting in charge-up. Due to this, it is possible to set the wire M1A electrically stable.

In the present embodiment, further preferably, the whole floating gate electrode FG is covered with the wire M1A. That is, further preferably, each floating gate electrode FG is included in the wire M1A in a planar manner and the state is one where the wire M1A exists directly on the whole of each floating gate electrode FG. In other words, it is preferable to arrange the wire M1A outside each side of each floating gate electrode FG. In order to do so, it is only required to make a width W4 (shown in FIG. 50) of the wire M1A greater than the width W2 (shown in FIG. 6) of the floating gate electrode FG (that is, W4>W2). Here, the width W4 of the wire M1A corresponds to the dimension of the wire M1A in the X direction and the width W2 of the floating gate electrode FG corresponds to the dimension of the floating gate electrode FG in the X direction.

When the wire M1A covers at least part of the floating gate electrode FG, it is possible to reduce the amount of water or the number of ions (for example, cations such as Na⁺ ions) that reach the floating gate electrode FG compared to the case where the floating gate electrode FG is not at all covered by the wire M1A. Hence, it is possible to obtain the effect of improving the holding characteristics of stored information of a nonvolatile memory even when the wire M1A covers at least part of the floating gate electrode FG, needless to say when the wire M1A covers the whole floating gate electrode FG.

However, in order to improve the holding characteristics of stored information of a nonvolatile memory as much as possible, it is effective to reduce the amount of water or the number of ions that reach the floating gate electrode FG as much as possible, and therefore, it is further preferable to cause the wire M1A to cover the whole floating gate electrode FG as shown in FIG. 50. That is, further preferably, each floating gate electrode FG is included in the wire M1A in a planar manner and the state is one where the wire M1A exists directly on the whole of each floating gate electrode FG.

When the wire M1A is caused to cover the whole floating gate electrode FG, distances L5, L6 (shown in FIG. 50) from the end part of the floating gate electrode FG in the X direction to the end part of the wire M1A in the X direction is greater than zero (that is, L5, L6>0) when viewed in a planar manner. By increasing the distances L5, L6, it is possible to further reduce the amount of water or the number of ions (for example, cations such as Na⁺ ions) that skirt the wire M1A and reach the floating gate electrode FG. From this viewpoint, by setting the distances L5, L6 from the end part of the floating gate electrode FG in the X direction to the end part of the wire M1A in the X direction to 0.4 μm or more (that is L5, L6≧0.4 μm), it is possible to further improve the holding characteristics of stored information of a nonvolatile memory. On the other hand, by reducing the distances L5, L6, it is possible to make the attempt to reduce the layout of the memory cell array. Hence, it is recommended to design the distances L5, L6 from both the viewpoint of the effect of improving the holding characteristics of stored information of a nonvolatile memory and the viewpoint of the layout of the memory cell.

### Ninth Embodiment

In the semiconductor device in the eighth embodiment described above, it is possible to appropriately perform the electrical erase operation. On the other hand, in the semiconductor device in the eighth embodiment, it is also possible to perform the erase itself by ultraviolet irradiation by utilizing scattered ultraviolet beams inside the semiconductor device, however, in the state where the wire M1A covers the whole floating gate electrode FG, the ultraviolet beams are shielded by the wire M1A, and therefore, the ultraviolet beams cannot reach the floating gate electrode FG successfully and there is a possibility that the efficiency in the erase by ultraviolet irradiation is reduced. In this case, it is required to take measures to increase the ultraviolet irradiation time at the time of erase operation etc.

Consequently, in the present ninth embodiment, the opening OP4 is provided in the wire M1A and in the tenth embodiment, to be described later, the opening OP5 is provided in the wire M1A to allow the ultraviolet beams to reach the floating gate electrode FG through the openings OP4, OP5. Due to this, it is possible to improve the efficiency in the erase operation by ultraviolet radiation.

The opening OP4 provided in the wire M1A is explained below specifically.

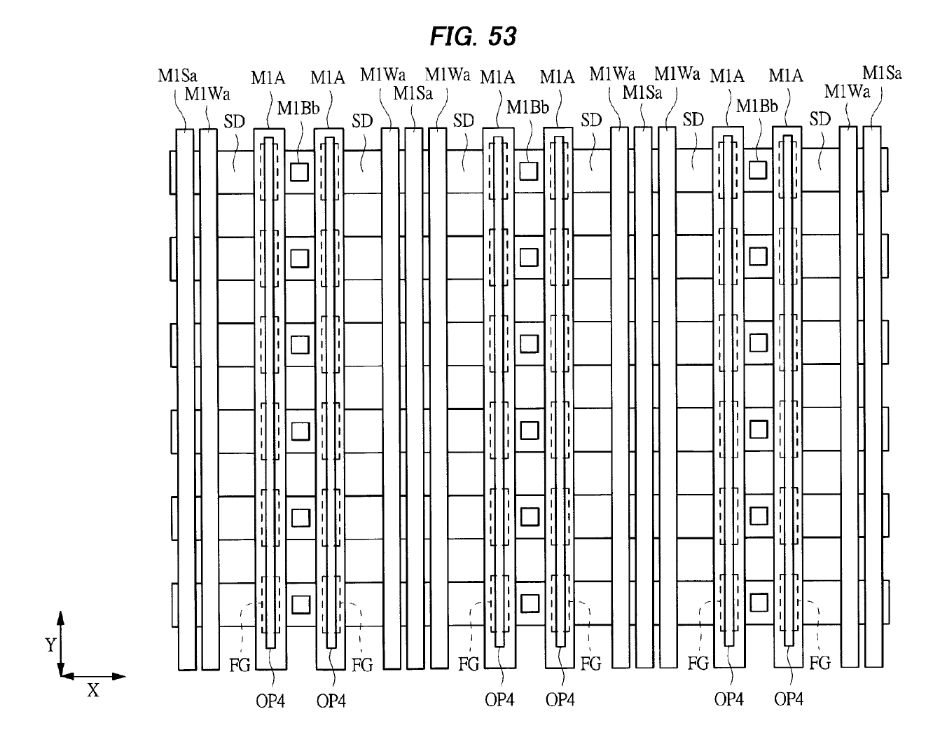

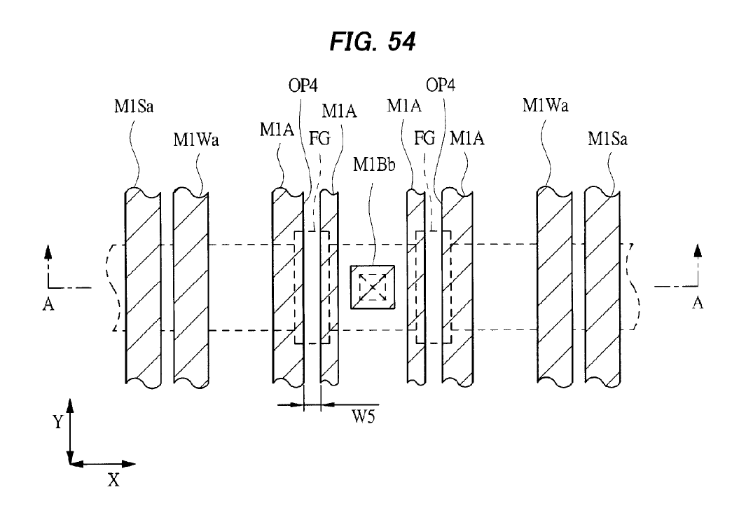

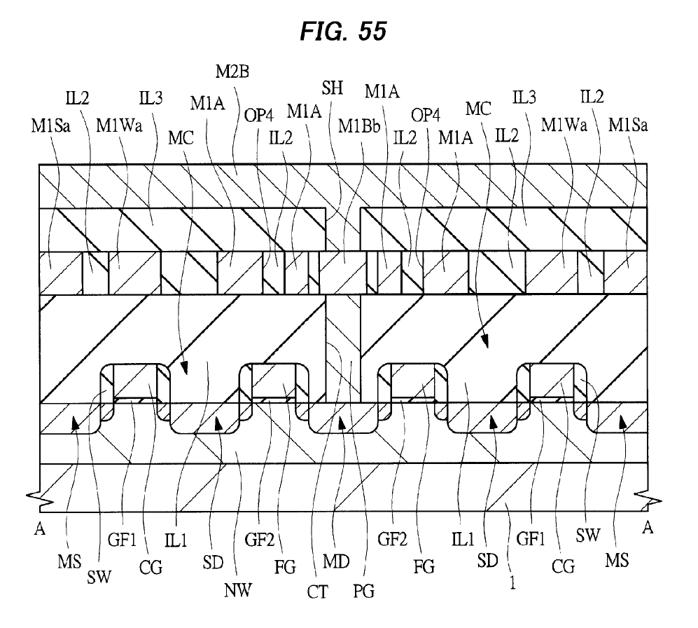

FIG. 53 and FIG. 54 are plan views of relevant parts of the semiconductor device in the present embodiment, wherein FIG. 53 corresponds to FIG. 48 in the eighth embodiment and FIG. 54 corresponds to FIG. 50 in the eighth embodiment. Further, FIG. 55 is a section view of relevant parts of the semiconductor device in the present embodiment and corresponds to FIG. 51 in the eighth embodiment. Consequently, FIG. 55 substantially corresponds to the section view in the position of the A-A line shown in FIG. 54.

The semiconductor device in the present embodiment shown in FIG. 53 to FIG. 55 has the same configuration as that of the semiconductor device in the eighth embodiment except for that the opening OP4 is provided in the wire M1A, and therefore, the opening (through-hole) OP4, which is the different point from the eighth embodiment, is explained here (explanation of other parts is omitted).

In the present embodiment, the opening OP4 is provided in each wire M1A and the opening OP4 is formed so as to be a slit-shaped opening the dimension of which in the Y direction is greater than the dimension in the X direction and to extend in the Y direction. Each opening OP4 is formed so as to cross the floating gate electrode FG when viewed in a planar manner and the opening OP4 partially overlaps the floating gate electrode FG. That is, the opening OP4 is formed in the wire M1A so as to cross the floating gate electrode FG of each memory cell MC when viewed in a planar manner. Because the opening OP4 crosses each floating gate electrode FG, each floating gate electrode FG is in the state where a part directly on which the wire M1A does not exist (that is, a part directly on which the insulating film IL2 in the opening OP4 exists) and a part directly on which the wire M1A exists (that is, a part where the opening OP4 does not exist) are mixed. The interior of the opening OP4 is filled with the insulating film IL2. Part of each floating gate electrode FG overlaps the opening OP4 in a planar manner and has a part directly on which the opening OP4 (the insulating film IL2 in the opening OP4) exists, and therefore, it is possible to regard the opening OP4 as an opening that exposes part of the floating gate electrode FG when viewed in a planar manner. That is, in the wire M1A in the present embodiment, the opening OP4 that exposes part of the floating gate electrode FG arranged under the wire M1A is formed. Further, FIG. 53 shows a case where the opening OP4 crosses the floating gate electrodes FG arranged side by side in the Y direction.

The effect obtained by providing the opening OP4 in the wire M1A in the present embodiment is basically the same as the effect obtained by providing the opening OP2 in the bit wire M1B in the fourth embodiment. In the present embodiment, by providing the opening OP4 (the opening OP4 that exposes part of the floating gate electrode FG) in the wire M1A, it is possible to appropriately irradiate the floating gate electrode FG with ultraviolet beams via the opening OP4, and therefore, it is possible to improve the efficiency in the erase operation by ultraviolet radiation.

It is preferable to make a width W5 (shown in FIG. 54) of the opening OP4 smaller than the width W2 (shown in FIG. 6) of the floating gate electrode FG (that is, W5<W2). Here, the width W5 of the opening OP4 corresponds to the dimension in the X direction of the opening OP4. Due to this, it is possible to prevent the whole floating gate electrode FG from being exposed from the opening OP4 and to bring about the state where only part of each floating gate electrode FG is exposed from the opening OP4. Hence, it is possible to appropriately obtain both the effect of improving the efficiency in the erase operation by ultraviolet radiation by providing the opening OP4 and the effect of improving the holding characteristics of stored information of a nonvolatile memory by partially covering each floating gate electrode FG with the wire M1A.

In FIG. 53 to FIG. 55, a case is shown where the number of the openings OP that cross each opening OP4 is one, however, it is also possible to increase the number of the openings that cross each opening OP4 to two or more.

In order to improve the holding characteristics of stored information of a nonvolatile memory as much as possible, the case is more advantageous where the opening that exposes part of the floating gate electrode FG is not provided in the wire M1A, as in the eighth embodiment. On the other hand, in order to make coexist the improvement in the holding characteristics of stored information of a nonvolatile memory and the improvement in efficiency in the erase operation by ultraviolet radiation, the case is more advantageous where the opening (OP4, OP5) that exposes part of the floating gate electrode FG is provided in the wire M1A, as in the present embodiment and the tenth embodiment, to be described later. Hence, a more significant effect can be obtained if the ninth embodiment and the tenth embodiment, to be described later, are applied to the case where erase is performed by ultraviolet radiation.

In order to make the attempt to improve the holding characteristics of stored information, it is effective for the wire M1A to exist directly on the end part (outer circumferential part) of the floating gate electrode FG on which the electric field tends to concentrate, and therefore, in the present embodiment, the opening OP4 is provided so as to cross the floating gate electrode FG, however, as can also be seen from FIG. 54 and FIG. 55, it is preferable for both end parts of each floating gate electrode FG in the X direction not to be exposed from the opening OP4. That is, it is preferable for the wire M1A to exist directly on both end parts (when the planar shape of the floating gate electrode FG is substantially a rectangle, sides parallel with the Y direction in the rectangle) of each floating gate electrode FG in the X direction. In other words, it is preferable for at least the corner part of each floating gate electrode FG to be covered with the wire M1A.

Due to this, it is possible to reduce the area of the end part (outer circumferential part) of the floating gate electrode FG exposed from the opening OP4, and therefore, it is possible to efficiently improve the holding characteristics of stored information of a nonvolatile memory. In the tenth embodiment also, to be described later, the wire M1A exists directly on both end parts of each floating gate electrode FG in the X direction.

As in the present embodiment, when the opening OP4 that crosses the floating gate electrode FG is provided in the wire M1A, it is possible to increase the dimension of the opening OP4 in the Y direction. Hence, when forming the wire M1 including the wire M1A by the damascene method, it is possible to suppress or prevent the occurrence of dishing due to the presence of the opening OP4 in the wire M1A. Consequently, in the present embodiment, when the wire M1 is a damascene wire (embedded wire), it is possible to obtain the effect of suppressing or preventing the occurrence of dishing even when erase by ultraviolet radiation is not performed.

Further, in the present embodiment, it is possible to use a slit instead of the opening OP4 provided in the wire M1A. The opening OP4 is a closed region (closed space) surrounded by the wire M1A when viewed in a planar manner, however, a slit may be used instead of the opening OP4, which is formed by opening one of the end parts of the opening OP4 in the X direction (that is, by bringing the opening OP4 into the state of not being closed by the wire M1A). When a slit is used as the opening OP4, the relationship between the slit (slit corresponding to the opening OP4) and the floating gate electrode FG is also the same as the relationship between the opening OP4 and the floating gate electrode FG described above.

### Tenth Embodiment

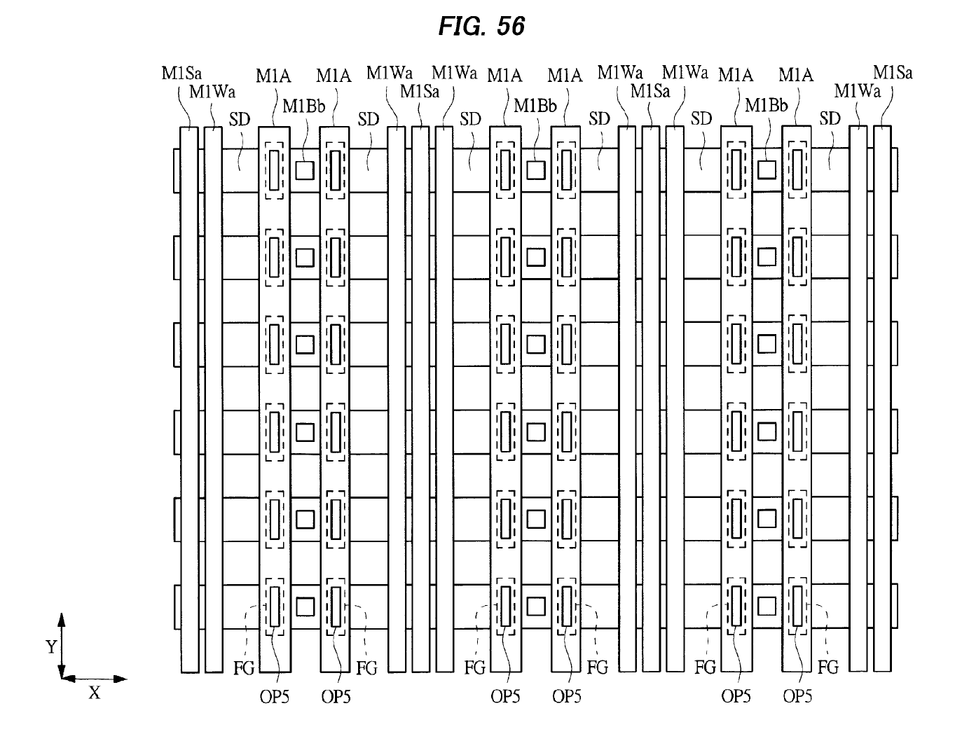

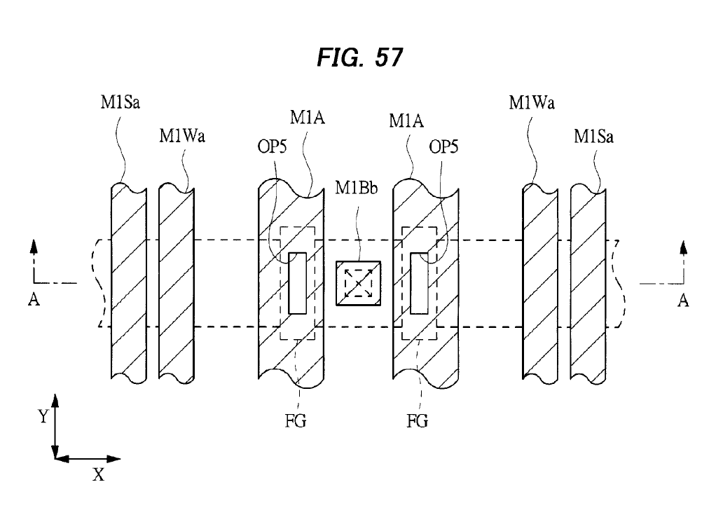

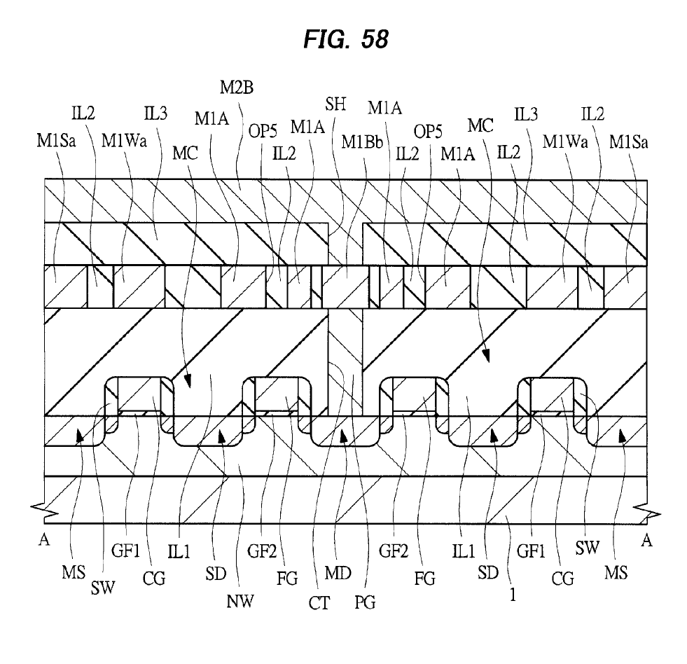

FIG. 56 and FIG. 57 are plan views of relevant parts of the semiconductor device in the present embodiment, wherein FIG. 56 corresponds to FIG. 48 in the eighth embodiment and FIG. 57 corresponds to FIG. 50 in the eighth embodiment. Further, FIG. 58 is a section view of relevant parts of the semiconductor device in the present embodiment and corresponds to FIG. 51 in the eighth embodiment. Consequently, FIG. 58 substantially corresponds to the section view in the position of the A-A line shown in FIG. 57.

The semiconductor device in the present embodiment shown in FIG. 56 to FIG. 58 has the same configuration as that of the semiconductor device in the eighth embodiment except for that the opening (through-hole) OP5 is provided in the wire part M1A, and therefore, the opening OP5, which is the different point from the eight embodiment, is explained here (explanation of other parts is omitted).

The opening OP5 provided in the wire M1A in the present embodiment is basically the same as the opening OP1 provided in the bit wire M1B in the third embodiment described above and also basically the same as the opening OP3 provided in the wire part M1Ba in the sixth embodiment described above. That is, in the present embodiment, the relationship between the opening OP5 provided in the wire M1A and the floating gate electrode FG is the same as the relationship between the opening OP1 provided in the bit wire M1B and the floating gate electrode FG in the third embodiment, and the same as the relationship between the opening OP3 provided in the wire part M1Ba and the floating gate electrode FG in the sixth embodiment.

To explain specifically, in the present embodiment, the opening OP5 is provided in the wire M1A and the opening OP5 is formed so as to be included in the floating gate electrode FG when viewed in a planar manner. That is, in each wire M1A, the opening OP5 is provided for each floating gate electrode FG that exists under the wire M1A and the planar dimensions (planar area) of each opening OP5 are smaller than the planar dimensions (planar area) of the floating gate electrode FG and as can also be seen from FIG. 57, the opening OP5 is included in the floating gate electrode FG in a planar manner. In other words, the opening OP5 is arranged inside each side of each floating gate electrode FG. Hence, the state is one where the floating gate electrode FG exists directly under each opening OP5. The interior of the opening OP5 is filled with the insulating film IL2. Directly under the opening OP5, part of the floating gate electrode FG exists, and therefore, it is possible to regard the opening OP5 as an opening that exposes part of the floating gate electrode FG when viewed in a planar manner. That is, in the wire M1A in the present embodiment, the opening OP5 that exposes part of the floating gate electrode FG arranged under the wire M1A is formed.

The effect obtained by providing the opening OP5 in the wire M1A in the present embodiment is basically the same as the effect obtained by providing the opening OP1 in the bit wire M1B in the third embodiment and also basically the same as the effect obtained by providing the opening OP3 in the wire part M1Ba in the sixth embodiment. In the present embodiment, by providing the opening OP5 (opening OP5 that exposes part of the floating gate electrode FG) in the wire M1A, it is possible to appropriately irradiate the floating gate electrode FG with ultraviolet beams via the opening OP5, and therefore, it is possible to improve the efficiency in the erase operation by ultraviolet radiation

In the present embodiment, each opening OP5 is formed so as to be included in each floating gate electrode FG in a planar manner, and therefore, the state is one where the wire MIA exists directly on the whole end part (outer circumferential part) of the floating gate electrode FG on which the electric field tends to concentrate. In other words, at least corner part of each floating gate electrode FG is covered with the wire M1A and at least each side of each floating gate electrode FG is covered with the wire M1A.

Hence, it is possible to efficiently improve the holding characteristics of stored information of a nonvolatile memory while providing the opening OP5 in the wire M1A that facilitates irradiation of the floating gate electrode FG with ultraviolet beams.

From the viewpoint of improving the holding characteristics of stored information of a nonvolatile memory as much as possible, it is effective to increase the area of the part covered with the wire M1A of the end part (outer circumferential part) of the floating gate electrode FG. From this viewpoint, in the present embodiment and the ninth embodiment, it is preferable to form the wire M1A into a shape, which is a profile (corresponding to the wire MIA in the eighth embodiment) capable of covering the whole floating gate electrode FG in which the opening OP4 or the opening OP5 that exposes part of the floating gate electrode FG is provided. That is, it is preferable to design the profile of the wire M1A so that the profile of the whole wire M1A including the openings OP4, OP5 includes the floating gate electrode FG in the wire M1A in which the opening OP4 or the opening OP5 is provided.

The invention made by the inventors of the present invention is specifically explained as above based on the embodiments, however, the present invention is not limited to the embodiments and it is needless to say that there can be various modified examples within the scope not deviating from its gist.

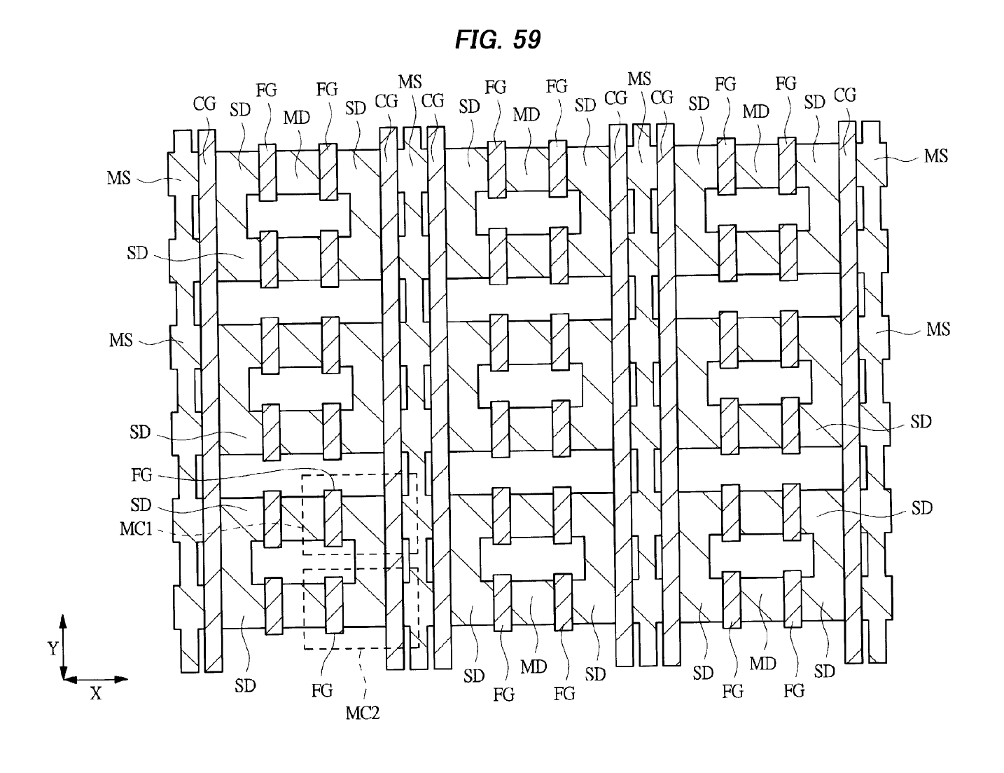

In the first to tenth embodiments described above, the nonvolatile memory that stores 1-bit information by one memory cell MC is explained, however, the techniques in the first to tenth embodiments can be applied to a nonvolatile memory that stores 1-bit information by the two memory cells MC as shown in FIG. 59. Here, FIG. 59 is a plan view (of relevant parts) corresponding to FIG. 2. The nonvolatile memory in FIG. 59 differs from the nonvolatile memory in FIG. 2 in that the semiconductor regions SD are linked in the Y direction and formed integrally into one unit as to the two memory cells MC neighboring in the Y direction. As to the nonvolatile memory in FIG. 59, for example, it is possible to regard the whole of memory cells MC1, MC2 as in a storing state if at least one of the floating gate electrodes FG of the memory cells MC1, MC2 is in the storing state (charge accumulate state) in the two memory cells MC1, MC2 neighboring in the Y direction. Hence, it is only required for the nonvolatile memory in FIG. 59 to be capable of holding stored information by at least one of the memory cells MC1, MC2, and therefore, it is possible to further improve the holding characteristics of stored information of the nonvolatile memory. On the other hand, it is possible for the nonvolatile memory in FIG. 59 to store 1-bit information by one memory cell MC, and therefore, it is possible to make an attempt to increase the storage capacity and downsize the semiconductor device (reduce in area). As to the nonvolatile memory in FIG. 59 also, it is possible to improve the holding characteristics of stored information of the nonvolatile memory by covering the floating gate electrode FG with the bit wire M1B, the wire part M1Ba, or the wire M1A as explained in the first to tenth embodiments.

The present invention is effective when applied to a semiconductor device.

What is claimed is:

1. A semiconductor device comprising:
a semiconductor substrate;
a plurality of nonvolatile memory cells arranged in an array in a first direction and in a second direction intersecting the first direction on the main surface of the semiconductor substrate; and
a plurality of wiring layers formed over the main surface of the semiconductor substrate,
wherein each of the nonvolatile memory cells has a memory transistor having a floating gate electrode and a control transistor coupled in series to the memory transistor,
wherein a bit wire that couples drain regions of the memory transistors of the nonvolatile memory cells arranged in the first direction is formed so as to extend in the first direction in the lowermost wiring layer of the wiring layers, and
wherein the width of the bit wire is greater than the dimension of the floating gate electrode in the second direction.

2. The semiconductor device according to claim 1,
wherein in each of the nonvolatile memory cells, the memory transistor and the control transistor are arranged side by side in the first direction, and
wherein the source region of the memory transistor and the drain region of the control transistor share the same semiconductor region.

3. The semiconductor device according to claim 2,
wherein the width of the part of the bit wire that extends over the floating gate electrode is greater than the dimension of the floating gate electrode in the second direction.

4. The semiconductor device according to claim 3,
wherein the whole floating gate electrode is covered with the bit wire.

5. The semiconductor device according to claim 3,
wherein in the bit wire, a plurality of openings that expose each part of a plurality of the floating gate electrodes arranged under the bit wire is formed.

6. The semiconductor device according to claim 5,
wherein the bit wire exists directly on both end parts of each of the floating gate electrodes arranged under the bit wire, in the second direction.

7. The semiconductor device according to claim 6,
wherein each of the openings is smaller than each of the floating gate electrodes, and
wherein in the bit wire, each of the openings is formed so as to be included in a planar manner by each of the floating gate electrodes arranged under the bit wire.

8. The semiconductor device according to claim 7,
wherein in each of the floating gate electrodes, the dimension in the first direction is smaller than that in the second direction, and
wherein in each of the openings, the dimension in the first direction is smaller than that in the second direction.

9. The semiconductor device according to claim 6,
wherein in each of the openings, the dimension in the second direction is smaller than that in the first direction, and
wherein one or more of the openings cross each of the floating gate electrodes.

10. A semiconductor device comprising:
a semiconductor substrate;
a plurality of nonvolatile memory cells arranged in an array in a first direction and in a second direction intersecting the first direction on the main surface of the semiconductor substrate; and
a plurality of wiring layers formed over the main surface of the semiconductor substrate,
wherein each of the nonvolatile memory cells has a memory transistor having a floating gate electrode and a control transistor coupled in series to the memory transistor,
wherein a bit wire that couples drain regions of the memory transistors of the nonvolatile memory cells arranged in the first direction is formed so as to extend in the first direction in the second wiring layer from the bottom of the wiring layers, and
wherein in each of the nonvolatile memory cells, a wiring part formed in the lowermost wiring layer of the wiring layers in order to draw up the drain region of the memory transistor to the bit wire covers at least part of the floating gate electrode.

11. The semiconductor device according to claim 10,
wherein in each of the nonvolatile memory cells, the memory transistors and the control transistors are arranged side by side in the first direction, and
wherein the source region of the memory transistor and the drain region of the control transistor share the same semiconductor region.

12. The semiconductor device according to claim 11,
wherein in each of the nonvolatile memory cells, the whole floating gate electrode is covered with the wiring part.

13. The semiconductor device according to claim 11,
wherein in the wiring part, an opening or a slit which exposes part of the floating gate electrode arranged under the wiring part is formed.

14. The semiconductor device according to claim 11,
wherein in the wiring part, an opening that exposes part of the floating gate electrode arranged under the wiring part is formed;
wherein the opening is smaller than the floating gate electrode; and
wherein the opening is formed so as to be included in a planar manner in the floating gate electrode arranged under the wiring part.

15. The semiconductor device according to claim 11,
wherein the wiring part has a shape which has a profile capable of covering the whole floating gate electrode and has an opening or a slit provided exposing part of the floating gate electrode.

16. A semiconductor device comprising:
a semiconductor substrate;
a plurality of nonvolatile memory cells arranged in an array in a first direction and in a second direction intersecting the first direction on the main surface of the semiconductor substrate; and
a plurality of wiring layers formed over the main surface of the semiconductor substrate,
wherein each of the nonvolatile memory cells has a memory transistor having a floating gate electrode and a control transistor coupled in series to the memory transistor,
wherein a bit wire that couples drain regions of the memory transistors of the nonvolatile memory cells arranged in the first direction is formed so as to extend in the first direction in the second wiring layer from the bottom of the wiring layers, and
wherein in each of the nonvolatile memory cells, at least part of the floating gate electrode is covered with a first wire which is formed in the lowermost wiring layer of the wiring layers and which is not coupled electrically with the bit wire.

17. The semiconductor device according to claim 16,
wherein in each of the nonvolatile memory cells, the memory transistors and the control transistors are arranged side by side in the first direction, and
wherein the source region of the memory transistor and the drain region of the control transistor share the same semiconductor region.

18. The semiconductor device according to claim 17,
wherein the first wire is a wire to be coupled to a fixed potential.

19. The semiconductor device according to claim 18,
wherein in each of the nonvolatile memory cells, the whole floating gate electrode is covered with the first wire.

20. The semiconductor device according to claim 18,
wherein in the first wire, an opening or a slit which exposes part of the floating gate electrode arranged under the first wire is formed.

21. The semiconductor device according to claim 18,
wherein in the first wire, an opening that exposes part of the floating gate electrode arranged under the first wire is formed,
wherein the opening is smaller than the floating gate electrode, and
wherein the opening is formed so as to be included in a planar manner in the floating gate electrode arranged under the first wire.
